(19) United States
(12) Patent Application Publication
(10) Pub. No.: US 2025/0137113 A1
(43) Pub. Date: May 1, 2025

(54) COATED ARTICLES WITH A PLANARIZATION LAYER/HYDROXYL-MODIFIED LAYER AND A SURFACE-MODIFYING LAYER AND METHODS OF MAKING THE SAME

(71) Applicant: CORNING INCORPORATED, CORNING, NY (US)

(72) Inventors: Kaveh Adib, CORNING, NY (US); Robert Alan Bellman, Ithaca, NY (US); Philip Simon Brown, Big Flats, NY (US); Cody Vic Cushman, Painted Post, NY (US); Brandy Wright Fuller, CORNING, NY (US)

(21) Appl. No.: 18/932,938

(22) Filed: Oct. 31, 2024

Related U.S. Application Data
(60) Provisional application No. 63/546,775, filed on Nov. 1, 2023.

(51) Int. Cl. C23C 14/10; C01B 33/12; C03C 17/245; C03C 17/34; C23C 14/22

(52) U.S. Cl. CPC C23C 14/10; C01B 33/126; C03C 17/245; C03C 17/3435; C23C 14/221; C03C 2218/151; C03C 2218/155

(57) ABSTRACT

Coated articles are described herein that include a first layer. The first layer may comprise a planarization layer and/or a hydroxyl-modified layer. The planarization layer includes a silica or a partial silica-like having Si—O—Si—O bonds. The coated article further includes a surface-modifying layer disposed on a first surface area of the first layer. In aspects, the first layer has a molar ratio of hydrogen to silicon of about 0.2 or more. Methods of forming coated articles can include evaporating a functionalized polyhedral oligomeric silsesquioxane and impinging an ion beam thereon to from a planarization layer. Methods for forming coated articles can include impinging a plasma at a first major surface of a substrate to form a hydroxyl-modified layer.

### CLAIM OF PRIORITY

This application claims the benefit of priority under 35 U.S.C. § 119 of U.S. Provisional Application Ser. No. 63/546,775 filed on Nov. 1, 2023, the content of which is relied upon and incorporated herein by reference in its entirety.

### FIELD

The present disclosure relates generally to coated articles with a first layer (e.g. planarization layer and/or hydroxyl-modified layer) and a surface-modifying layer and methods of making the same and, more particularly, to coated articles comprising the surface-modifying layer disposed on the first layer (e.g. planarization layer and/or hydroxyl-modified layer) and methods of making coated articles.

### BACKGROUND

Glass, glass-ceramic, and ceramic materials are commonly used in various consumer electronic products including display devices, for example, liquid crystal displays (LCDs), electrophoretic displays (EPD), organic light-emitting diode displays (OLEDs), plasma display panels (PDPs), or the like. For example, chemically strengthened glass is favored for many touch-screen products, including cell phones, music players, e-book readers, notepads, tablets, laptop computers, automatic teller machines, and other similar devices. Many of these glass, glass-ceramic, and ceramic materials are also employed in displays and display devices of consumer electronic products that do not have touch-screen capability but are prone to direct human contact, including desktop computers, laptop computers, elevator screens, equipment displays, and others. Glass, glass-ceramic, and ceramic materials are often treated to provide aesthetic and functional characteristics based on the end-use application of the material. For example, anti-reflective, anti-glare, and anti-fingerprint treatments are common treatments used on materials used in touch-screen products.

The durability of some types of treatments, such as an anti-fingerprint coating, can be limited, especially when used in combination with other treatments, for example an anti-reflective coating. Material choices for anti-fingerprint treatments and/or an easy-to-clean (ETC) treatments typically rely on the ability of the treatment materials on the surface to repel material, for example, such as water, dust, and environmental debris including sebum, oils, and proteins. Anti-fingerprint and/or ETC treatments experience wear over time, such as from repeated touching, swiping, cleaning, etc. during use that can affect the ability of the surface of the anti-fingerprint and/or ETC treatment to maintain the ability to repel material.

It is known to use fluorinated silanes, for example fluoroethersilanes, which can bind to the surface as a monolayer or multilayer, to form coatings with a thickness from 2 nm to 5 nm. Once this nanoscale coating is abraded away, the surface no longer exhibits repellant properties. Consequently, there is a need for a way to improve the abrasion resistance of coatings that can be used with glass, glass-ceramic, and/or ceramic articles. This need and other needs are addressed by the present disclosure.

### SUMMARY

There are set forth herein coated articles, first layers (e.g. planarization layers and/or hydroxyl-modified layers), and methods of making the same. The first layer can provide a decreased surface roughness Ra relative to what would be obtained in an article (e.g., coated article) without the first layer, which enables the coated article of the present disclosure including the first layer to have increased abrasion resistance of the surface-modifying layer. In aspects, the first layer can provide a reduced surface roughness relative to a surface roughness of an underlying layer, as a ratio of the surface roughness Ra of the first layer to the surface roughness Ra of the underlying layer, can be 0.9 or less (e.g., from 0.1 to 0.90, from 0.2 to 0.80, or from 0.3 to 0.70). Alternatively or additionally, for example when the first layer is disposed directly on a substrate, the first layer can provide a low surface roughness (e.g., about 0.6 nm or less, from 0.1 nm to 0.6 nm, or from 0.15 nm to about 0.40 nm) that can increase an abrasion resistance of a surface-modifying layer disposed thereon

As discussed below with reference to Example 11 and Example 45, the planarization layers and/or the hydroxyl-modified layers in accordance with aspects of the present disclosure can provide unexpected low surface roughness Ra. Indeed, as demonstrated by the results of the Steel Wool Abrasion Test, the Rubber Abrasion Test, and the Cheesecloth Abrasion Test, the surface-modifying layer disposed on the planarization layer in a coated article in accordance with aspects of the present disclosure can withstand abrasion and maintain good contact angles.

Without wishing to be bound by theory, it is believed that higher spatial frequencies of a surface (e.g., as measured by a 2D isotropic power spectral density discussed herein) impacts the abrasion resistance of a surface-modifying layer disposed thereon. For example, it is believed that decreasing the amplitude of these higher spatial frequencies can enable increased abrasion resistance. Overall surface roughness values such as surface roughness Ra may not fully capture the role of the decreased amplitude at higher spatial frequencies in the first layer. In contrast, aspects of the power spectral density (PSD) (e.g., 2D isotropic PSD) discussed herein may more directly describe these aspects of the first layer.

The first layer can reduce an amplitude of high spatial frequencies (see the power spectral density in FIG. 27), which the inventors have discovered unexpectedly controls the abrasion resistance of the coated article. As shown in FIGS. 23-25, the first layer appears to coarsen the resolution of surface features (corresponding to reducing an amplitude of high spatial frequencies in the power spectral density) that in turn, reduces the surface roughness (and/or high frequency texture) of the resulting surface.

The first layer of the present disclosure can be readily distinguished from other silicon-containing oxides (e.g., a silica capping layer or the substrate) by the properties discussed herein (e.g., hydroxyl content, hardness, refractive index, power spectral density of the surface, surface roughness Ra, molar ratio of hydrogen to silica). For example, the first layer can comprise a greater hydroxyl content than a hydroxyl content of the capping layer; the first layer can exhibit a lower hardness, lower elastic modulus, and/or higher refractive index than the corresponding property of the capping layer; and/or a surface roughness Ra of the first layer can be less than a surface roughness Ra of the capping layer. Additionally, for example, the first layer can comprise a greater molar ratio of hydrogen to silica than a molar ratio of hydrogen to silica of the substrate.

The surface-modifying coating can reduce a visibility and/or color shift associated with disposing a fingerprint thereon. Providing a high water contact angle (e.g., about 100° or more) can enhance the removal of aqueous material (e.g., water droplets, sweat droplets) from the anti-fingerprint coating. Consequently, the anti-fingerprint coating can be hydrophobic and oleophilic. The coated article in accordance with the aspects of the disclosure can exhibit good abrasion resistance (e.g., an abraded water contact angle of about 90° or more after 2,000 cycles, 3,000 cycles, and/or 3,500 cycles in a Steel Wool Abrasion Test, a cheesecloth-abraded water contact angle of about 90° after 200,000 cycles in a Cheesecloth Abrasion Test), for example, maintaining a hydrophobic character. The first layer can exhibit good adhesion to the surface-modifying layer disposed thereon, for example, by providing a lower roughness surface for the surface-modifying layer.

In aspects, forming a planarization layer (e.g., as part of the coated article) can comprise evaporating a functionalized polyhedral oligomeric silsesquioxanes (POSS) and impinging it with an ion beam. Properties of the planarization can be controlled by the discharge current of the ion beam. For a KRI EH-400 End-Hall ion source in a Angstrom Evovac chamber operating at 100V, providing a discharge current of about 0.25 A or more can facilitate the formation of the coating, for example, producing an ion beam with sufficient energy to cause the functionalized POSS to react with other functionalized POSS and/or the first major surface of the substrate at an appreciable rate (e.g., compared to lower discharge currents). Providing a discharge current of about 1 A or less to the ion beam source facilitates deposition of a condensed POSS material. The ion beam discharge can facilitate condensation of the functionalized POSS converting at least a portion of the cage structure of the functionalized POSS to a silica or a partial Si—O—Si—O network. Functionalized POSS is evaporated and subjected to ion beam to create a silica or a partially condensed silica-like network at or near room temperature. Alternatively, the substrate that the thermally evaporated functionalized POSS condenses on and the ion beam impinges can be heated. Substrate temperature during POSS deposition is 250° C. or less, 200° C. or less, 100° C. or less, or preferably 50° C. or less.

In aspects, forming a hydroxyl-modified layer (e.g., as part of the coated article) can comprise impinging a substrate with a plasma in a chamber. Properties of the hydroxyl-modified layer can be controlled by the chamber pressure during the impinging, the gaseous environment during the impinging, the duration of treatment, and/or the power of the plasma. For silica surfaces, the plasma impacted surface layer of the article may possess a high concentration of silanol groups which allows the surface to be readily modified to form a surface-modifying layer, such as a silane-based easy to clean (ETC) coatings (non-fluorinated or perfluorinated) on the hydroxyl-modified layer. The combination of the reduced roughness and good ETC bonding leads to enhanced abrasion performance in terms of steel wool, rubber abrasion, and cheese cloth abrasion durability of the coated articles formed therefrom. For a radio frequency plasma operating in a chamber comprising molecules or ions of oxygen, hydrogen, hydroxyl, or combinations thereof, the method can facilitate the breaking of Si—O bonds while simultaneously or sequentially modifying the surface with hydrogen. The hydrogen plasma exposure under or immediately after oxygen plasma ion bombardment leads to the formation of a hydroxyl enriched surface layer extending into the surface. Such embodiments may reduce the surface roughness of the coated article at high spatial frequencies while minimally changing the overall thickness of the substrate and/or the coated article.

The substrate can comprise a glass-based and/or ceramic-based material, which can provide good dimensional stability, good impact resistance, and/or good puncture resistance. The glass-based and/or ceramic-based substrate can comprise one or more compressive stress regions, which can further provide increased impact resistance and/or increased puncture resistance.

Some example aspects of the disclosure are described below with the understanding that any of the features of the various aspects may be used alone or in combination with one another.

Aspect 1. A coated article comprising:
a substrate comprising a first major surface, the substrate comprising a glass-based material, a glass-ceramic material, or a ceramic-based material;
a planarization layer disposed on the first major surface, the planarization layer comprising a thickness between a first surface area and a second surface area opposite the first surface area from about 10 nanometers to about 600 nanometers, the second surface area facing the first major surface, the planarization layer comprises a silica or a silica-like network comprising Si—O—Si—O bonds, and the planarization layer comprises a molar ratio of hydrogen to silicon of about 0.2 or more;
a surface-modifying layer disposed on the first surface area of the planarization layer.

Aspect 2. The coated article of aspect 1, wherein the thickness of the planarization layer is from about 20 nanometers to about 100 nanometers.

Aspect 3. The coated article of any one of aspects 1-2, wherein the molar ratio of hydrogen to silicon in the planarization layer is from 0.2 to 0.4.

Aspect 4. The coated article of any one of aspects 1-2, wherein the molar ratio of hydrogen to silicon is from 0.22 to 0.35.

Aspect 5. The coated article of any one of aspects 1-2, wherein the planarization layer exhibits a ratio of hydroxyl groups to Si—O—Si bonds from 0.005 to 0.06.

Aspect 6. The coated article of any one of aspects 1-2, wherein the planarization layer exhibits a ratio of hydroxyl groups to Si—O—Si bonds in the planarization layer greater than a corresponding ratio of hydroxyl groups to Si—O—Si bonds in a reactively sputtered silica layer by a multiple from 2 to 20.

Aspect 7. The coated article of any one of aspects 1-6, wherein the planarization layer has a 2D isotropic power spectral density of AFM height data at the first surface area of the planarization layer with a value of about 500 nm4 or less at a spatial frequency of 30 μm⁻¹.

Aspect 8. The coated article of any one of aspects 1-6, wherein the planarization layer has a 2D isotropic power spectral density of AFM height data at the first surface area of the planarization layer with a ratio of a first value at a first spatial frequency of 30 μm⁻¹ divided by a second value at a second spatial frequency of 10 μm⁻¹ that is less than 0.55.

Aspect 9. The coated article of aspect 8, wherein the ratio of the first value at the first spatial frequency of 30 μm⁻¹ divided by the second value at the second spatial frequency of 10 μm⁻¹ is from 0.3 to 0.5.

Aspect 10. The coated article of any one of aspects 1-9, wherein the first surface area of the planarization layer exhibits a surface roughness Ra from 0.1 nanometers to 3.0 nanometers.

Aspect 11. The coated article of aspect 10, wherein the surface roughness Ra of the planarization layer is from 0.15 to 0.4 nanometers.

Aspect 12. The coated article of any one of aspects 1-9, wherein a ratio of a surface roughness Ra of the first surface area of the planarization layer divided by a surface roughness Ra of a surface in contact with the first surface area is about 0.9 or less.

Aspect 13. The coated article of any one of aspects 1-12, wherein the planarization layer exhibits an elastic modulus from about 35 GigaPascals to about 70 GigaPascals.

Aspect 14. The coated article of any one of aspects 1-13, wherein the planarization layer exhibits a hardness from about 3 GigaPascals to about 8 GigaPascals as measured by a Berkovich Indenter Hardness test.

Aspect 15. The coated article of any one of aspects 1-14, wherein the planarization layer comprises a refractive index from 1.46 to 1.49 at an optical wavelength of 550 nanometers.

Aspect 16. The coated article of any one of aspects 1-15, wherein the surface-modifying layer comprising an exterior surface of the coated article, and the coated article exhibits:
a water contact angle from 90° to 120°; and
a coefficient of friction of the exterior surface of 0.25 or less.

Aspect 17. The coated article of any one of aspects 1-16, wherein a surface-modifying thickness of the surface-modifying layer is from 1 nanometer to 75 nanometers.

Aspect 18. The coated article of any one of aspects 1-17, wherein the surface-modifying layer exhibits an abraded water contact angle of about 90° or more after being abraded for 3,000 cycles in a Steel Wool Abrasion test.

Aspect 19. The coated article of any one of aspects 1-18, wherein the surface-modifying layer exhibits a cheesecloth-abraded water contact angle of about 80° or more after being subjected to 200,000 cycles of in a Cheesecloth Abrasion Test.

Aspect 20. The coated article of any one of aspects 1-19, further comprising an anti-reflective coating positioned between the planarization layer and the substrate.

Aspect 21. The coated article of any one of aspects 1-20, further comprising a gradient coating comprising a refractive index gradient positioned between the planarization layer and the substrate.

Aspect 22. The coated article of any one of aspects 1-21, further comprising an optical stack positioned between the planarization layer and the substrate, wherein the optical stack comprises an anti-reflective coating, a band-pass filter coating, an edge neutral mirror, a beam splitter coating, a multi-layer high-reflectance coating, or an edge filter coating.

Aspect 23. The coated article of aspect 22, wherein the optical stack has a stack thickness is from about 10 nanometers to about 10 micrometers.

Aspect 24. The coated article of aspect 23, wherein the stack thickness of the optical stack is from about 50 nanometers to about 5 micrometers.

Aspect 25. The coated article of any one of aspects 23-24, wherein the stack thickness of the optical stack is from about 50 nanometers to about 500 nanometers.

Aspect 26. The coated article of any one of aspects 22-25, wherein the optical stack comprises a scratch resistant layer, and the scratch resistant layer has a scratch-resistant thickness from 0.05 micrometers to 3 micrometers.

Aspect 27. The coated article of any one of aspects 22-26, wherein the coated article including the optical stack and the surface-modifying layer exhibits a hardness of 8 GigaPascals or greater measured by a Berkovich Indenter Hardness test.

Aspect 28. The coated article of any one of aspects 22-26, wherein the coated article including the optical stack and the surface-modifying layer exhibits a hardness of 12 GigaPascals or greater measured by a Berkovich Indenter Hardness test.

Aspect 29. The coated article of any one of aspects 22-28, wherein the optical stack comprises one or more of a silicon-containing oxide, a silicon-containing nitride, a silicon-containing oxynitride, and Nb₂O₅.

Aspect 30. The coated article of any one of aspects 22-29, wherein the optical stack comprises two or more layers with different refractive indices including at least a first low refractive index (RI) layer and a second high refractive index (RI) layer, wherein the absolute value of a difference between the first low RI layer and the second high RI layer is 0.2 or more, and further wherein the optical stack comprises one or more of a silicon-containing oxide, a silicon-containing nitride, a silicon-containing oxynitride, and Nb₂O.

Aspect 31. The coated article of any one of aspects 1-19, wherein the coated article further comprises at least one of:
an anti-reflective coating positioned between the planarization layer and the substrate;
a gradient coating positioned between the planarization layer and the substrate; or both.

Aspect 32. The coated article of aspect 31, wherein the anti-reflective coating comprises a plurality of silica and silicon nitride layers, and an anti-reflective thickness of the anti-reflective coating is from about 200 nanometers to about 3 micrometers.

Aspect 33. The coated article of any one of aspects 1-32, wherein the substrate is a textured substrate.

Aspect 34. A method of forming a coated article comprising:
evaporating a functionalized polyhedral oligomeric silsesquioxane onto a first major surface of a substrate, the functionalized polyhedral oligomeric silsesquioxane is functionalized with a C₁-C₁₀ alkyl group, a C₂-C₈ alkene group, a phenyl group, or an alkyl silyl group, or combinations thereof; and
impinging an ion beam at the first major surface of the substrate, the impinging occurs in a chamber comprising a chamber pressure ranging from about 10⁻⁴ Pascal to about 1 Pascal, the ion beam is generated using a discharge current from about 0.25 Amps to about 1 Amp, the impinging forms a planarization layer on the first major surface of the substrate, the planarization layer comprises a thickness between a first surface area and a second surface area opposite the first surface area from about 10 nanometers to about 600 nanometers,
disposing a surface-modifying layer disposed on the first surface area of the planarization layer,
wherein the planarization layer comprises a molar ratio of hydrogen to silicon of about 0.2 or more. the planarization layer comprises silica or a silica-like network comprising Si—O—Si—O bonds, the substrate comprises a glass-based material, a glass-ceramic material, or a ceramic-based material.

Aspect 35. The method of aspect 34, wherein the molar ratio of hydrogen to silicon in the planarization layer is from 0.2 to 0.4.

Aspect 36. The method of aspect 34, wherein the molar ratio of hydrogen to silicon is from 0.22 to 0.35.

Aspect 37. The method of aspect 34, wherein the planarization layer exhibits a ratio of hydroxyl groups to Si—O—Si bonds from 0.005 to 0.06.

Aspect 38. The method of aspect 34, wherein the planarization layer exhibits a ratio of hydroxyl groups to Si—O—Si bonds in the planarization layer greater than a corresponding ratio of hydroxyl groups to Si—O—Si bonds in a reactively sputtered silica layer by a multiple from 2 to 20.

Aspect 39. The method of any one of aspects 34-36, wherein the planarization layer has a 2D isotropic power spectral density of AFM height data at the first surface area of the planarization layer with a value of about 500 nm4 or less at a spatial frequency of 30 μm⁻¹.

Aspect 40. The method of any one of aspects 34-36, wherein the planarization layer has a 2D isotropic power spectral density of AFM height data at the first surface area of the planarization layer with a ratio of a first value at a first spatial frequency of 30 μm⁻¹ divided by a second value at a second spatial frequency of 10 μm⁻¹ is less than 0.55.

Aspect 41. The method of any one of aspects 34-40, wherein the first surface area of the planarization layer exhibits a surface roughness Ra from 0.1 nanometers to 3.0 nanometers.

Aspect 42. The method of any one of aspects 34-40, wherein a ratio of a surface roughness Ra of the first surface area of the planarization layer divided by a surface roughness Ra of a surface in contact with the first surface area is about 0.9 or less.

Aspect 43. The method of any one of aspects 34-42, wherein surface-modifying layer comprising an exterior surface of the coated article, and the coated article exhibits: a water contact angle from 90° to 120°; and a coefficient of friction of the first surface area of 0.25 or less.

Aspect 44. The method of any one of aspects 34-43, wherein a surface-modifying thickness of the surface-modifying layer is from 1 nanometer to 75 nanometers.

7 Aspect 45. The method of any one of aspects 40-41, wherein the surface-modifying layer exhibits an abraded water contact angle of about 90° or more after being abraded for 3,000 cycles in a Steel Wool Abrasion test.

Aspect 46. The method of any one of aspects 40-42, wherein the surface-modifying layer exhibits a cheesecloth-abraded water contact angle of about 80° or more after being subjected to 200,000 cycles of in a Cheesecloth Abrasion Test.

Aspect 47. The method of any one of aspects 34-46, wherein the planarization layer exhibits an elastic modulus from about 35 GigaPascals to about 70 GigaPascals.

Aspect 48. The method of any one of aspects 34-47, wherein, before evaporating the functionalized polyhedral oligomeric silsesquioxane, at least one of the following is disposed on the first major surface of the substrate:
an anti-reflective coating positioned between the planarization layer and the substrate;
a gradient coating positioned between the planarization layer and the substrate; or both.

Aspect 49. The method of aspect 48, wherein the anti-reflective coating comprises a plurality of silica and silicon nitride layers, and an anti-reflective thickness of the anti-reflective coating is from about 200 nanometers to about 3 micrometers.

Aspect 50. The method of any one of aspects 34-49, wherein the substrate is a textured substrate.

Aspect 51. A method of forming a coated articled comprising:
disposing a solution over a first major surface of a substrate, the solution comprising a polysilazane or a polyhedral oligomeric silsesquioxane;
heating the solution at a temperature from about 150° C. to about 400° C. for a period of time from about 5 minutes to about 120 minutes to form a planarization layer; and
disposing a surface-modifying layer disposed on the planarization layer, wherein the planarization layer comprises a molar ratio of hydrogen to silica of about 0.2 or more, the planarization layer comprises silica or a silica-like network comprising Si—O—Si—O bonds, and the substrate comprises a glass-based material, a glass-ceramic material, or a ceramic-based material.

Aspect 52. The method of aspect 51, wherein a concentration of the polysilazane or the polyhedral oligomeric silsesquioxane ranges from about 0.2 wt % to about 25 wt %.

Aspect 53. The method of any one of aspects 51-52, wherein the temperature ranges from about 150° C. to about 250° C.

Aspect 54. The method of any one of aspects 51-53, wherein the reacting comprises heating the alkyl silane at a temperature of about 80° C. to about 250° C. for a period of time from about 5 minutes to about 8 hours.

Aspect 55. The method of any one of aspects 51-54, wherein the molar ratio of hydrogen to silicon in the planarization layer is from 0.2 to 0.4.

Aspect 56. The method of any one of aspects 51-55, wherein the molar ratio of hydrogen to silicon is from 0.22 to 0.35.

Aspect 57. The method of any one of aspects 51-56, wherein the planarization layer exhibits a ratio of hydroxyl groups to Si—O—Si bonds from 0.005 to 0.06.

Aspect 58. The method of any one of aspects 51-56, wherein the planarization layer exhibits a ratio of hydroxyl groups to Si—O—Si bonds in the planarization layer greater than a corresponding ratio of hydroxyl groups to Si—O—Si bonds in a reactively sputtered silica layer by a multiple from 2 to 20.

Aspect 59. The method of any one of aspects 51-58, wherein the planarization layer has a 2D isotropic power spectral density of AFM height data at the first surface area of the planarization layer with a value of about 500 nm⁴ or less at a spatial frequency of 30 μm⁻¹.

Aspect 60. The method of any one of aspects 51-58, wherein the planarization layer has a 2D isotropic power spectral density of AFM height data at the first surface area of the planarization layer with a ratio of a first value at a first spatial frequency of 30 μm⁻¹ divided by a second value at a second spatial frequency of 10 μm⁻¹ is less than 0.55.

Aspect 61. The method of any one of claims 51-60, wherein the first surface area of the planarization layer exhibits a surface roughness Ra from 0.1 nanometers to 3.0 nanometers.

Aspect 62. The method of any one of aspects 51-60, wherein a ratio of a surface roughness Ra of the first surface area of the planarization layer divided by a surface roughness Ra of a surface in contact with the first surface area is about 0.9 or less.

Aspect 63. The method of any one of aspects 51-62, wherein surface-modifying layer comprising an exterior surface of the coated article, and the coated article exhibits:
a water contact angle from 90° to 120°; and
a coefficient of friction of the first surface area of 0.25 or less.

Aspect 64. The method of any one of aspects 51-63, wherein a surface-modifying thickness of the surface-modifying layer is from 1 nanometer to 75 nanometers.

Aspect 65. The method of any one of aspects 63-64, wherein the surface-modifying layer exhibits an abraded water contact angle of about 90° or more after being abraded for 3,000 cycles in a Steel Wool Abrasion test.

Aspect 66. The method of any one of aspects 63-65, wherein the surface-modifying layer exhibits a cheesecloth-abraded water contact angle of about 80° or more after being subjected to 200,000 cycles of in a Cheesecloth Abrasion Test.

Aspect 67. The method of any one of aspects 51-66, wherein the planarization layer exhibits an elastic modulus from about 35 GigaPascals to about 70 GigaPascals.

Aspect 68. The method of any one of aspects 51-67, wherein, before disposing the solution, at least one of the following is disposed on the first major surface of the substrate:
an anti-reflective coating positioned between the planarization layer and the substrate;
a gradient coating positioned between the planarization layer and the substrate; or both.

Aspect 69. The method of aspect 68, wherein the anti-reflective coating comprises a plurality of silica and silicon nitride layers.

Aspect 70. The method of any one of aspects 68-69, wherein an anti-reflective thickness of the anti-reflective coating is from about 200 nanometers to about 3 micrometers.

Aspect 71. The coated article of any one of aspects 1-21, wherein the substrate is a textured substrate.

Aspect 72. The coated article of aspect 71, wherein the coated article further comprises an anti-reflective coating or a gradient coating positioned between the planarization layer and the textured substrate.

Aspect 73 The coated article of any one of aspects 71-72, wherein a thickness of the anti-reflective coating is from about 200 nanometers to about 3 micrometers.

Aspect 74. The coated article of any one of aspects 1-34 or 71-73 inclusive, wherein a ratio of an ion intensity of carbon to an ion intensity of silicon as measured by secondary-ion mass-spectroscopy is about 0.01 or less.

Aspect 75. The coated article of any one of aspects 1-34 or 71-74, wherein the surface-modifying layer is an anti-fingerprint coating or an easy-to-clean coating.

Aspect 76. The method of aspect 50, wherein, before evaporating the functionalized polyhedral oligomeric silsesquioxane, the method comprises disposing an anti-reflective coating or a gradient coating on the textured substrate, and the anti-reflective coating or the gradient coating is positioned between the textured substrate and the surface-modifying layer.

Aspect 77. The method of any one of aspects 34-50 or 76 inclusive, wherein an ion intensity of carbon to an ion intensity of silicon as measured by secondary-ion mass-spectroscopy is about 0.01 or less.

Aspect 78. The method of any one of aspects 34-50 or 76-77 inclusive, wherein the surface-modifying layer comprises an anti-fingerprint coating or an easy-to-clean coating.

Aspect 79. The method of any one of aspects 51-67, wherein the substrate is a textured substrate.

Aspect 80. The method of aspect 79, wherein, before disposing the solution silsesquioxane, the method comprises disposing an anti-reflective coating or a gradient coating on the textured substrate, and the anti-reflective coating or the gradient coating is positioned between the textured substrate and the surface-modifying layer.

Aspect 81. The method of any one of claim 51-70 or 79-80 inclusive, wherein an ion intensity of carbon to an ion intensity of silicon as measured by secondary-ion mass-spectroscopy is about 0.01 or less.

Aspect 82. The method of any one of aspects 51-70 or 79-81 inclusive, wherein the surface-modifying layer comprises an anti-fingerprint coating or an easy-to-clean coating.

Aspect 83. The coated article of any one of aspects 1-34 or 71-75 inclusive, wherein the substrate comprises a polymer substrate or a metal substrate.

Aspect 84. The coated article of any one of aspects 1-34, 71-75, or 83 inclusive, wherein a ratio of a 2D isotropic power spectral density of AFM height data at the first surface area of the planarization layer at a spatial frequency of 30 μm⁻¹ divided by a a 2D isotropic power spectral density of AFM height data of a surface in contact with the first surface area at a spatial frequency of 30 μm⁻¹ is about 0.9 or less.

Aspect 85. A coated article comprising: a substrate comprising a first major surface, the substrate comprising a glass-based material, a glass-ceramic material, or a ceramic-based material, wherein the entirety of the substrate comprises a molar ratio of hydrogen to silica of about 0.2 or less; a first layer disposed on the first major surface, the first layer comprising a thickness between a first surface area and a second surface area opposite the first surface area from about 5 nanometer to about 600 nanometers, the second surface area facing the first major surface, the first layer comprises a silica or a silica-like network each comprising Si—O—Si—O bonds, Si—OH bonds, or both, and the entirety of the first layer comprises a molar ratio of hydrogen to silica of about 0.2 or more; and a surface-modifying layer disposed on the first surface area of the first layer.

Aspect 86. The coated article of aspect 85, wherein the first layer is a planarization layer comprising the Si—O—Si—O bonds.

Aspect 87. The coated article of aspect 85, wherein the first layer is a hydroxyl-modified layer comprising the Si—OH bonds.

Aspect 88. The coated article of aspect 85, wherein the first layer comprises a planarization layer comprising the Si—O—Si—O bonds and a hydroxyl-modified layer comprising the Si—OH bonds.

Aspect 89. The coated article of any one of aspects 85-88, wherein the first layer has a 2D isotropic power spectral density of AFM height data at the first surface area of the first layer with a ratio of a logarithm of a first value at a first spatial frequency of 40 μm⁺¹ divided by a logarithm of a second value at a second spatial frequency of 10 μm⁻¹ that is less than 0.4.

Aspect 90. The coated article of aspect 89, wherein the ratio is less than 0.35 or 0.3.

Aspect 91. The coated article of any one of aspects 85-90, wherein the coated article comprises an amount of excess oxygen of at least about 15%.

Aspect 92. The coated article of any one of aspects 85-91, wherein the thickness of the first layer is from about 5 nanometers to about 100 nanometers.

Aspect 93. The coated article of any one of aspects 85-92, wherein the molar ratio of hydrogen to silicon in the first layer is from 0.2 to 0.6.

Aspect 94. The coated article of any one of aspects 85-93, wherein the molar ratio of hydrogen to silicon is from 0.22 to 0.4.

Aspect 95. The coated article of any one of aspects 85-94, wherein the first layer has a 2D isotropic power spectral density of AFM height data at the first surface area of the first layer with a value of about 500 nm⁴ or less at a spatial frequency of 30 μm⁻¹.

Aspect 96. The coated article of any one of aspects 85-95, wherein the first layer has a 2D isotropic power spectral density of AFM height data at the first surface area of the first layer with a value of about 250 nm⁴ or less at a spatial frequency of 40 μm⁻¹.

Aspect 97. The coated article of any one of aspects 85-96, wherein the first surface area of the first layer exhibits a surface roughness Ra from 0.1 nanometers to 3.0 nanometers.

Aspect 98. The coated article of any one of aspects 85-97, wherein a ratio of a 2D isotropic power spectral density of AFM height data at the first surface area of the first layer at a spatial frequency of 40 μm⁻¹ divided by a 2D isotropic power spectral density of AFM height data of a surface in contact with the first surface area at a spatial frequency of 40 μm⁻¹ is about 0.9 or less.

Aspect 99. The coated article of any one of aspects 85-98, wherein a ratio of a surface roughness Ra of the first surface area of the first layer divided by a surface roughness Ra of a surface in contact with the first surface area is about 0.9 or less.

Aspect 100. The coated article of any one of aspects 85-99, wherein the first layer comprises a refractive index from 1.46 to 1.49 at an optical wavelength of 550 nanometers.

Aspect 101. The coated article of any one of aspects 85-100, wherein the surface-modifying layer is an anti-fingerprint coating or an easy-to-clean coating.

Aspect 102. The coated article of any one of aspects 85-101, wherein the surface-modifying layer comprising an exterior surface of the coated article, and the coated article exhibits:

a water contact angle from 90° to 120°; and
a coefficient of friction of the exterior surface of 0.25 or less.

Aspect 103. The coated article of any one of aspects 85-102, wherein a surface-modifying thickness of the surface-modifying layer is from 1 nanometer to 75 nanometers.

Aspect 104. The coated article of any one of aspects 85-103, wherein the surface-modifying layer exhibits an abraded water contact angle of about 90° or more after being abraded for 3,000 cycles in a Steel Wool Abrasion test.

Aspect 105. The coated article of any one of aspects 85-104, wherein the surface-modifying layer exhibits a cheesecloth-abraded water contact angle of about 80° or more after being subjected to 200,000 cycles of in a Cheesecloth Abrasion Test.

Aspect 106. The coated article of any one of aspects 85-105, further comprising an anti-reflective coating positioned between the first layer and the substrate.

Aspect 107. The coated article of any one of aspects 85-106, further comprising a gradient coating comprising a refractive index gradient positioned between the first layer and the substrate.

Aspect 108. The coated article of any one of aspects 85-107, further comprising an optical stack positioned between the first layer and the substrate, wherein the optical stack comprises an anti-reflective coating, a band-pass filter coating, an edge neutral mirror, a beam splitter coating, a multi-layer high-reflectance coating, or an edge filter coating.

Aspect 109. The coated article of aspect 108, wherein the optical stack has a stack thickness is from about 10 nanometers to about 10 micrometers.

Aspect 110. The coated article of aspect 109, wherein the stack thickness of the optical stack is from about 50 nanometers to about 5 micrometers.

Aspect 111. The coated article of any one of aspects 109-110, wherein the stack thickness of the optical stack is from about 50 nanometers to about 500 nanometers.

Aspect 112. The coated article of any one of aspects 108-111, wherein the optical stack comprises a scratch resistant layer, and the scratch resistant layer has a scratch-resistant thickness from 0.05 micrometers to 3 micrometers.

Aspect 113. The coated article of any one of aspects 108-112, wherein the coated article including the optical stack and the surface-modifying layer exhibits a hardness of 8 GigaPascals or greater measured by a Berkovich Indenter Hardness test.

Aspect 114. The coated article of any one of aspects 108-113, wherein the coated article including the optical stack and the surface-modifying layer exhibits a hardness of 12 GigaPascals or greater measured by a Berkovich Indenter Hardness test.

Aspect 115. The coated article of any one of aspects 108-114, wherein the optical stack comprises one or more of a silicon-containing oxide, a silicon-containing nitride, a silicon-containing oxynitride, and Nb₂O₅.

Aspect 116. The coated article of any one of aspects 108-115, wherein the optical stack comprises two or more layers with different refractive indices including at least a first low refractive index (RI) layer and a second high refractive index (RI) layer, wherein the absolute value of a difference between the first low RI layer and the second high RI layer is 0.2 or more, and further wherein the optical stack comprises one or more of a silicon-containing oxide, a silicon-containing nitride, a silicon-containing oxynitride, and Nb₂O.

Aspect 117. The coated article of any one of aspects 85-116, wherein the substrate is a textured substrate.

Aspect 118. The coated article of aspect 117, wherein the coated article further comprises an anti-reflective coating or a gradient coating positioned between the first layer and the textured substrate.

Aspect 119. The coated article of aspect 118, wherein a thickness of the anti-reflective coating is from about 200 nanometers to about 3 micrometers.

Aspect 120. The coated article of any one of aspects 85-119, wherein the substrate comprises a polymer substrate or a metal substrate.

Aspect 121. A method of forming a coated article comprising:
impinging a plasma at a first major surface of a substrate, wherein: the impinging occurs in a chamber comprising a chamber pressure ranging from about 1 Pascal to about 100 Pascal;
the chamber comprises molecules or ions of oxygen, hydrogen, hydroxyl, or combinations thereof; the impinging forms a hydroxyl-modified layer on the first major surface of the substrate; and the hydroxyl-modified layer comprises a thickness between a first surface area and a second surface area opposite the first surface area from about 5 nanometers to about 100 nanometers; disposing a surface-modifying layer over the first surface area of the hydroxyl-modified layer, wherein: the hydroxyl-modified layer comprises a molar ratio of hydrogen to silica of about 0.2 or more; and the hydroxyl-modified layer comprises silica or a silica-like network comprising Si—OH bonds.

Aspect 122. The method of aspect 121, wherein the substrate comprises a glass-based material, a glass-ceramic material, or a ceramic-based material.

Aspect 123. The method of any one of aspects 121-122, wherein the substrate comprises a polymer substrate or a metal substrate.

Aspect 124. The method of any one of aspects 121-123, wherein water vapor is introduced into the chamber to produce the molecules or ions of oxygen, hydrogen, hydroxyl, or combinations thereof.

Aspect 125. The method of any one of aspects 121-123, wherein O₂ is introduced into the chamber for a first duration of time, and H₂ is introduced into the chamber for a second duration of time.

Aspect 126. The method of aspect 125, wherein during the first duration of time, a concentration of O₂ in the chamber is at least 60 mol. % relative to a total volume of gases in the chamber.

Aspect 127. The method of any one of aspects 125-126, wherein during the second duration of time, a concentration of H₂ in the chamber is at least 60 mol. % relative to a total volume of gases in the chamber.

Aspect 128. The method of any one of aspects 121-127, wherein the plasma is a radio frequency plasma having an areal power density of at least 0.2 W/cm².

Aspect 129. The method of any one of aspects 121-128, wherein the plasma is a radio frequency plasma having an areal power density of less than or equal to about 5 W/cm².

Aspect 130. The method of any one of aspects 128-129, wherein the areal power density of greater than or equal to about 0.4 W/cm² and less than or equal to about 1 W/cm².

Aspect 131. The method of any one of aspects 121-130, wherein a duration of the impinging the plasma at the first major surface of the substrate is for a treatment time of greater than or equal to about 10 seconds and less than or equal to about 30 minutes.

Aspect 132. The method of aspect 131, wherein the treatment time is greater than or equal to about 45 seconds and less than or equal to about 10 minutes.

Aspect 133. The method of any one of aspects 121-132, wherein a temperature of the chamber during the impinging the plasma at the first major surface of the substrate is greater than or equal to about 10° C. and less than or equal to about 200° C.

Aspect 134. The method of any one of aspects 121-133, wherein prior to impinging the plasma at the first major surface of the substrate, a thickness of the substrate is an initial thickness, and subsequent to impinging the plasma at the first major surface of the substrate a combined thickness of the substrate and the hydroxyl-modified layer is a modified thickness, and a difference between the initial thickness and the modified thickness is less than or equal to about 10 nm.

Aspect 135. The method of any one of aspects 121-134, wherein the first layer has a 2D isotropic power spectral density of AFM height data at the first surface area of the first layer with a ratio of a logarithm of a first value at a first spatial frequency of 40 μm⁻¹ divided by a logarithm of a second value at a second spatial frequency of 10 μm⁻¹ that is less than 0.4.

Aspect 136. The method of any one of aspects 121-135, wherein a ratio of a 2D isotropic power spectral density of AFM height data at the first surface area of the first layer at a spatial frequency of 40 μm⁻¹ divided by a 2D isotropic power spectral density of AFM height data of a surface in contact with the first surface area at a spatial frequency of 40 μm⁻¹ is about 0.9 or less.

Aspect 137. The method of any one of aspects 121-136, wherein the coated article comprises an amount of excess oxygen of at least about 15%.

### BRIEF DESCRIPTION OF THE DRAWINGS

The above and other features and advantages of aspects of the present disclosure are better understood when the following detailed description is read with reference to the accompanying drawings, in which:

FIGS. 1 and 2A-2C are schematic views of exemplary coated articles according to aspects;

FIG. 3 is a schematic plan view of an example consumer electronic device according to aspects;

FIG. 4 is a schematic perspective view of the example consumer electronic device of FIG. 3;

FIG. 5 schematically illustrates a functionalized polyhedral oligomeric silsesquioxane (POSS) compound;

FIG. 6 schematically illustrates a reaction of polysilazane (PHPS);

FIG. 7 is a flow chart illustrating example methods of making coated articles in accordance with aspects of the disclosure;

FIG. 8 schematically illustrates a step(s) in methods of making a coated article comprising evaporating a functionalized POSS and impinging an ion beam on a first major surface of a substrate;

FIG. 9 schematically illustrates a step in methods of making a coated article comprising disposing a solution over a first major surface of a substrate;

FIG. 10 schematically illustrates a step in methods of making a coated article comprising heating the solution on the first major surface;

FIG. 11 schematically illustrates a step in methods of making a coated article comprising disposing a surface-modifying layer on a planarization surface;

FIG. 12 schematically illustrates refractive index (left-side vertical axis-y-axis on left) and extinction coefficient (right-side vertical axis-y-axis on right) as a function of deposition rate (horizontal axis-x-axis) for Examples 1-5;

FIG. 13 schematically illustrates elastic modulus in GPa (left-side vertical axis-y-axis on left) and hardness in GPa (right-side vertical axis-y-axis on right) as a function of deposition rate in A/s for Examples 1-5;

FIGS. 14-16 schematically illustrate infrared (IR) absorption spectra for Examples 6-10 with the horizontal axis (x-axis) corresponding to wavenumber (cm⁻¹) and the vertical axis (y-axis) corresponding to normalized absorbance;

FIG. 17 schematically illustrates a molar ratio of hydrogen to silicon on the vertical axis (y-axis) as a function of deposition rate in A/s on the horizontal axis (x-axis) for Examples 6-10;

FIG. 18 schematically illustrates surface roughness Ra in nanometers on the vertical axis (y-axis) as a function of layer thickness in nanometers on the horizontal axis (x-axis) for Example 11 and Comparative Examples BB-CC;

FIG. 19 schematically illustrates a relationship between a steel-wool abraded water contact angle (°) on the vertical axis (y-axis) and a surface roughness Ra after steel wool abrasion in the Steel Wool Abrasion Test in nanometers on the horizontal axis (x-axis) for Examples 20-22 and Comparative Example AA;

FIG. 20 schematically illustrates a relationship between a surface roughness Ra of a layer in nanometers on the vertical axis (y-axis) as a function of the underlying substrate surface roughness Ra in nanometers on the horizontal axis (x-axis) and deposition rate (curves) for Examples 12-16 and Comparative Example BB;

FIG. 21 schematically illustrates a relationship between a surface roughness Ra of a layer in nanometers on the vertical axis (y-axis) as a function of the underlying substrate surface roughness Ra in nanometers on the horizontal axis (x-axis) and layer thickness (curves) for Examples 17-19 and Comparative Example BB;

FIG. 22 illustrates atomic force microscopy (AFM) images of reactively sputtered silica for Examples 20-22 and Comparative Example AA;

FIGS. 23-25 illustrate atomic force microscopy (AFM) images of planarization layers in accordance with aspects of the disclosure for Examples 23-31 and Comparative Examples DD-FF;

FIG. 26 illustrates logarithms of two-dimensional (2D) power spectral density (PSD) distributions on the vertical axis (y-axis) as a function of spatial frequency in μm⁻¹ on the horizontal axis (x-axis) for Comparative Examples AA and GG-II;

FIG. 27 illustrates logarithms of two-dimensional (2D) power spectral density (PSD) distributions on the vertical axis (y-axis) as a function of spatial frequency in μm⁻¹ on the horizontal axis (x-axis) for Examples 32-34 and Comparative Example II;

FIG. 28 illustrates water contact angles (°) on the vertical axis (y-axis) in a Steel Wool Abrasion Test for Assemblies A-T along the horizontal axis (x-axis);

FIG. 29 illustrates water contact angles (°) on the vertical axis (y-axis) in a Steel Wool Abrasion Test for Assemblies AAA-DDD along the horizontal axis (x-axis);

FIG. 30 illustrates water contact angles (°) on the vertical axis (y-axis) in a Steel Wool Abrasion Test for Assemblies EEE-HHH along the horizontal axis (x-axis);

FIG. 31 schematically illustrates water contact angles (°) on the vertical axis (y-axis) in a Cheesecloth Abrasion Test for Assemblies III-JJJ along the horizontal axis (x-axis);

FIG. 32 schematically illustrates molar ratios of hydrogen to silicon as measured by dynamic secondary-ion mass spectrometry (D-SIMS) on the vertical axis (y-axis) for Examples 35-44 and JJ-KK along the horizontal axis (x-axis);

FIG. 33 schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Comparative Example JJ;

FIG. 34 schematically illustrates compositional profiles relative to an amount of silicon as measured by dynamic SIMS (D-SIMS) on the vertical axis (y-axis) as a function of a distance from the surface in nanometers on the horizontal axis (x-axis) for Comparative Example LL;

FIG. 35 schematically illustrates compositional profiles relative to an amount of silicon as measured by dynamic SIMS (D-SIMS) on the vertical axis (y-axis) as a function of a distance from the surface in nanometers on the horizontal axis (x-axis) for Example 37;

FIG. 36 schematically illustrates compositional profiles relative to an amount of silicon as measured by dynamic SIMS (D-SIMS) on the vertical axis (y-axis) as a function of a distance from the surface in nanometers on the horizontal axis (x-axis) for Example 41;

FIG. 37 schematically illustrates logarithms of two-dimensional (2D) power spectral density (PSD) distributions on the vertical axis (y-axis) as a function of spatial frequencies (μm⁻¹) on the horizontal axis (x-axis) for Assemblies AAA, BBB, and DDD without the easy-to-clean coating; and

FIG. 38 schematically illustrates logarithms of two-dimensional (2D) power spectral density (PSD) distributions on the vertical axis (y-axis) as a function of spatial frequencies (μm⁻¹) on the horizontal axis (x-axis) for Assemblies AAA, BBB, and DDD without the easy-to-clean coating for Assemblies EEE-HHH without the easy-to-clean coating;

FIG. 39 schematically illustrates logarithms of two-dimensional (2D) power spectral density (PSD) distributions on the vertical axis (y-axis) as a function of spatial frequencies (μm⁻¹) on the horizontal axis (x-axis) for Examples 45-49 and Comparative Examples LL and MM;

FIG. 40A schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Comparative Example MM;

FIG. 40B schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Example 50;

FIG. 41 schematically illustrates elemental composition analysis in atomic % as measured by X-ray photoelectron spectroscopy (XPS) on the vertical axis (y-axis) for carbon, oxygen, aluminum, silicon, chlorine, and calcium present on the surface of Comparative Example MM and Example 50;

FIG. 42 schematically illustrates an atomic % of excess oxygen as measured by X-ray photoelectron spectroscopy (XPS) on the vertical axis (y-axis) present on the surface of Comparative Example MM and Example 50;

FIG. 43 illustrates water contact angles (°) on the vertical axis (y-axis) in a Rubber Abrasion Test for Comparative Examples NN-RR and Examples 53-57 along the horizontal axis (x-axis);

FIG. 44 illustrates water contact angles (°) on the vertical axis (y-axis) in a Steel Wool Abrasion Test for Comparative Examples NN-RR and Examples 53-57 along the horizontal axis (x-axis);

FIG. 45 illustrates water contact angles (°) on the vertical axis (y-axis) in a Cheesecloth Abrasion Test for C₂ treated with Branson O₂ activation and 2:1 H₂: O₂ plasma treatment Ex along the horizontal axis (x-axis);

FIG. 46A schematically illustrates logarithms of two-dimensional (2D) power spectral density (PSD) distributions on the vertical axis (y-axis) as a function of spatial frequencies (μm⁻¹) on the horizontal axis (x-axis) for Comparative Examples MM, NN, SS, and TT;

FIG. 46B schematically illustrates logarithms of two-dimensional (2D) power spectral density (PSD) distributions on the vertical axis (y-axis) as a function of spatial frequencies (μm⁻¹) on the horizontal axis (x-axis) for Comparative Examples MM, NN, and SS, and Examples 58-60;

FIG. 47A schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Comparative Example MM;

FIG. 47B schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Comparative Example UU;

FIG. 47C schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Example 61;

FIG. 48 schematically illustrates elemental composition analysis in atomic % as measured by X-ray photoelectron spectroscopy (XPS) on the vertical axis (y-axis) for carbon, nitrogen, oxygen, fluorine, aluminum, and silicon on the x-axis present on the surface of Comparative Example MM, UU, and Example 61;

FIG. 49 schematically illustrates an atomic % of excess oxygen as measured by X-ray photoelectron spectroscopy (XPS) on the vertical axis (y-axis) present on the surface of Comparative Example MM, UU and Example 61;

FIG. 50 illustrates water contact angles (°) on the vertical axis (y-axis) in a Rubber Abrasion Test for Examples 62-71 along the horizontal axis (x-axis);

FIG. 51 illustrates water contact angles (°) on the vertical axis (y-axis) in a Cheesecloth Abrasion Test for sequential O₂—H₂ plasma treatment and simultaneous 2:1 H₂-O₂ plasma treatment along the horizontal axis (x-axis);

FIG. 52A schematically illustrates logarithms of two-dimensional (2D) power spectral density (PSD) distributions on the vertical axis (y-axis) as a function of spatial frequencies (μm⁻¹) on the horizontal axis (x-axis) for GG3, and Examples 75-79;

FIG. 52B schematically illustrates logarithms of two-dimensional (2D) power spectral density (PSD) distributions on the vertical axis (y-axis) as a function of spatial frequencies (μm⁻¹) on the horizontal axis (x-axis) for GG3, and Examples 72-74;

FIG. 53 schematically illustrates logarithms of two-dimensional (2D) power spectral density (PSD) distributions on the vertical axis (y-axis) as a function of spatial frequencies (μm⁻¹) on the horizontal axis (x-axis) for GG3, 579 nm SiO₂ on GG3, and Examples 82-83 and 86-87;

FIG. 54A schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Comparative Example MM;

FIG. 54B schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Example 89;

FIG. 55A schematically illustrates elemental composition analysis in atomic % as measured by X-ray photoelectron spectroscopy (XPS) on the vertical axis (y-axis) for carbon, oxygen, aluminum, silicon, chlorine, and calcium on the x-axis present on the surface of Comparative Example MM and Example 89;

FIG. 55B schematically illustrates an atomic % of excess oxygen as measured by X-ray photoelectron spectroscopy (XPS) on the vertical axis (y-axis) present on the surface of Comparative Example MM and Example 89;

FIG. 56 illustrates water contact angles (°) on the vertical axis (y-axis) in a Rubber Abrasion Test for Examples 90-94 along the horizontal axis (x-axis);

FIG. 57 schematically illustrates logarithms of two-dimensional (2D) power spectral density (PSD) distributions on the vertical axis (y-axis) as a function of spatial frequencies (μm⁻¹) on the horizontal axis (x-axis) for Examples 90-94;

FIG. 58 schematically illustrates logarithms of two-dimensional (2D) power spectral density (PSD) distributions on the vertical axis (y-axis) as a function of spatial frequencies (μm⁻¹) on the horizontal axis (x-axis) for GG3, 860 nm SiO₂ on GG3, and Examples 96, 99-100, and 102-104;

FIG. 59A schematically illustrates compositional profiles relative to signal intensity of silicon as measured by dynamic SIMS (D-SIMS) on the vertical axis (y-axis) as a function of a distance from the surface in nanometers on the horizontal axis (x-axis) for 400 nm SiO₂ on GG3;

FIG. 59B schematically illustrates compositional profiles relative to signal intensity of silicon as measured by dynamic SIMS (D-SIMS) on the vertical axis (y-axis) as a function of a distance from the surface in nanometers on the horizontal axis (x-axis) for Example 104;

FIG. 60 schematically illustrates elemental composition analysis in atomic % as measured by X-ray photoelectron spectroscopy (XPS) on the vertical axis (y-axis) for carbon, oxygen, fluorine, aluminum, and silicon on the x-axis present on the surface of 400 nm SiO₂ on GG3 and Example 104;

FIG. 61 schematically illustrates an atomic % of excess oxygen as measured by X-ray photoelectron spectroscopy (XPS) on the vertical axis (y-axis) present on the surface of 400 nm SiO₂ on GG3 and Example 104;

FIG. 62 schematically illustrates logarithms of two-dimensional (2D) power spectral density (PSD) distributions on the vertical axis (y-axis) as a function of spatial frequencies (μm⁻¹) on the horizontal axis (x-axis) for GG3, C₁, and Examples 105-107;

FIG. 63 illustrates water contact angles (°) on the vertical axis (y-axis) in a Rubber Abrasion Test for Examples 105-107 along the horizontal axis (x-axis);

FIG. 64A illustrates a hydrogen to silicon molar ratio at the surface of the examples on the vertical axis (y-axis) for various methods disclosed herein along the horizontal axis (x-axis); and

FIG. 64B illustrates a hydrogen to silicon molar ratio at the bulk/steady state of the examples on the vertical axis (y-axis) for various methods disclosed herein along the horizontal axis (x-axis).

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts.

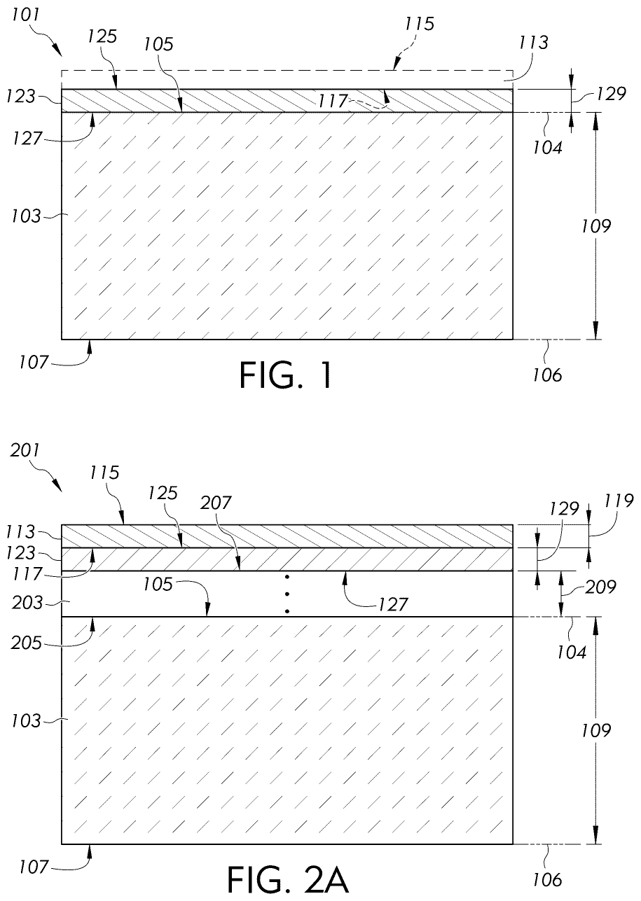

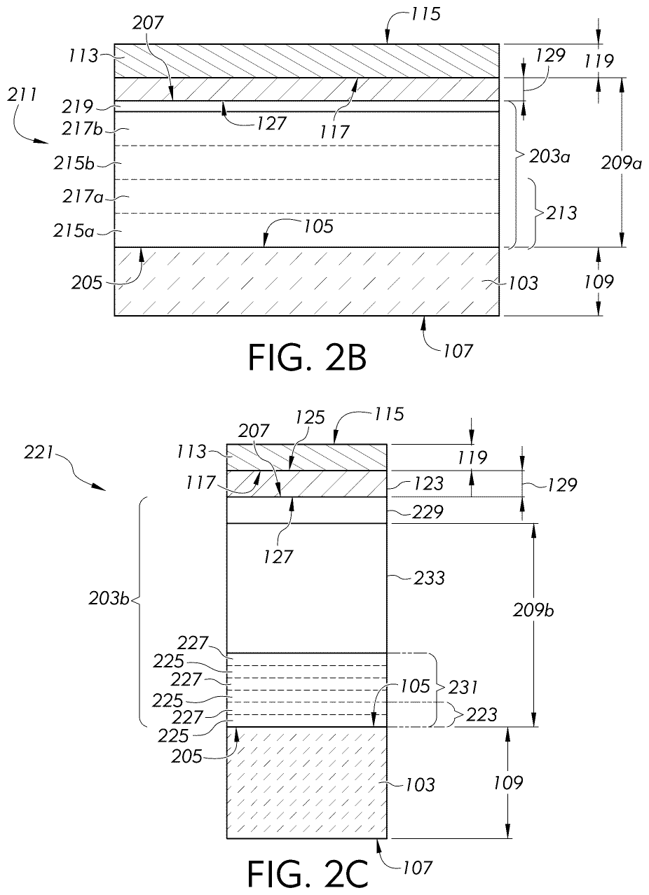

FIGS. 1 and 2A-2C illustrate views of a coated article 101, 201, 211, or 221 comprising a first layer 123 (e.g. planarization layer 123 and/or hydroxyl-modified layer 123) disposed over a substrate 103 in accordance with aspects of the disclosure. In aspects, as shown, the coated article the coated article 101, 201, 211, or 221 further comprises a surface-modifying layer 113 disposed on the first layer 123 with the first layer 123 positioned between surface-modifying layer 113 and the substrate 103. In aspects, as shown in FIGS. 2A-2C, the coated article 201, 211, and/or 221 can comprise an optical stack 203, 203a, and/or 203b, an optical film 231, and/or a scratch-resistant layer 233 that can impart increased hardness, an anti-glare property, an anti-reflection property, or combinations thereof to the coated article. Unless otherwise noted, a discussion of features of aspects of one first layer or coated article can apply equally to corresponding features of any aspects of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

As shown in FIGS. 1 and 2A-2C, the substrate 103 comprises a first major surface 105 and a second major surface 107 opposite the first major surface 105. As shown, the first major surface 105 can extend along a first plane 104, and/or the second major surface 107 can extend along a second plane 106. In aspects, as shown, the second plane 106 can be parallel to the first plane 104. As used herein, a substrate thickness 109 is defined between the first major surface 105 and the second major surface 107 as a distance between the first plane 104 and the second plane 106. In aspects, the substrate thickness 109 can be about 10 micrometers (μm) or more, about 25 μm or more, about 40 μm or more, about 60 μm or more, about 70 μm or more, about 80 μm or more, about 90 μm or more, about 100 μm or more, about 125 μm or more, about 150 μm or more, about 200 μm or more, about 300 μm or more, about 2 millimeters (mm) or less, about 1 mm or less, about 800 μm or less, about 500 μm or less, about 300 μm or less, about 200 μm or less, about 180 μm or less, or about 160 μm or less. In aspects, the substrate thickness 109 can range from about 10 μm to about 2 mm, from about 25 μm to about 2 mm, from about 40 μm to about 2 mm, from about 60 μm to about 2 mm, from about 70 μm to about 2 mm, from about 70 μm to about 1 mm, from about 70 μm to about 800 μm, from about 80 μm to about 500 μm, from about 90 μm 500 μm, from about 100 μm to about 200 μm, from about 125 μm to about 200 μm, from about 150 μm to about 200 μm, from about 150 μm to about 160 μm, or any range or subrange therebetween. Alternatively, the substrate thickness 109 can be from about 1 millimeter (mm) to about 5 mm, from about 1 mm to about 3 mm, or any range or subrange therebetween.

The substrate 103 can comprise a glass-based material, a glass-ceramic, a ceramic-based material, a metal material and/or a polymeric material, for example, having a pencil hardness of 8H or more, (e.g., 9H or more). As used herein, pencil hardness is measured using ASTM D 3363-20 with standard lead graded pencils. Providing a glass-based substrate and/or a ceramic-based substrate can enhance puncture resistance and/or impact resistance. As used herein, “glass-based” includes both glasses and glass-ceramics, wherein glass-ceramics have one or more crystalline phases and an amorphous, residual glass phase. A glass-based material may comprise an amorphous material (e.g., glass) and optionally one or more crystalline materials (e.g., ceramic). Exemplary glass-based materials may be an alkali-free glass and/or comprise a low content of alkali metals (e.g., R₂O of about 10 mol % or less, wherein R₂O comprises Li₂O Na₂O, and K₂O). As used herein, “ceramic-based” includes both ceramics and glass-ceramics, wherein glass-ceramics have one or more crystalline phases and an amorphous, residual glass phase. In aspects, ceramic-based materials can comprise one or more oxides, nitrides, oxynitrides, carbides, borides, and/or silicides. Throughout the disclosure, the Young's modulus of the glass-based materials, glass-ceramics, and ceramic-based materials are measured using the resonant ultrasonic spectroscopy technique set forth in ASTM E2001-13, titled “Standard Guide for Resonant Ultrasound Spectroscopy for Defect Detection in Both Metallic and Non-metallic Parts.” In aspects, the substrate 103 can comprise an elastic modulus ranging from about 10 GPa to about 100 GPa, from about 40 GPa to about 100 GPa, from about 60 GPa to about 100 GPa, from about 60 GPa to about 80 GPa, from about 80 GPa to about 100 GPa, or any range or subrange therebetween.

The substrate 103 may include an inorganic material with amorphous and crystalline portions. The substrate 103 may be formed from man-made materials and/or naturally occurring materials (e.g., quartz). In some specific embodiments, the substrate 103 may specifically exclude polymeric, plastic and/or metal substrates. The substrate 103 may be characterized as an alkali-including substrate (i.e., the substrate includes one or more alkalis). In one or more embodiments, the substrate 103 exhibits a refractive index in the range from about 1.5 to about 1.6. In specific embodiments, the substrate 103 (e.g., a strengthened glass-ceramic substrate) may exhibit an average strain-to-failure at the first major surface 105 and/or the second major surface 107 that is 0.5% or greater, 0.6% or greater, 0.7% or greater, 0.8% or greater, 0.9% or greater, 1% or greater, 1.1% or greater, 1.2% or greater, 1.3% or greater, 1.4% or greater, 1.5% or greater or even 2% or greater, as measured using an ROR Test using at least 5, at least 10, at least 15, or at least 20 samples to determine the average strain-to-failure value. In specific embodiments, the substrate 103 may exhibit an average strain-to-failure at its surface on one or more opposing primary surfaces 112, 114 of about 1.2%, about 1.4%, about 1.6%, about 1.8%, about 2.2%, about 2.4%, about 2.6%, about 2.8%, or about 3% or greater.

The term “strain-to-failure” refers to the strain at which cracks propagate in one or more layers of the coated article, such as the first layer 123, the surface-modifying layer 113, the substrate 103, or combinations thereof simultaneously without application of additional load, typically leading to catastrophic failure in a given material, layer or film and perhaps even bridge to another material, layer, or film, as defined herein. That is, breakage of one or more layers of the coated article without breakage of the substrate 103 constitutes failure, and breakage of the substrate 103 also constitutes failure. The term “average” when used in connection with average strain-to-failure or any other property is based on the mathematical average of measurements of such property on 5 samples. Typically, crack onset strain measurements are repeatable under normal laboratory conditions, and the standard deviation of crack onset strain measured in multiple samples may be as little as 0.01% of observed strain. Average strain-to-failure as used herein was measured using an ROR Test. However, unless stated otherwise, strain-to-failure measurements described herein refer to measurements from the ring-on-ring testing, as described in International Publication No. WO2018/125676, published on Jul. 5, 2018, entitled “Coated Articles with Optical Coatings Having Residual Compressive Stress,” and incorporated herein by reference in its entirety.

Suitable glass-ceramic substrates 103 may exhibit an elastic modulus (or Young's modulus) in the range from about 60 GPa to about 130 GPa. In some instances, the elastic modulus of the glass-ceramic substrate 103 may be in the range from about 70 GPa to about 120 GPa, from about 80 GPa to about 110 GPa, from about 80 GPa to about 100 GPa, from about 80 GPa to about 90 GPa, from about 85 GPa to about 110 GPa, from about 85 GPa to about 105 GPa, from about 85 GPa to about 100 GPa, from about 85 GPa to about 95 GPa, and all ranges and sub-ranges therebetween (e.g., ˜103 GPa). In some implementations, the elastic modulus of the glass-ceramic substrate 103 may be greater than 85 GPa, greater than 90 GPa, greater than 95 GPa, or even greater than 100 GPa. In some examples, Young's modulus may be measured by sonic resonance (ASTM E1875), resonant ultrasound spectroscopy, or nanoindentation using Berkovich indenters. Further, suitable glass-ceramic substrates 103 may exhibit a shear modulus in the range from about 20 GPa to about 60 GPa, from about 25 GPa to about 55 GPa, from about 30 GPa to about 50 GPa, from about 35 GPa to about 50 GPa, and shear modulus ranges and sub-ranges therebetween (e.g., ˜43 GPa). In some implementations, the glass-ceramic substrate 103 may have a shear modulus of greater than 35 GPa, or even greater than 40 GPa. Further, the glass-ceramic substrates 103 can exhibit a fracture toughness of greater than 0.8 MPa·√m, greater than 0.9 MPa·√m, greater than 1 MPa·√Vm, or even greater than 1.1 MPa·m in some instances (e.g., ˜1.15 MPa·√m).

According to some embodiments, the glass-ceramic substrate 103 can have the following composition: 55-75 mol % SiO₂; 0.2-10 mol % Al₂O₃; 0.2-3 mol % P₂O₅; 0-5 mol % B₂O₃; 15-30 mol % Li₂O; 0-2 mol % Na₂O; 0-2 mol % K₂O; 0-2 mol % MgO; 0-2 mol % ZnO; 0.1-10 mol % ZrO₂; 0-4 mol % TiO₂; 0.01-1.0 mol % SnO₂; and 0-2 mol % Y₂O₃. According to an embodiment, the glass-ceramic substrate 103 can consist essentially of the following composition: 68-72 mol % SiO₂; 3-5 mol % Al₂O₃; 0.6-1.2 mol % P₂O₅; 0-5 mol % B203; 17-25 mol % Li₂O; 0.01-1.7 mol % Na₂O; 0.01-0.5 mol % K₂O; 1.5-3 mol % ZrO₂; 0.01-0.1 mol % SnO₂; 0.01-0.1 mol % HfO₂; and 0.01-0.5 mol % Fe₂O₃ (exemplary compositions are listed below in Table 1, as measured prior to any ceramming step).

In one or more embodiments, the glass-ceramic substrate 103 includes one or more glass-ceramic materials and may be strengthened or non-strengthened. In one or more embodiments, the substrates 103 as a glass-ceramic material may comprise one or more crystalline phases such as lithium disilicate (Li₂Si₂O₅), lithium metasilicate, petalite (LiAlSi₄O₁₀), beta quartz, and/or beta spodumene, as potentially combined with residual glass in the structure. In an embodiment, the substrate 103 comprises a disilicate phase. In another implementation, the substrate 103 comprises a disilicate phase and a petalite phase. According to an embodiment, the substrate 103 has a crystallinity of at least 40% by weight. In some implementations, the substrate 103 has a crystallinity of at least about 40%, 45%, 50%, 55%, 60%, 65%, 70%, 75%, 80%, 85%, or greater (by weight), with the residual as a glass phase. Further, according to some embodiments, each of the crystalline phases of the substrate 103 has an average crystallite size of less than 100 nm, less than 75 nm, less than 50 nm, less than 40 nm, less than 30 nm, and all crystallite sizes within or less than these levels. According to one exemplary embodiment, the substrate 103 comprises lithium disilicate and petalite phases with 40-50 wt. % lithium disilicate (Li₂Si₂O₅), 35-45 wt. % petalite (LiAlSi₄O₁₀), <2 wt. % of other phases, and the remainder as residual glass (e.g., 10⁻²¹ wt. % glass) (exemplary phase assemblages are listed below in Table 6). Unless otherwise noted, all phase assemblage amounts and values are measured through X-ray diffraction (XRD) using a Rietveld analysis.

TABLE 1
Exemplary glass-ceramic substrate compositions

| Composition | Glass Ceramic | Glass Ceramic | Glass Ceramic |
|---|---|---|---|
| (mol %) | Substrate A | Substrate B | Substrate C |
| SiO₂ | 70.39 | 70.77 | 68.98 |
| Al₂O₃ | 4.21 | 4.21 | 4.03 |
| P₂O5 | 0.85 | 0.85 | 1.01 |
| Li₂O | 21.16 | 21.98 | 22.31 |
| Na₂O | 1.50 | 0.06 | 0.07 |
| K₂O | 0.13 | 0.07 | 0.07 |
| ZrO₂ | 1.71 | 2.01 | 2.78 |
| CaO | 0.01 | 0.02 | 0.71 |
| Fe₂O₃ | 0.02 | 0.02 | 0.02 |
| HfO₂ | 0.02 | 0.02 | 0.03 |
| SnO₂ | 0.01 | 0.01 | 0.01 |

TABLE 2
Phase assemblages of exemplary glass-ceramic substrate
compositions (XRD)

| | | lithium disilicate | petalite | |
|---|---|---|---|---|
| | Glass | (Li₂Si₂O₅) | (LiAlSi₄O₁₀) | other phases |
| Material | (wt %) | (wt %) | (wt %) | (wt %) |
| Glass Ceramic | 19 | 43 | 38 | <2% |
| Substrate A | | | | |
| Glass Ceramic | 12 | 45 | 43 | <2% |
| Substrate B | | | | |
| Glass Ceramic | 13 | 44 | 42 | <2% |
| Substrate C | | | | |

Embodiments of the glass-ceramic substrate 103 employed in the coated articles of the disclosure (see, e.g., FIG. 1) can exhibit a refractive index that is higher than refractive indices of conventional glass substrates or strengthened glass substrates. For example, the refractive index of the substrates 103 can range from about 1.52 to 1.65, from about 1.52 to 1.64, from about 1.52 to 1.62, or from about 1.52 to 1.60, and all refractive indices within the foregoing ranges (e.g., as measured at a visible wavelength of 589 nm). As such, conventional optical coatings, which are typically optimized for glass substrates and their refractive index ranges, are not necessarily suitable for use with substrates 103 as comprising glass-ceramic material of the coated articles of the disclosure. In particular, the layers of the coated article between the substrate 103 and the surface-modifying layer 113 can be modified to achieve low reflectance and low color generated by the transition zone between the glass-ceramic substrate 103 and the surface-modifying layer 113. This layer re-design requirement can also be described as optical impedance matching between the substrate 110 and the surface-modifying layer 113. Further, the layers of the coated article between the substrate 103 and a scratch-resistant layer 233 (as discussed later herein) can be modified to achieve low reflectance and low color generated by the transition zone between the glass-ceramic substrate 103 and the scratch-resistant layer 233. This layer re-design requirement can also be described as optical impedance matching between the substrate 103 and the scratch-resistant layer 233.

According to implementations, the glass-ceramic substrate 103 is substantially optically clear, transparent and free from light scattering. In such embodiments, the substrate 103 may exhibit an average light transmittance over the optical wavelength regime of about 80% or greater, about 81% or greater, about 82% or greater, about 83% or greater, about 84% or greater, about 85% or greater, about 86% or greater, about 87% or greater, about 88% or greater, about 89% or greater, about 90% or greater, about 91% or greater, about 92% or greater, about 93% or greater, or even about 94% or greater. In some embodiments, these light reflectance and transmittance values may be a total reflectance or total transmittance (taking into account reflectance or transmittance on both the first major surface 105 and the second major surface 107 of the substrate 103) or may be observed on a single-side of the substrate 103 (i.e., on the first major surface 105 only, without taking into account the second major surface 107). Unless otherwise specified, the average reflectance or transmittance of the substrate 103 alone is measured at an incident illumination angle of 0 degrees relative to the first major surface 105 (however, such measurements may be provided at incident illumination angles of 45 degrees or 60 degrees).

In some aspects, the glass-ceramic substrate 103, in addition to being transparent, can also be colored transparent, opaque, colored opaque, translucent, or colored translucent. As used herein “opaque” and “translucent” can mean as follows: opacity is the measure of impenetrability to visible light. An opaque object is neither transparent (allowing all light to pass through) nor translucent (allowing some light to pass through). When light strikes an interface between two substances, in general some may be reflected, some absorbed, some scattered, and the rest transmitted. An opaque substance transmits very little light, and therefore reflects, scatters, or absorbs most of it. Opacity depends on the frequency of the light being considered. For instance, some kinds of glass, while transparent in the visual range, are largely opaque to ultraviolet light. Further, the colored transparent, colored opaque, and colored translucent can be anyone of a variety of colors including, for example, black, white, green, yellow, pink, red, blue, orange, purple, brown, etc.

In aspects, the substrate 103 can comprise a polymer substrate. For instance, in aspects, the substrate 103 may be characterized as organic and may specifically be polymeric. Examples of suitable polymers include, without limitation: thermoplastics including polystyrene (PS) (including styrene copolymers and blends), polycarbonate (PC) (including copolymers and blends), polyesters (including copolymers and blends, including polyethyleneterephthalate and polyethyleneterephthalate copolymers), polyolefins (PO) and cyclicpolyolefins (cyclic-PO), polyvinylchloride (PVC), acrylic polymers including polymethyl methacrylate (PMMA) (including copolymers and blends), thermoplastic urethanes (TPU), polyetherimide (PEI) and blends of these polymers with each other. Other exemplary polymers include epoxy, styrenic, phenolic, melamine, and silicone resins.

In aspects, the substrate 103 can comprise a metal substrate. In aspects, all or a portion of the metal substrate may be formed of a metallic material having an austenite transformation temperature. In some embodiments, at least surface of the substrate 103 may be formed of a metallic material having an austenite transformation temperature. In some embodiments, a metallic material of the metal substrate may be a steel. In some embodiments, a metallic material of the metal substrate may be a martensitic steel. In some embodiments, a metallic material of the metal substrate may be a martensitic stainless steel. In some embodiments, a metallic material of the metal substrate may be a precipitation hardening martensitic steel. In some embodiments, a metallic material of the metal substrate may not be a precipitation hardening martensitic stainless steel. In some embodiments, a metallic material of the metal substrate may be a conventional steel material.

In some specific embodiments, the substrate 103 may specifically exclude polymeric, plastic and/or metal substrates.

In aspects, the substrate 103 can be optically transparent. As used herein, “optically transparent” or “optically clear” means an average transmittance of 70% or more in the wavelength range of 400 nm to 750 nm through a 1.0 mm thick piece of a material. In aspects, an “optically transparent material” or an “optically clear material” may have an average transmittance of 75% or more, 80% or more, 85% or more, or 90% or more, 91% or more, 92% or more, 94% or more, 96% or more in the wavelength range of 400 nm to 750 nm through a 1.0 mm thick piece of the material. The average transmittance in the wavelength range of 400 nm to 700 nm is calculated by measuring the transmittance of whole number wavelengths from about 400 nm to about 700 nm and averaging the measurements.

In aspects, the coated article 101, 201, 211, or 221 comprising a glass-based substrate and/or a ceramic-based substrate can comprise one or more compressive stress regions. In aspects, a compressive stress region may be created by chemically strengthening. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the substrate 103 can enable good impact resistance, good puncture resistance, and/or enable small bend radii, for example, with the compressive stress from the chemical strengthening counteracting bend-induced tensile stress on the outermost surface of the substrate. A compressive stress region may extend into a portion of the first portion and/or the second portion for a depth called the depth of compression (DOC). As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C₇₇₀-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 400 μm, SCALP is used to measure the depth of compression and central tension (CT). Where the stress in the substrate and/or portion is generated by exchanging both potassium and sodium ions into the substrate and/or portion, and the article being measured is thicker than about 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate and/or portion (e.g., sodium, potassium). Throughout the disclosure, DOL is measured in accordance with ASTM C-1422. Without wishing to be bound by theory, a DOL is usually greater than or equal to the corresponding DOC. Through the disclosure, when the maximum central tension cannot be measured directly by SCALP (as when the article being measured is thinner than about 400 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the substrate 103 may comprise a first compressive stress region at the first major surface 105 that can extend to a first depth of compression from the first major surface 105. In aspects, the substrate 103 may comprise a second compressive stress region at the second major surface 107 that can extend to a second depth of compression from the second major surface 107. In aspects, the first depth of compression and/or the second depth of compression as a percentage of the substrate thickness 109 can be about 5% or more, about 10% or more, about 12% or more, about 15% or more, about 17% or more, about 30% or less, about 25% or less, about 22% or less, about 20% or less, about 17% or less, or about 15% or less. In aspects, the first depth of compression and/or the second depth of compression as a percentage of the substrate thickness 109 can range from about 5% to about 30%, from about 10% to about 25%, from about 10% to about 22%, from about 12% to about 20%, from about 12% to about 17%, from about 15% to about 17%, or any range or subrange therebetween. In aspects, the first depth of compression and/or the second depth of compression can be about 1 μm or more, about 10 μm or more, about 15 μm or more, about 20 μm or more, about 25 μm or more, about 30 μm or more, about 200 μm or less, about 150 μm or less, about 100 μm or less, about 60 μm or less, about 45 μm or less, about 30 μm or less, or about 20 μm or less. In aspects, the first depth of compression and/or the second depth of compression can range from about 1 μm to about 200 μm, from about 1 μm to about 150 μm, from about 10 μm to about 100 μm, from about 15 μm to about 600 μm, from about 20 μm to about 45 μm, from about 20 μm to about 30 μm, or any range or subrange therebetween. By providing a first portion comprising a first glass-based and/or ceramic-based portion comprising a first depth of compression and/or a second depth of compression from about 1% to about 30% of the first thickness, good impact and/or puncture resistance can be enabled.

In aspects, the first compressive stress region can comprise a maximum first compressive stress, and/or the second compressive stress region can comprise a maximum second compressive stress. In further aspects, the maximum first compressive stress and/or the maximum second compressive stress can be about 100 MegaPascals (MPa) or more, about 300 MPa or more, 400 MPa or more, about 500 MPa or more, about 600 MPa or more, about 700 MPa or more, about 1,500 MPa or less, about 1,200 MPa or less, about 1,000 MPa or less, or about 800 MPa or less. In further aspects, the maximum first compressive stress and/or the maximum second compressive stress can range from about 100 MPa to about 1,500 MPa, from about 100 MPa to about 1,200 MPa, from about 300 MPa to about 1,200 MPa, from about 300 MPa to about 1,000 MPa, from about 400 MPa to about 1,000 MPa, from about 500 MPa to about 1,000 MPa, from about 600 MPa to about 900 MPa, from about 700 MPa to about 800 MPa, or any range or subrange therebetween. By providing a maximum first compressive stress and/or a maximum second compressive stress from about 100 MPa to about 1,500 MPa, good impact and/or puncture resistance can be enabled.

In aspects, the substrate 103 may comprise a tensile stress region. The tensile stress region can be positioned between the first compressive stress region and the second compressive stress region. In aspects, the tensile stress region can comprise a maximum tensile stress. In further aspects, the maximum first stress can be about 10 MPa or more, about 20 MPa or more, about 30 MPa or more, about 100 MPa or less, about 80 MPa or less, or about 60 MPa or less. In further aspects, the maximum tensile stress can range from about 10 MPa to about 100 MPa, from about 10 MPa to about 80 MPa, from about 10 MPa to about 60 MPa, from about 20 MPa to about 100 MPa, from about 20 MPa to about 80 MPa, from about 20 MPa to about 60 MPa, from about 30 MPa to about 100 MPa, from about 30 MPa to about 80 MPa, from about 30 MPa to about 60 MPa, or any range or subrange therebetween. Providing a maximum tensile stress from about 10 MPa to about 100 MPa can enable good impact and/or puncture resistance.

As used herein, if a first layer and/or component is described as “disposed over” a second layer and/or component, other layers may or may not be present between the first layer and/or component and the second layer and/or component. Furthermore, as used herein, “disposed over” does not refer to a relative position with reference to gravity. For example, a first layer and/or component can be considered “disposed over” a second layer and/or component, for example, when the first layer and/or component is positioned underneath, above, or to one side of a second layer and/or component. As used herein, a first layer and/or component described as “bonded to” a second layer and/or component means that the layers and/or components are bonded to each other, either by direct contact and/or bonding between the two layers and/or components or via an adhesive layer. As used herein, a first layer and/or component described as “contacting” or “in contact with” a second layer and/or components refers to direct contact and includes the situations where the layers and/or components are bonded to each other. As used herein, a first layer and/or component described as “disposed on” a second layer and/or component means that the layers do not have any other layers therebetween other than an optional layer of a coupling agent or are bonded together. Consequently, a first layer disposed over a second layer may further be disposed on, in contact with, and/or bonded to the second layer.

In particular aspects, the coated article may include a glass substate, a planarization layer disposed on the glass substate, and a surface modifying layer disposed on the planarization layer, wherein the planarization layer is positioned between the glass substrate and the surface-modifying layer. In particular aspects, the coated article may include a glass-ceramic substate, a planarization layer disposed on the glass-ceramic substate, and a surface modifying layer disposed on the planarization layer, wherein the planarization layer is positioned between the glass-cermaic substrate and the surface-modifying layer.

In aspects, as shown in FIGS. 2A-2C, the coated article 201, 211, or 221 can comprise an optical stack 203 comprising a third major surface 205 disposed on the first major surface 105 of the substrate 103. As shown, the optical stack 203 can comprise a fourth major surface 207 opposite the third major surface 205 with a stack thickness 209 defined therebetween. In aspects, the stack thickness 209 can be about 10 nanometers (nm) or more, about 50 nm or more, about 100 nm or more, about 300 nm or more, about 500 nm or more, about 700 nm or more, about 1 μm or more, about 10 μm or less, about 5 μm or less, about 2 μm or less, or about 1 μm or less. In aspects, the stack thickness 209 can range from about 10 nm to about 10 μm, from about 50 nm to about 5 μm, from about 100 nm to about 2 μm, from about 300 nm to about 1 μm, from about 500 nm to about 1 μm, or any range or subrange therebetween. In exemplary aspects, the stack thickness 209 can range from 10 nm to 10 μm, from 50 nm to 5 μm, or from 50 nm to 500 nm.

In further aspects, the optical stack 203 can comprise an anti-reflective (AR) coating, a band-pass filter coating, an edge neutral mirror, a beam splitter coating, a multi-layer high-reflectance coating, and/or an edge filter coating. For example, the anti-reflective coating of the optical stack 203 can be positioned between the surface-modifying layer 113 and the substrate 103, and/or the anti-reflective coating of the optical stack 203 can be positioned between the first layer 123 and the substrate 103. In even further aspects, the optical stack 203 (e.g., anti-reflective coating) can comprise two or more layers with differing refractive index values, for example, with a first low refractive index (RI) from about 1.3 to about 1.6 and a second high refractive index (RI) from about 1.6 to about 3.0. In still further aspects, the two or more layers of the optical stack 203 can form an alternative set of layers, for example, 2 sets or more, 3 sets or more, 5 sets or more, or 10 sets or more, for example, from 2 to 15 periods, from 2 to 10 periods, from 2 to 12 periods, from 3 to 8 periods, from 3 to 6 periods, or any range or subrange therebetween. In particular aspects, the coated article may include a glass-ceramic substrate, an AR coating, a planarization layer, and a surface-modifying layer. In particular aspects, the coated article may include an AR coating, positioned between a glass-ceramic substrate and a planarization layer, and a surface-modifying layer positioned on the planarization layer.

In aspects, as shown in FIG. 2B, the coated article 211 comprises optical stack 203a comprising a plurality of a silicon-containing oxide, a silicon-containing nitride, a silicon-containing oxynitride, and/or Nb₂O₅ layers. For example, the optical stack 203a can be an anti-reflective coating. As shown, the optical stack 203a can comprise one or more periods 213 comprising two or more layers with different refractive indices, for example, a first low RI layer 215a and a second high RI layer 217a. For example, the optical stack 203a shown in FIG. 2B has 2 periods 213 comprising first low RI layers 215a and 215b (L) and a second high RI layers 217a and 217b (H) that alternate in the following sequence of layers: L/H/L/H, although H/L/H/L could be provided in other aspects. An absolute value of a difference between the first low RI layer 215a and a second high RI layer 217a can be about 0.01 or more, about 0.05 or more, about 0.1 or more, or even 0.2 or more. Exemplary materials for the first low RI layer 215a include SiO₂, Al₂O₃, GeO₂, SiO₂, AlOₓN_{y}, SiOₓN_{y}, SiᵤAlᵥOₓN_{y}, MgO, and MgAl₂O₄. Exemplary materials for the second high RI layer 217a include SiᵤAlᵥOₓN_{y}, AlN, oxygen-doped SiNₓ, SiNₓ, Si₃N₄, AlOₓN_{y}, SiOₓN_{y}, Ta₂O₅, Nb₂O₅, HfO₂, TiO₂, ZrO₂, Y₂O₃, ZrO₂, Al₂O₃, and diamond-like carbon. The oxygen content of the materials for the high RI layer(s) 130B may be minimized, especially in SiNₓ or AlNₓ materials. The foregoing materials may be hydrogenated up to about 30% by weight. As used herein, it is to be understood that the subscripts (e.g., “u,” “v”, “x,” “y,” and “z”) range from greater than 0 to 1, where the subscripts sum to 1 to represent an “atomic fraction formula.” See, for example: (i) Charles Kittel, Introduction to Solid State Physics, seventh edition, John Wiley & Sons, Inc., NY, 1996, pp. 611-627; (ii) Smart and Moore, Solid State Chemistry, An introduction, Chapman & Hall University and Professional Division, London, 1992, pp. 136-151; and (iii) James F. Shackelford, Introduction to Materials Science for Engineers, Sixth Edition, Pearson Prentice Hall, New Jersey, 2005, pp. 404-418. The balance of the material (i.e., 1 minus the sum of the subscripts) is the first atom (e.g., SiNₓ with x=0.57 actually corresponds to Si_{0.43}No.57, which is the same as Si₃N₄). Also, the sum of all subscripts is greater than 0.

In aspects, the optical stack 203a can include the antireflective structure, antireflective coating, or outer optical film described in U.S. Pat. No. 10,948,629, issued Mar. 16, 2021, U.S. Published Application No. 2022/0011468, and/or WIPO Publication WO 2022/125846, which are incorporated by reference in their entirety. In aspects, as shown in FIG. 2B, the optical stack 203a can comprise a capping layer 219. In further aspects, the capping layer 219 can comprise a low refractive index material, which can be the same material as the first low RI layer 215a. In further aspects, the capping layer 219 can comprise a silicon-containing oxide (e.g., silicon dioxide), a silicon-containing nitride (e.g., an oxide-doped silicon nitride, silicon nitride, etc.), and a silicon-containing oxynitride (e.g., silicon oxynitride). An exemplary aspect of the capping layer is silicon dioxide (SiO₂). In aspects, as shown, the layer of the optical stack 203 closest to the substrate 103 can be a low index layer (i.e., first low RI layer 215a) and the layer closest to the first layer 123 can be a low index layer (e.g., capping layer 219). An exemplary combination of materials for the optical stack is SiO₂ for the first low RI layer, silicon nitride (e.g., Si₃N₄, SiNₓ) or silicon oxynitride (SiOxNy) for the second high RI layer, and silicon dioxide (SiO₂) for the capping layer.

In aspects, the coated article 211 can comprise a stack thickness 209a corresponding to a physical thickness of the optical stack 203a in a range from about 50 nm to less than 500 nm, from about 75 nm to about 490 nm, from about 100 nm to about 180 nm, from about 125 nm to about 475 nm, from about 150 nm to about 450 nm, from about 175 nm to about 425 nm, from about 200 nm to about 400 nm, from about 225 nm to about 375 nm, from about 250 nm to about 350 nm, from about 250 nm to about 340 nm, or any range or subrange therebetween. As used herein, the term “optical thickness” is determined by (n*d), where “n” refers to the RI of the sub-layer and “d” refers to the physical thickness of the layer. In aspects, at least one layer in the optical stack 203a can have an optical thickness from about 2 nm to about 200 nm, from about 10 nm to about 100 nm, from about 15 nm to about 90 nm, from about 50 nm to about 80 nm, or any range or subrange therebetween. In further aspects, the first low RI layers 215a and 215b in periods 213 in the optical stack 203 can be within or more of the ranges mentioned in the previous sentence. In aspects, a combined physical thickness of the second high RI layers 217a and 217b can be about 90 nm or more, about 100 nm or more, about 120 nm or more, about 130 nm or more, about 150 nm or more, or less than 500 nm. For example, the combined physical thickness of the second high RI layers 217a and 217b can range from about 90 nm to less than 500 nm, from about 100 nm to about 300 nm, from about 120 nm to about 200 nm, or any range or subrange therebetween. In aspects, the combined physical thickness of the second high RI layers 217a and 217b as a percentage of the physical thickness of the stack thickness 209a can be about 30% or more, about 35% or more, about 40% or more, or about 45% or more, for example, ranging from about 35% to about 75%, from about 40% to about 65%, from about 45% to about 55%, or any range or subrange therebetween.

In aspects, the optical stack 203a of the coated article 211 can comprise a residual stress of less than about +50 MPa (tensile) to about −1000 MPa (compression). In some aspects, the anti-reflective coating can be characterized by a residual stress from about −50 MPa to about −1000 MPa (compression) or from about −75 MPa to about −800 MPa (compression). Unless otherwise noted, residual stress in the anti-reflective coating is obtained by measuring the curvature of the substrate 103 before and after deposition of the anti-reflective coating, and then calculating residual film stress according to the Stoney equation according to principles known and understood by those with ordinary skill in the field of the disclosure.

In aspects, the optical stack 203a and/or the coated article 211 may exhibit a visible photopic average reflectance of about 1% or less, about 0.9% or less, about 0.8% or less, about 0.7% or less, about 0.6% or less, about 0.5% or less, about 0.4% or less, about 0.3% or less, or about 0.2% or less, over the optical wavelength regime. These photopic average reflectance values may be exhibited at incident illumination angles in the range from about 0° to about 20°, from about 0° to about 40°, or from about 0° to about 60°. As used herein, “photopic average reflectance” mimics the response of the human eye by weighting the reflectance versus wavelength spectrum according to the human eye's sensitivity. Photopic average reflectance may also be referred to as the luminance, or tristimulus Y value of reflected light, according to known conventions, for example CIE color space conventions. The photopic average reflectance [symbol] Rₚ [symbol] is defined as the spectral reflectance, R(λ), multiplied by the illuminant spectrum, I(λ), and the CIE's color matching function, y(λ), related to the eye's spectral response:

$$〈 {R}_{p} 〉 = {\int }_{380 n m}^{720 n m} R ( λ ) \times I ( λ ) \times \overline{y} ( λ ) d λ .$$

Further, the article exhibits a CIE a*value, in reflectance, from about −10 to +2 and a CIE b* value, in reflectance, from −10 to +2, the CIE a*and CIE b* values each measured on the optical film structure at a normal incident illumination angle. In aspects, the optical stack 203a and/or the coated article 211 can exhibit a photopic average light transmission of about 90% or greater, 92% or greater, 94% or greater, 96% or greater, or 98% or greater, over the optical wavelength regime. In some embodiments, the optical stack 203a and/or the coated article 211 exhibits an average light transmission of about 87% or greater, 88% or greater, 89% or greater, 90% or greater, 91% or greater, 92% or greater, 93% or greater, 94% or greater, or 95% or greater, over the optical wavelength regime in the infrared spectrum from 800 nm to 1000 nm, from 900 nm to 1000 nm, or from 930 nm to 950 nm. In aspects, the optical stack 203a and/or the coated article 211 can exhibit a hardness of 8 GPa or greater measured at an indentation depth of about 100 nm or a maximum hardness of 9 GPa or greater measured over an indentation depth range from about 100 nm to about 500 nm, the hardness and the maximum hardness measured by a Berkovich Indenter Hardness Test (as defined below).

In aspects, as shown in FIG. 2B, the coated article 211 comprises optical stack 203a comprising an optical film 231, a scratch-resistant layer 233, and an optional capping layer 229. In aspects, the optical stack 203b can include the scratch resistant coating, anti-reflective coating, and/or optical film structure described in U.S. Pat. No. 9,328,016, issued May 3, 2016, U.S. Pat. No. 9,684,097, issued Jun. 20, 2017, U.S. Pat. No. 9,703,011, issued Jul. 11, 2017, U.S. Pat. No. 9,079,802, issued Jul. 14, 2015, U.S. Pat. No. 9,726,786, issued Aug. 8, 2017, U.S. Pat. No. 10,416,352, issued Sep. 17, 2019, which are incorporated by reference in their entirety. For example, the optical stack 203b can be an anti-reflective coating and/or a scratch-resistant coating.

In further aspects, as shown in FIG. 2C, the optical film 130 of the optical stack 203b can comprise one or more periods 223 comprising two or more layers with different refractive indices, for example, a first low RI layer 225 and a second high RI layer 227. For example, the optical stack 203b shown in FIG. 2C has 3 periods 223 forming the optical film 231 with alternating first low RI layers 225 and second high RI layers 227. In even further aspects, the optical film 231 can comprise any number of periods, for example, within one or more of the ranges discussed above for the optical stack 203a. An absolute value of a difference between the first low RI layers 225 and the second high RI layers 227 can be about 0.01 or more, about 0.05 or more, about 0.1 or more, or even 0.2 or more. In further aspects, the first low RI layers 225 can comprise any of the materials discussed above for the first low RI layer 215a, for example, silicon dioxide (SiO₂). In further aspects, the second high RI layers 227 can comprise any of the materials discussed above for the second high RI layer 217a, for example, SiOxNy. In further aspects, a layer of the first low RI sub-layers 225 and/or the second high RI sub-layers 227 can comprise an optical thickness (n*d) in the range from about 2 nm to about 200 nm, from about 10 nm to about 100 nm, from about 15 nm to about 100 nm, or any range or subrange therebetween. In even further aspects, all of the layers in the optical film 130 or all of the second high RI layers in the optical film 130 can have an optical thickness within one or more of the ranges mentioned in the previous sentence. In further aspects, a layer of the first low RI sub-layers 225 and/or the second high RI sub-layers 227 can comprise a physical thickness from about 10 nm to about 800 nm, from about 10 nm to about 500 nm, from about 10 nm to about 300 nm, from about 10 nm to about 200 nm, from about 20 nm to about 100 nm, or any range or subrange therebetween. In further aspects, the optical stack 203 and/or any one or of the layers or sections therein (e.g., optical film 231, a scratch-resistant layer 233, an optional capping layer 229) may exhibit an extinction coefficient (at a wavelength of about 400 nm) of about 104 or less.

In further aspects, as shown in FIG. 2C, the scratch-resistant layer 233 can include an inorganic carbide, nitride, oxide, diamond-like material, or combination of these. Examples of suitable materials for the scratch-resistant layer 233 include metal oxides, metal nitrides, metal oxynitride, metal carbides, metal oxycarbides, and/or combinations thereof combination thereof. Exemplary metals include B, Al, Si, Ti, V, Cr, Y, Zr, Nb, Mo, Sn, Hf, Ta and W. Specific examples of materials that may be utilized in the scratch-resistant layer 233 may include Al₂O₃, AlN, AlOₓN_{y}, Si₃N₄, SiOₓN_{y}, SiᵤAlᵥOₓN_{y}, diamond, diamond-like carbon, SiₓC_{y}, SiₓO_{y}C_{z}, ZrO₂, TiOₓN_{y}, or combinations thereof. In even further aspects, the scratch-resistant layer 233 can comprise the same material as the second high RI layers 227, for example, SiOₓN_{y}. In even further aspects, a physical thickness of the scratch-resistant layer and/or optical stack can be from about 0.05 μm to about 3 μm, from about 0.1 μm to about 3 μm, from about 0.2 μm to about 3 μm, from about 0.3 μm to about 2.2 μm, from about 0.5 μm to about 2.1 μm, from about 1 μm to about 2.1 μm, from about 1.8 μm to about 2.1 μm, or any range or subrange therebetween. In exemplary aspects, a physical thickness of the scratch-resistant layer can be from 0.05 μm to 3 μm, from 0.3 μm to 2.2 μm, or from 1 μm to 2.1 μm. The scratch-resistant layer 233 and/or the optical stack 203b may exhibit a hardness of about 8 GPa or greater, about 10 GPa or greater, about 13 GPa or greater, or about 17 GPa or greater, as measured by the Berkovich Indenter Hardness Test (as described below).

Although not shown, it is to be understood that the scratch-resistant layer can be sandwiched by portions of the optical film. For example, 3 or more periods can be positioned between the scratch-resistant layer and the substrate while 2 or more periods can be positioned between the scratch-resistant layer and the surface-modifying layer and/or between the scratch-resistant layer and the first layer.

In further aspects, as shown in FIG. 2C, the optical stack 203b can comprise capping layer 229 disposed over (e.g., disposed on) the scratch-resistant layer. In even further aspects, the capping layer 229 can include a low refractive index material, such as SiO₂, Al₂O₃, GeO₂, SiO₂, AlOₓN_{y}, SiOₓN_{y}, SiᵤAlᵥOₓN_{y}, MgO, MgF₂, BaF₂, CaF₂, DyF₃, YbF₃, YF₃, or CeF₃. In further aspects, the capping layer 229 can comprise the same material as the first high RI layers 225, for example, SiO₂. In further aspects, a thickness of the capping layer 229 can be from about 10 nm to about 120 nm, from about 20 nm to about 115 nm, from about 50 nm to about 110 nm, from about 80 nm to about 110 nm, from about 90 nm to about 105 nm, or any range or subrange therebetween. The capping layer 229 may exhibit an intrinsic hardness in the range from about 7 GPa to about 10 GPa, as measured by the Berkovich Indenter Hardness Test (as measured on the surface of a layer of the same material of the capping layer, formed in the same manner, but having a thickness of about 1 micrometer or greater).

In further aspects, a stack thickness 209b corresponding to a physical thickness of the optical stack 203b can range from about 0.5 μm to about 3 μm, from about 1 μm to about 3 μm, from about 1.2 μm to about 3 μm, from about 1.5 μm to about 3 μm from about 2 μm to about 2.6 μm, or any range or subrange therebetween. In further aspects, the optical stack 203b can exhibit an average light reflectance of about 0.5% or less, about 0.25% or less, about 0.1% or less, or even 0.05% or less over the optical wavelength regime. In further aspects, the optical stack 203b can exhibit an average transmittance or average reflectance having an average oscillation amplitude of about 5 percentage points or less over the optical wavelength regime. In further aspects, the optical stack 203b may exhibit an average light transmission of 80% or greater, 82% or greater, 85% or greater, 90% or greater, 90.5% or greater, 91% or greater, 91.5% or greater, 92% or greater, 92.5% or greater, 93% or greater, 93.5% or greater, 94% or greater, 94.5% or greater, or 95% or greater.

The optical stack 203, 203a, or 203b may be formed using various deposition methods, for example, vacuum deposition techniques, chemical vapor deposition (e.g., plasma enhanced chemical vapor deposition (PECVD), low-pressure chemical vapor deposition, atmospheric pressure chemical vapor deposition, and plasma-enhanced atmospheric pressure chemical vapor deposition), physical vapor deposition (e.g., reactive or nonreactive sputtering or laser ablation), thermal or e-beam evaporation and/or atomic layer deposition. Liquid-based methods may also be used, for example, printing, spraying, or slot coating. Where vacuum deposition is utilized, inline processes may be used to form the optical stack 203, 203a, or 203b in one deposition run. In aspects, the vacuum deposition can be made by a linear PECVD source. In aspects, the optical stack 203, 203a, or 203b can be prepared using a sputtering process (e.g., a reactive sputtering process), chemical vapor deposition (CVD) process, plasma-enhanced chemical vapor deposition process, or some combination of these processes. In aspects, the optical stack 203a or 203b comprising low RI layer(s) 215a, 215b, or 225 and high RI layer(s) 217a, 217b, or 227 can be prepared according to a reactive sputtering process. According to some embodiments, optical stack 203a or 203b (including low RI layer 215a, 215b, or 225, high RI layer 217a, 217b, or 227 and capping layer 219 or 229) can be fabricated using a metal-mode, reactive sputtering in a rotary drum coater. The reactive sputtering process conditions were defined through careful experimentation to achieve the desired combinations of hardness, refractive index, optical transparency, low color, and controlled film stress.

In further aspects, the optical stack 203 can comprise a gradient coating comprising a refractive index gradient. For example, the gradient coating of the optical stack 203 can be positioned between the surface-modifying layer 113 and the substrate 103, and/or the gradient coating of the optical stack 203 can be positioned between the first layer 123 and the substrate 103. In even further aspects, the refractive index gradient can span a range of refractive index values of about 0.2 or more, about 0.3 or more, about 0.4 or more, about 1 or less, about 0.8 or less, about 0.6 or less, or about 0.5 or less, for example, from about 0.2 to about 1, from about 0.3 to about 0.8, from about 0.4 to about 0.6, or any range or subrange therebetween. In even further aspects, the gradient coating can comprise a concentration gradient of one or more of oxygen, nitrogen, and/or silicon. It should be understood, however, that other functional coatings may be provided in the optical stack 203 to achieve predetermined optical properties of the coated article 201, 211, or 221.

According to one or more aspects, an anti-reflective coating can be used in combination with an anti-glare (AG) surface. Anti-glare surface treatments can impact the performance of anti-reflective coatings. Thus, selection of the proper anti-glare surface can be important for optimal performance, particularly in difficult use environments, such as vehicle interiors. In such environments, anti-glare surfaces on a cover glass needs to have the minimum sparkle and provide the appropriate anti-glare effect and tactile while meeting a required Contrast Ratio (CR) under sunlight. For example, a sample can be prepared with a chemically-etched Ultra-Low Sparkle (ULS) AG surface on a glass substrate made of Corning® Gorilla® Glass with an anti-reflective coating according to embodiments of this disclosure, and an easy-to-clean (ETC) coating to provide stable color appearance with wide-viewing angles. The ambient contrast performance was evaluated at a system level to gauge the impact of AG/AR coating on sunlight viewability.

In the above-mentioned example, the anti-glare surface was prepared on a Corning® Gorilla® Glass substrate by using a chemical etching method that enables ultra-low sparkle performance suitable for high resolution display up to 300 pixels per inch (PPI). Then, the anti-glare glass optical properties can be analyzed, including with and without contributions from specular reflection (i.e., specular component excluded (SCE) or specular component included (SCI)), transmission haze, gloss, distinctness of image (DOI), and sparkle. Further information regarding these properties and how these measurement are made can be found in (1) C. Li and T. Ishikawa, Effective Surface Treatment on the Cover Glass for Auto-Interior Applications, SID Symposium Digest of Technical Papers Volume 1, Issue 36.4, pp. 467 (2016); (2) J. Gollier, G. A. Piech, S. D. Hart, J. A. West, H. Hovagimian, E. M. Kosik Williams, A. Stillwell and J. Ferwerda, Display Sparkle Measurement and Human Response, SID Symposium Digest of Technical Papers Volume 44, Issue 1 (2013); and (3) J. Ferwerda, A. Stillwell, H. Hovagimian and E. M. Kosik Williams, Perception of sparkle in anti-glare display screen, Journal of the SID, Vol 22, Issue 2 (2014), the contents of which are incorporated herein by reference.

The balance of the five metrics of SCE/SCI (see previous paragraph), transmission haze, gloss, distinctness of image (DOI), and sparkle is important for maximizing the benefits of an anti-glare for display readability, tactility on the glass surface, and the aesthetic appearance of high-performance touch displays in applications such as vehicle interiors. Sparkle is a micro-scattering interaction of the anti-glare surface with LCD pixels to create bright spots degrading image quality, especially at high resolution. The sparkle effect can be characterized using the method of the Pixel Power Deviation with reference (PPDr) to examine the sparkle effect on different resolution displays. For example, ultra-low sparkle anti-glare glass with less than 1% PPDr will have invisible sparkle effect on a display of less than 300 pixels-per-inch (PPI). However, up to 4% PPDr may be acceptable depending on the contents of display, based on the preference of the end-user. In vehicular or automotive interior settings, about 120 PPI to about 300 PPI is acceptable, and displays over 300 PPI have diminishing value.

In aspects, the substrate 103 and/or an anti-glare surface of the optical stack 203, 203a, and/or 203b can comprise a textured surface, for example, having particulates, a mechanically roughened surface, and/or a chemically roughened surface. In further aspects, the anti-glare and/or textured surface can be formed by treating the corresponding surface with an anti-glare treatment. Exemplary aspects of anti-glare treatments include chemical or physical surface treatment to form irregularities and/or etching the surface (e.g., with hydrofluoric acid) to create an etched region exhibiting anti-glare properties. In aspects, the optical stack 203, 203a, and/or 203b (e.g., including the anti-glare coating and/or anti-reflection coating) can be disposed on the first major surface 105 of the substrate when the first major surface 105 is textured (e.g., when the substrate is a textured substrate).

Throughout the disclosure, hardness of the optical stack is measured using the “Berkovich Indenter Hardness Test.” As used herein, the “Berkovich Indenter Hardness Test” measures the hardness of a material by indenting the surface (e.g., fourth major surface 207) with a diamond Berkovich indenter to form an indent to an indentation depth in the range from about 50 nm to about 1000 nm (or the entire thickness of the optical stack 203, 203a, or 203b, whichever is less) and measuring the hardness from this indentation at various points along the entire indentation depth range, along a specified segment of this indentation depth (e.g., in the depth range from about 100 nm to about 500 nm), or at a particular indentation depth (e.g., at a depth of 100 nm, at a depth of 500 nm, etc.) generally using the methods set forth in Oliver, W. C. and Pharr, G. M., “An improved technique for determining hardness and elastic modulus using load and displacement sensing indentation experiments”, J. Mater. Res., Vol. 7, No. 6, 1992, 1564-1583; and Oliver, W. C. and Pharr, G. M., “Measurement of Hardness and Elastic Modulus by Instrument Indentation: Advances in Understanding and Refinements to Methodology”, J. Mater. Res., Vol. 19, No. 1, 2004, 3-20. Further, when hardness is measured over an indentation depth range (e.g., in the depth range from about 100 nm to about 500 nm), the results can be reported as a maximum hardness within the specified range, wherein the maximum is selected from the measurements taken at each depth within that range. As used herein, “hardness” and “maximum hardness” both refer to as-measured hardness values, not averages of hardness values. Similarly, when hardness is measured at an indentation depth, the value of the hardness obtained from the Berkovich Indenter Hardness Test is given for that particular indentation depth.

The optical stack 203, 203a or 203b, if present, can comprise a hardness of greater than about 8 GPa, by the Berkovich Indenter Hardness Test at an indentation depth of about 100 nm. The optical stack 203 may exhibit a hardness of about 8 GPa or greater, about 9 GPa or greater, about 10 GPa or greater, about 11 GPa or greater, about 12 GPa or greater, about 13 GPa or greater, about 14 GPa or greater, or about 15 GPa or greater by the Berkovich Indenter Hardness Test at an indentation depth of about 100 nm. For example, the optical stack 203 or 203a, including the first layer 123 and/or surface-modifying layer 113, as described herein, may exhibit a hardness of about 8 GPa or greater, about 10 GPa or greater or about 12 GPa or greater, by the Berkovich Indenter Hardness Test at an indentation depth of about 100 nm. In aspects, the optical stack 203 or 203b can exhibit a hardness ranging from about 8 GPa to about 30 GPa, from about 10 GPa to about 25 GPa, from about 12 GPa to about 20 GPa, from about 16 GPa to about 20 GPa, or any range or subrange therebetween. Such measured hardness values may be exhibited by the optical stack 203, 203a, or 203b and/or the coated article 101, 201, 211, or 221 over an indentation depth of about 50 nm or greater or about 100 nm or greater (e.g., from about 100 nm to about 300 nm, from about 100 nm to about 400 nm, from about 100 nm to about 500 nm, from about 100 nm to about 600 nm, from about 200 nm to about 300 nm, from about 200 nm to about 400 nm, from about 200 nm to about 500 nm, or from about 200 nm to about 600 nm). Similarly, maximum hardness values of about 8 GPa or greater, about 9 GPa or greater, about 10 GPa or greater, about 11 GPa or greater, about 12 GPa or greater, about 13 GPa or greater, about 14 GPa or greater, or about 15 GPa or greater by the Berkovich Indenter Hardness Test may be exhibited by the optical stack 203 and/or the coated article 101, 201, 211, or 221 over an indentation depth of about 50 nm or greater or about 100 nm or greater (e.g., from about 100 nm to about 300 nm, from about 100 nm to about 400 nm, from about 100 nm to about 500 nm, from about 100 nm to about 600 nm, from about 200 nm to about 300 nm, from about 200 nm to about 400 nm, from about 200 nm to about 500 nm, or from about 200 nm to about 600 nm).

As shown in FIGS. 1 and 2A-2C, the coated article 101, 201, 221, or 221 comprises the first layer 123 disposed over the first major surface 105 of the substrate 103. As shown, the first layer 123 comprises a first surface area 125 and a second surface area 127 opposite the first surface area 125. In aspects, as shown in FIGS. 1 and 2A-2C, the second surface area 127 of the first layer 123 can face the first major surface 105 of the substrate 103. In further aspects, as shown in FIG. 1, the second surface area 127 of the first layer 123 can contact the first major surface 105 of the substrate 103. Alternatively, as shown in FIGS. 2A-2C, one or more layers, for example, the optical stack 203, 203a, and/or 203b, can be positioned between the second surface area 127 of the first layer 123 and the first major surface 105 of the substrate 103. In even further aspects, as shown in FIGS. 2B-2C, the capping layer 219 or 229 can be at the fourth major surface 207 of the optical stack 203a and/or 203b, and/or the second surface area 127 can contact the capping layer 219 or 229 (e.g., at the fourth major surface 207 of the optical stack 203a and/or 203b). In even further aspects, even when the capping layer 219 or 229 comprises a silicon-containing oxide, the first layer 123 can be distinguished from the capping layer by the properties discussed herein (e.g., hydroxyl content, hardness, refractive index, power spectral density of the surface, surface roughness Ra, molar ratio of hydrogen to silica). For example, the first layer can comprise a greater hydroxyl content than a hydroxyl content of the capping layer; the first layer can exhibit a lower hardness, lower elastic modulus, and/or higher refractive index than the corresponding property of the capping layer; and/or a surface roughness Ra of the first layer can be less than a surface roughness Ra of the capping layer. As used herein, the term “first layer” is not intended to be limited by a specific surface roughness Ra (or a specific reduction in surface roughness Ra relative to the surface that the first layer is disposed and/or formed on). Instead, the first layer can comprise any of the aspects discussed herein, including the hydroxyl content and/or the power spectral density in addition to or instead of surface roughness Ra properties.

As shown in FIGS. 1 and 2A-2C, a first layer thickness 129 is defined as an average distance between the first surface area 125 and the second surface area 127. In aspects, the first layer thickness 129 can be about 5 nm or more, about 8 nm or more, about 10 nm or more, about 20 nm or more, about 50 nm or more, about 100 nm or more, about 200 nm or more, about 600 nm or less, about 500 nm or less, about 400 nm or less, about 350 nm or less, or about 300 nm or less. In aspects, the first layer thickness 129 can range from about 5 nm to about 600 nm, from about 10 nm to about 500 nm, from about 20 nm to about 400 nm, from about 20 nm to about 300 nm, from about 20 nm to about 200 nm, from about 20 nm to about 150 nm, from about 20 nm to about 100 nm, from about 50 nm to about 100 nm, or any range or subrange therebetween. In aspects, the first layer thickness 129 can range from about 5 nm to about 600 nm, from about 10 nm to about 600 nm, from about 20 nm to about 500 nm, from about 50 nm to about 400 nm, from about 100 nm to about 350 nm, from about 200 nm to about 300 nm, or any range or subrange therebetween. In exemplary aspects, the first layer thickness 129 can be from 10 nm to 600 nm, from 10 nm to 600 nm, or from 20 nm to 100 nm. If the first layer 123 comprises the planarization layer, as described herein, the first layer thickness 129 may be determined from a cross-sectional scanning electron microscope (SEM) image. If the first layer 123 comprises the hydroxyl-modified layer, as described herein, the first layer thickness 129 may be further determined using a cross-sectional scanning electron microscope (SEM) image in combination with measuring one or more properties of the first layer 123 to distinguish from other layers (e.g., the substrate) by the properties discussed herein (e.g., hydroxyl content, hardness, refractive index, power spectral density of the surface, surface roughness Ra). For example, the first layer 123 can comprise a greater molar ratio of hydrogen to silica than a molar ratio of hydrogen to silica of the substrate.

Throughout the disclosure, an elastic modulus (e.g., Young's modulus) of the optical stack, the first layer, and/or the surface-modifying layer is determined using nanoindentation with a Berkovich diamond indenter tip. See: Fischer-Cripps, A. C., “Critical Review of Analysis and Interpretation of Nanoindentation Test Data,” Surface & Coatings Technology, 200, 4153-4165 (2006); and Hay, J., Agee, P, and Herbert, E., “Continuous Stiffness measurement During Instrumented Indentation Testing, Experimental Techniques,” 34 (3) 86-94 (2010). For coatings, instantaneous estimates of the elastic modulus are measured as a function of indentation depth. The elastic modulus is taken as the maximum value of the instantaneous estimate of the elastic modulus for measurements within the 50% of the first layer thickness 129 closest to the exterior surface 115 (i.e., first surface area 125) minus 5 nm of the first layer 123 from the exterior surface 115. Without wishing to be bound by theory, if a coating is of sufficient thickness, then it is then possible to isolate the properties of the coating from an adjacent coating based on the resulting response profiles as a function of depth. Extraction of reliable nanoindentation data is based on well-established protocols described in the above-mentioned references. Otherwise, these metrics can be subject to significant errors. In aspects, the first layer 123 can exhibit an elastic modulus of about 30 GPa or more, about 35 GPa or more, about 40 GPa or more, about 45 GPa or more, about 50 GPa or more, about 55 GPa or more, about 70 GPa or less, about 65 GPa or less, about 60 GPa or less, about 55 GPa or less, or about 50 GPa or less. In aspects, the first layer 123 can exhibit an elastic modulus from about 30 GPa to about 70 GPa, from about 35 GPa to about 65 GPa, from about 40 GPa to about 65 GPa, from about 45 GPa to about 55 GPa, or any range or subrange therebetween. For example, as shown in FIG. 13 by points 1305 (squares), the first layer formed at deposition rates (discussed below) from 0.5 A/s to 2.0 A/s has an elastic modulus from 30 GPa to 70 GPa.

Throughout the disclosure, hardness is measured for first layers with a thickness of at least 30 nm as the maximum hardness recorded in a range of from 20 nm the first surface area 125 of the first layer 123 to 60% of the first layer thickness 129 (from the first surface area 125 of the first layer 123) in a Berkovich Indenter Hardness Test. It has been found that measurements closer to the surface than 20 nm tend to underestimate the hardness while measurements closer than 40% of the first layer thickness to an underlying layer can be significantly influenced by the properties of the underlying layer. For first layers with a thickness of 30 nm or less, it is believed that no reliable hardness measurement can be obtained. In aspects, the first layer 123 can exhibit a hardness of 3 GPa or more, about 3.5 GPa or more, 4 GPa or more, 5 GPa or more, 6 GPa or more, 8 GPa or less, 7 GPa or less, or 6 GPa or less measured at an indentation depth of about 20 nm by a Berkovich Indenter Hardness Test. In aspects, the first layer 123 can exhibit a hardness (e.g., or less measured at an indentation depth of about 20 nm by a Berkovich Indenter Hardness Test) from 3 GPa to 8 GPa, from 3.5 GPa to 7 GPa, from 4 GPa to 6 GPa, or any range or subrange therebetween. In aspects, the first layer 123 can exhibit a maximum hardness of 3 GPa or more, about 3.5 GPa or more, 4 GPa or more, 5 GPa or more, 6 GPa or more, 8 GPa or less, 7 GPa or less, or 6 GPa. In aspects, the first layer 123 can exhibit a hardness (e.g., measured over an indentation depth range from about 20 nm to about 500 nm or 60% of the first layer thickness, the hardness and the maximum hardness measured by a Berkovich Indenter Hardness Test) from 3 GPa to 8 GPa, from 3.5 GPa to 7 GPa, from 4 GPa to 6 GPa, or any range or subrange therebetween. For example, as shown in FIG. 13 by points 1315 (circles), the first layer formed at deposition rates (discussed below) from 0.5 A/s to 2.0 A/s has a hardness from 2 GPa to 8 GPa (e.g., from 3 GPa to 8 GPa or from 3 GPa to 7 GPa).

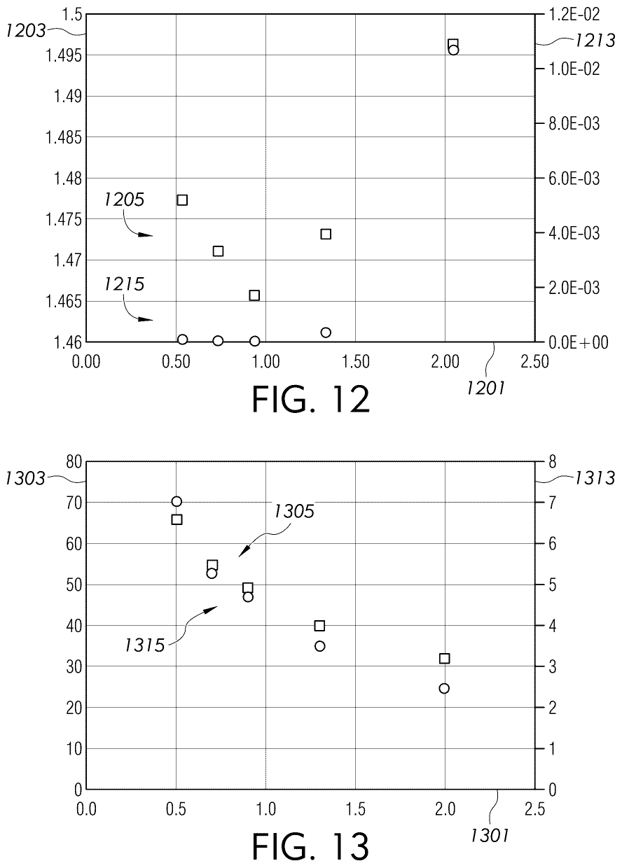

Throughout the disclosure, a refractive index of coatings and films is measured by spectroscopic ellipsometry using a Woollam M-2000 and modelled using Woollam CompleteEase software. Unless otherwise specified, refractive index is measured at 550 nm. In aspects, a refractive index of the first layer 123 can be about 1.460 or more, about 1.465 or more, about 1.47 or more, about 1.48 or more, less than about 1.50, about 1.49 or less, about 1.48 or less, about 1.47 or less, or about 1.465 or less. In aspects, a refractive index of the first layer 123 can range from about 1.460 to less than about 1.50, from about 1.465 to about 1.49, from about 1.47 to about 1.48, or any range or subrange therebetween. In aspects, a refractive index of the substrate 103 can be greater than or less than the refractive index of the first layer 123. In aspects, if a capping layer 219 or 229 is present, a refractive index of the capping layer 219 or 229 can be greater than the refractive index of the first layer 123. For example, as shown in FIG. 12 by points 1205 (squares), the first layer formed at deposition rates (discussed below) from 0.5 A/s to 2.0 A/s has an elastic modulus from 1.45 to less than 1.50 (e.g., from 1.46 to 1.48 or from 1.46 to 1.48). It is noted that a reactively sputtered silica layer has a refractive index of less than 1.460 (about 1.458) whereas the refractive index of the first layer can be greater than the refractive index of a reactively sputtered silica layer.

As used herein, an elemental composition of the first layer and/or the surface-modifying layer is determined using X-ray photoelectron spectroscopy (XPS). In aspects, the first layer and/or the surface-modifying layer can be fluorine-free. In aspects, the first layer 123 can comprise silicon atoms, oxygen atoms, carbon atoms, and hydrogen atoms. In further aspects, oxygen atoms in the first layer can be more common than any other atom in the first layer detected by XPS. In further aspects, the first layer can comprise about 30 atom % carbon or less, about 25 atom % carbon or less, about 10 atom % carbon or less, about 5 atom % carbon or less, about 2 atom % carbon or less, about 0.1 atom % carbon or more, about 1 atom % carbon or more, about 2 atom % carbon or more, or about 5 atom % carbon or more. All X-ray Photoelectron Spectroscopy (XPS) measurements were performed with a Physical Electronics PHI Quantes XPS instrument using monochromatized Al Kα radiation and a combination of low energy electrons and Argon ions for charge neutralization. The XPS instrument was operated by the SmartSoft-XPS software (V4.4.0.15) provided and sold by Physical Electronics (copyrighted by ULVAC-PHI, Inc. 2022). During the XPS measurements, an approximately 100 micrometer wide monochromatized Al Kα beam with a beam energy of approximately 25 Watts was rastered over the probed area which was 1 mm by 0.5 mm in size. For each example, 2-3 such areas were measured on each analyzed surface. The areas were at least 1 centimeter apart. The pass energy of spectrometer was set to a value of 69 eV with a step size of 0.125 eV/step and dwell time of 50 milliseconds per step. The core levels monitored during the XPS measurements are listed below in the order they were measured and the number of scans that each core level was measured appears in parenthesis: C 1s (7 scans), N 1s (10 scans), F 1s (5 scans), O 1s (5 scans), Si 2p (5 scans), Al 2p (4 scans) and Ca 2p (5 scans when present). The data analysis was performed using the MultiPak software package (Version 9.9.2 2021 Nov. 1) provided and sold by Physical Electronics (copyrighted by ULVAC-PHI, Inc. 1994-2021). During analysis, the energy scale was referenced to the C—C/C—H peak of hydrocarbons set at the commonly accepted value of 284.8 eV. Compositional analysis was performed using the atomic sensitivity factors provided in the version of MultiPak software cited above without any alteration.

In aspects, the first layer 123 can comprise a silica or a partial silica-like network. A silica-like network refers to a coordination of silicon atoms bonded together by oxygen atoms with four Si—O bonds for a silicon atom, corresponding to a SiO₂ network. As used herein, a fraction of silicon atoms in a silica-like-network is determined by Fourier-transform infrared (FTIR) spectroscopy based on an intensity of an absorbance associated with a Si—O—Si bend (e.g., from about 1000 cm⁻¹ to 1060 cm⁻¹) relative all Si—O—Si bends (including the T-type stretch of POSS at about 1105 cm⁻¹). In aspects, a percentage of silicon atoms in the first layer 123 in a silica-like network can be about 50% or more, about 60% or more, about 65% or more, about 70% or more, about 90% or less, about 80% or less, about 75% or less, or about 70% or less. In aspects, a percentage of silicon atoms in the first layer 123 in a silica-like network can range from about 50% to about 90%, from about 60% to about 80%, from about 65% to about 75%, or any range or subrange therebetween. Providing a partial silica-like network can enable the first layer coating to be stiff (e.g., elastic modulus of about 30 GPa or more) while remaining flexible enough to withstand abrasion.

A ratio of atomic silicon to atomic oxygen in one or more layers of the coated article, such as the first layer 123 can be measured using XPS based on Si 2p fine structure relative to an overall amount of Si. In aspects, a ratio of atomic silicon to atomic oxygen in one or more layers of the coated article, such as the first layer 123 can range from 0.2 to 0.6, depending on presence of other cations and amounts of carbonaceous contaminations present on the surface.

The silica or silica-like network of the first layer 123 can also comprise Si—OH bonds. One way to quantify an amount (e.g., density) of hydroxyl in the first layer 123 is based on molar ratios determined by secondary-ion mass spectroscopy (SIMS). Unless otherwise indicated, samples were cleaned with a low-energy Ar gas cluster ion beam (GCIB) source before analysis with SIMS. A molar ratio at the surface can be measured using static SIMS. Unless otherwise indicated, the molar ratio is for a bulk of the first layer using dynamic SIMS (D-SIMS). Unlike static SIMS, dynamic SIMS erodes the surface to provide depth-resolved compositional information. As used herein, D-SIMS was conducted using a time-of-flight secondary ion mass spectrometer (ToF-SIMS) with a dual beam configuration. Unless otherwise indicated, the TOF-SIMS used for the results reported herein was a TOF-SIMS M6 instrument (available from IONTOF GmbH) equipped with a Nanoprobe50 bismuth source. The TOF-SIMS M6 instrument was operated with a dual-beam configuration, where the analysis beam was a 30 kilo-electron Volts (keV) Bi₃⁺beam with a current of about 0.1 pA and the sputter beam was 2 keV Cs⁺ with a current of about 120 nA. The sputter beam was configured form a 300 μm by 300 μm sputter “crater,” and the analysis beam was configured to impinge a 75 μm by 75 μm area centered in the sputter “crater.” Charge compensation was achieved using an electron flood gun operating with 20 nA beam current, 20 eV electron energy, and a 1.5 mm spot size focused on the location impinged by the analysis beam. The chamber was evacuated to a pressure of 5×10⁻⁷ Pascals (5×10⁻⁹ millibar) before being brought to and maintained at a pressure of 5×10⁻⁵ Pascals (5×10⁻⁷ millibar) using argon (e.g., 99.99999% purity). Data was collected in negative ion mode with the analyzer in the “all purpose” mode, an analyzer energy of 3000 V and a cycle time of 100 microseconds. Data was processed using Surface Lab software (version 7.3.125519 available from IONTOF GmbH). To obtain molar ratios from the ¹⁶O¹H⁻, ¹⁸O⁻, and ²⁸Si⁻ signals, the known isotope ratio between ¹⁸O⁻ and ¹⁷O ⁻ was used to calculate and subtract the ¹⁷O⁻ interference from the ¹⁶O¹H-signal. A normalized intensity was defined as the mass-interference-corrected ¹⁶O¹H signal divided by the ²⁸Si⁻ signal. The normalized intensity (¹⁶O¹H⁻/²⁸Si⁻) was further corrected to remove background signals (as determined from the normalized intensity (¹⁶O¹H⁻/²⁸Si⁻) measured from fused quartz) to determine a “corrected signal.” The corrected signal was converted to a hydrogen to silicon molar ratio (“molar ratio”) using a calibration curve (derived from a series of natural mid-ocean-ridge basaltic (MORB) glasses with known-OH concentrations and other silica and silicate minerals covering a range from 0.0 wt % to 1.98 wt %) with an equation of “molar ratio”=1.26*“corrected signal”.

Throughout the disclosure, the “molar ratio” in terms of the molar ratio of hydrogen to silicon refers to a molar ratio of hydrogen to silicon (i.e., a molar amount of hydrogen divided by a molar amount of silicon) as determined by SIMS analysis, unless explicitly recited otherwise, of a material (e.g., first layer 123). Without wishing to be bound by theory, it is believed that hydrogen is indicative of hydroxyl groups (e.g., silanol, Si—O—H). In aspects, a molar ratio (of hydrogen to silicon) can be about 0.2 or more (e.g., about 0.2 or more), about 0.21 or more, about 0.22 or more, about 0.23 or more, about 0.24 or more, about 0.25 or more, about 0.6 or less, about 0.55 or less, about 0.50 or less, about 0.45 or less, about 0.4 or less, about 0.37 or less, about 0.35 or less, about 0.32 or less, about 0.30 or less, or about 0.28 or less. In aspects, a molar ratio (of hydrogen to silicon) can be in a range from about 0.2 to about 0.6, about 0.2 to about 0.55, about 0.2 to about 0.5, about 0.2 to about 0.45, from about 0.20 to about 0.4 (e.g., from about 0.2 to about 0.4), from about 0.21 to about 0.37, from about 0.22 to about 0.35, from about 0.23 to about 0.32, from about 0.24 to about 0.32, from about 0.24 to about 0.30, from about 0.25 to about 0.28, or any range or subrange therebetween. In exemplary aspects, the molar ratio of hydrogen to silicon can be in a range from 0.20 to 0.4 or from about 0.22 to about 0.35. For example, as discussed below with reference to FIG. 32, the planarization layers in accordance with aspects of the present disclosure (e.g., Examples 35-40 and 42-44) exhibits a molar ratio of hydrogen to silicon of 0.20 or more, from about 0.20 to 0.4, or from about 0.22 to about 0.35. In further exemplary aspects, the molar ratio of hydrogen to silicon can be in a range from 0.20 to 0.6 or from about 0.25 to about 0.55. For example, as discussed below, the hydroxyl-modified layers in accordance with aspects of the present disclosure exhibits a molar ratio of hydrogen to silicon of 0.20 or more, from about 0.20 to 0.6, or from about 0.22 to about 0.55. In contrast, conventional methods of silica deposition (Comparative Examples JJ-KK) have a molar ratio of about 0.10 or less, meaning that Examples 35-40 and 42-44 have at least about double (2×) the molar ratio of Comparative Examples JJ-KK. In aspects, the molar ratio at the surface can be within any of the ranges recited above in this paragraph. In aspects, the molar ratio (of hydrogen to silicon) of the first layer can be greater than the molar ratio of a reactively sputtered silica layer by a multiple of 2 or more, 2.5 or more, 3 or more, 4 or more, 10 or less, 7 or less, 5 or less, or 4 or less. In aspects, the molar ratio (of hydrogen to silicon) of the first layer can be greater than the molar ratio of a reactively sputtered silica layer by a multiple in a range from about 2 to 10, from 2 to 7, from 2.5 to 5, from 2.5 to 4, from 3 to 4, or any range or subrange therebetween. In aspects, an ion intensity of carbon (as a ratio to the ion intensity of silicon) can be about 0.01 or less, about 0.005 or less, about 0.002 or less, or about 0.001 or less, for example, in a range from about 0.00001 to about 0.01, from about 0.00005 to about 0.005, from about 0.0001 to about 0.002, from about 0.0005 to about 0.001, or any range or subrange therebetween. The intensity of carbon is based on measurements that are corrected to remove background signals (as determined from the intensity of carbon measured from fused quartz).

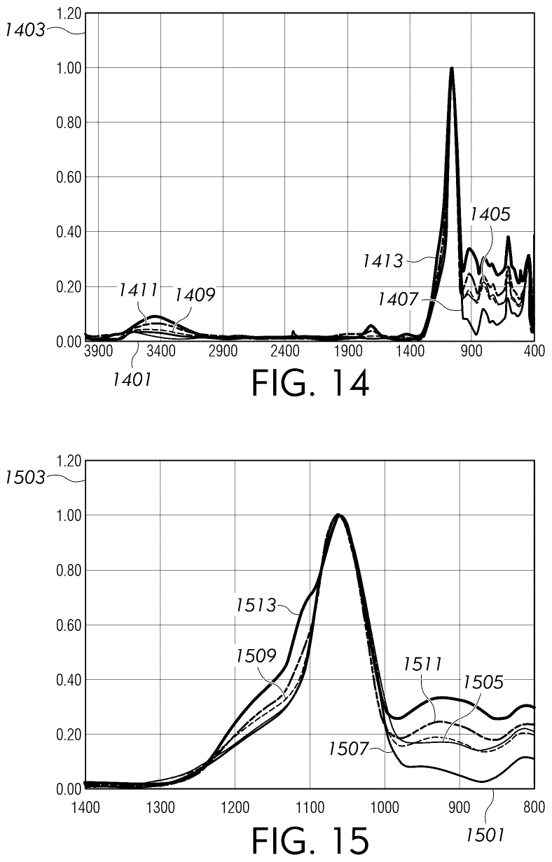

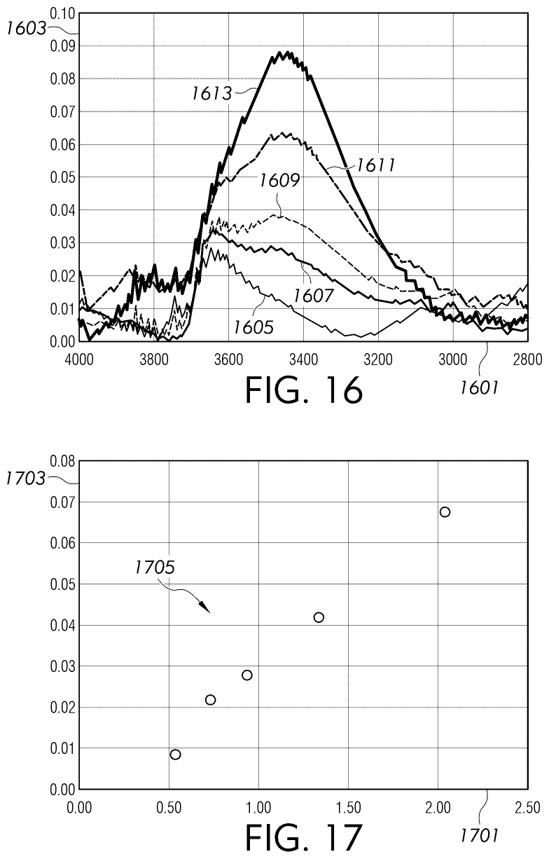

Another way to quantify an amount (e.g., density) of hydroxyl in the first layer is based on absorbance measured in infrared (IR) spectroscopy. As discussed below with reference to FIGS. 14 and 16, a broad absorbance associated with alcohols (e.g., hydroxyl (OH) stretch, for example, in silanols—Si—O—H) can be seen from about 3200 cm⁻¹ to about 3500 cm⁻¹ (e.g., with a peak centered around 3420 cm⁻¹). Also, as discussed below with reference to FIGS. 14 and 15, a broad absorbance is seen at 1059 cm⁻¹, which is attributed to an Si—O—Si structure. As used herein, a “hydroxyl ratio” is a peak absorbance of the broad hydroxyl signal (centered around 3420 cm⁻¹) divided by a peak absorbance of the Si—O—Si signal (centered at about 1060 cm⁻¹). In aspects, the hydroxyl ratio can be about 0.005 or more, about 0.008 or more, about 0.010 or more (e.g., about 0.01 or more), about 0.07 or less, about 0.06 or less, about 0.05 or less, or about 0.045 or less. In aspects, the hydroxyl ratio can be in a range from about 0.005 to about 0.07, from about 0.005 to about 0.06, from about 0.008 to about 0.5, from about 0.01 to about 0.045, or any range or subrange therebetween. For example, as discussed below with reference to FIG. 17, Examples 6-10 have a hydroxyl ratio of from 0.005 to 0.07. Examples 6-9 have a hydroxyl ratio from 0.005 to 0.06 (e.g., from 0.008 to 0.05 or from 0.01 to 0.045). Without wishing to be bound by theory, a hydroxyl ratio for a reactively sputtered silica layer is much lower than the hydroxyl ratios shown in FIG. 17. In aspects, the hydroxyl ratio of the first layer can be greater than the hydroxyl ratio of a reactively sputtered silica layer by a multiple of 2 or more, 3 or more, 4 or more, 5 or more, 8 or more, 20 or less, 15 or less, 12 or less, 10 or less, 8 or less, 6 or less, 5 or less, or 4 or less. In aspects, the hydroxyl ratio of the first layer can be greater than the hydroxyl ratio of a reactively sputtered silica layer by a multiple in a range from 2 to 20, from 3 to 20, from 4 to 15, from 5 to 15, from 8 to 12, from 8 to 10, or any range or subrange therebetween. In aspects, In aspects, the hydroxyl ratio of the first layer can be greater than the hydroxyl ratio of a reactively sputtered silica layer by a multiple of about 10 or less, for example, in a range from 2 to 10, from 3 to 8, from 3 to 6, from 3 to 5, from 3 to 4, or any range or subrange therebetween.

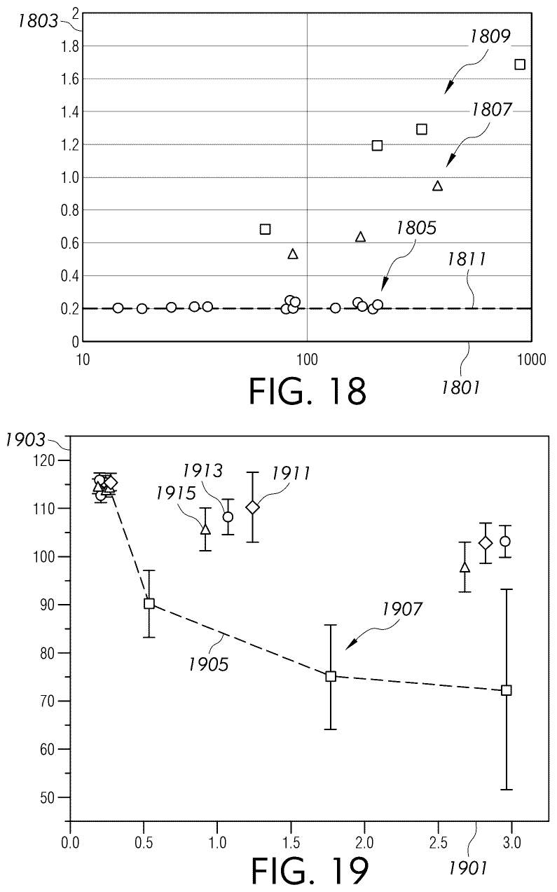

As used herein, “surface roughness” means the Ra surface roughness, which is an arithmetical mean of the absolute deviations of a surface profile from an average position in a direction normal to the surface of the test area. Ra surface roughness values for an 2 μm by 2 μm test area using atomic force microscopy (AFM). In aspects, the first layer 123 can comprise a surface roughness Ra (e.g., as-formed) of about 1 nm or less, 0.8 nm or less, 0.7 nm or less, about 0.60 nm or less (e.g., about 0.6 nm or less), about 0.50 nm or less (e.g., about 0.5 nm or less), 0.40 nm or less, 0.35 nm or less, about 0.30 nm or less, about 0.25 nm or less, about 0.1 nm or more, about 0.20 nm or more, about 0.25 nm or more, about 0.30 nm or more, or about 0.40 nm or more. In aspects, the first layer 123 can comprise a surface roughness Ra (e.g., as-formed) ranging from about 0.1 nm to about 1 nm, from about 0.1 nm to about 0.8 nm, from about 0.1 nm to about 0.7 nm, from about 0.1 nm to about 0.6 nm, from about 0.1 to about 0.50 nm, from about 0.15 nm to about 0.40 nm, from about 0.20 nm to about 0.35, from about 0.25 nm to about 0.30 nm, or any range or subrange therebetween. For example, FIG. 18 shows a relationship between the surface roughness of a coating on the vertical axis 1803 (i.e., y-axis) and the thickness on the horizontal axis 1801 (i.e., x-axis) of various coatings (i.e., points 1805 (circles) corresponding to the first layer of the present disclosure, points 1807 (triangles) corresponding to high-density plasma chemical vapor deposition (HDPCVD) silica, and points 1809 (squares) corresponding to sputtered silica). Without wishing to be bound by theory, the surface roughness Ra of the first surface area 125 of the first layer 123 can be within one of the above-mentioned layers when the second surface area 127 contacts the first major surface 105 of the substrate 103 (e.g., when the coated article does not contain an optical stack). Providing a low surface roughness (e.g., about 0.6 nm or less, from 0.1 nm to 0.6 nm, or from 0.15 nm to about 0.40 nm) can increase an abrasion resistance of a surface-modifying layer disposed thereon.

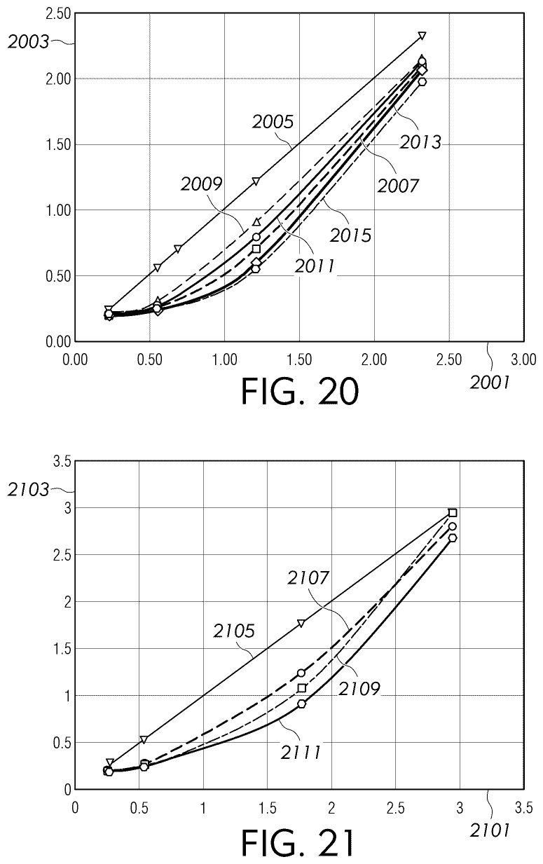

Alternatively or additionally, the first surface area 125 of the first layer 123 can provide a lower surface roughness than a surface that the second surface area 127 of the first layer 123 is in contact with (e.g., the first major surface 105 of the substrate 103 in FIG. 1, fourth major surface 207 of the optical stack 203 in FIG. 2A, and/or fourth major surface 207 of the capping layer 219 or 229 or optical stack 203a, or 203b in FIGS. 2B-2C). For example, the first layer can provide a decreased surface roughness Ra than would be obtained in an article (e.g., coated article) without the first layer, which enables the coated article of the present disclosure including the first layer to have increased abrasion resistance of the surface-modifying layer. For example, as shown in FIGS. 20-21, curves 2007, 2009, 2011, 2013, 2015, 2107, 2109, and 2111 in accordance with aspects of the present disclosure are associated with lower surface roughness Ra as indicated by the vertical axis 2003 or 2103 (i.e., y-axis) relative to a reactively sputtered silica coating corresponding to curves 2005 and 2105 for any common surface roughness Ra of the underlying surface (e.g., substrate) as indicated by the horizontal axis 2001 and 2101 (i.e., x-axis). In aspects, a ratio of the surface roughness Ra of the first surface area 125 of the first layer 123 to a surface roughness Ra of a surface in contact with the second surface area 127 of the first layer 123 can be about 0.90 or less, about 0.85 or less, about 0.85 or less, about 0.80 or less, about 0.75 or less, about 0.70 or less, about 0.65 or less, about 0.60 or less, about 0.55 or less, about 0.50 or less, about 0.1 or more, about 0.2 or more, about 0.3 or more, about 0.4 or more, about 0.5 or more. In aspects, a ratio of the surface roughness Ra of the first surface area 125 of the first layer 123 to a surface roughness Ra of a surface in contact with the second surface area 127 of the first layer 123 can be in a range from about 0.1 to about 0.90, from about 0.1 to about 0.85, from about 0.2 to about 0.80, from about 0.2 to about 0.75, from about 0.3 to about 0.70, from about 0.3 to about 0.65, from about 0.4 to about 0.60, from about 0.5 to about 0.55, or any range or subrange therebetween.

Without wishing to be bound by theory, it is believed that higher spatial frequencies of a surface (e.g., as measured by a 2D isotropic power spectral density discussed herein) impacts the abrasion resistance of a surface-modifying layer disposed thereon. For example, it is believed that decreasing the amplitude of these higher spatial frequencies can enable increased abrasion resistance. Overall surface roughness values such as surface roughness Ra may not fully capture the role of the decreased amplitude at higher spatial frequencies in the first layer. In contrast, aspects of the power spectral density (PSD) (e.g., 2D isotropic PSD) discussed herein may more directly describe these aspects of the first layer.

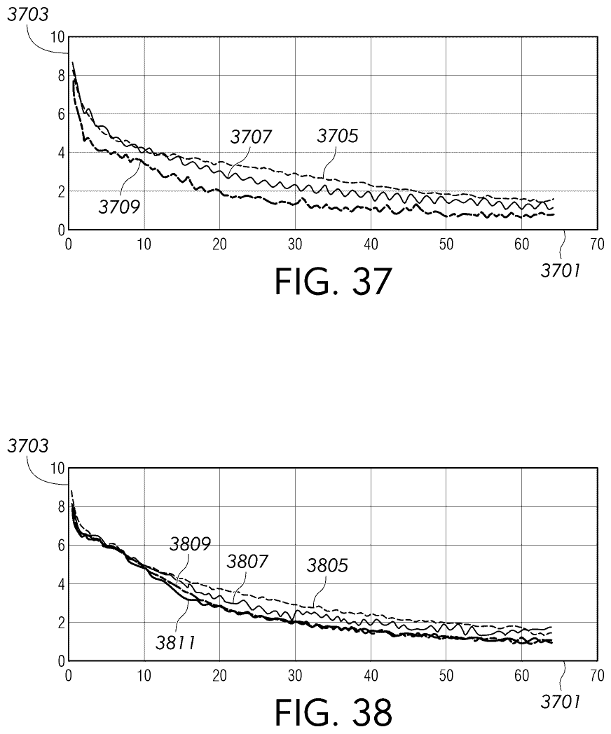

Throughout the disclosure, the “power spectral density” (PSD) of a surface refers to the two-dimensional (2D) isotropic power spectral density (PSD) determined from height data measured using atomic force microscopy (AFM) for a 2 μm by 2 μm test area of the surface. As used herein, “power spectral density” is a Fourier transform of the surface profile determined from the height data discussed in the previous sentence. The “2D isotropic” PSD of a surface refers to a PSD determined in both dimension of the surface (perpendicular to the height data) measured in nm⁴. Unless otherwise indicated, the power spectral density (PSD) is calculated using NanoScope Software available from Bruker Corporation using the default parameters for the 2D isotropic PSD. For example, FIGS. 25-26 and 37-38 schematically illustrate curves 2605, 2607, 2609, 2611, 2705, 2707, 2709, 2711, 3705, 3707, 3709, 3805, 3807, 3809, and/or 3811 corresponding to PSDs with the horizontal axis 2601, 2701, or 3701 (i.e., x-axis) corresponding to a spatial frequency in inverse micrometers (μm⁻¹) and the vertical axis 2603, 2703, or 3703 (i.e., y-axis) corresponds to a logarithm of the PSD in nm⁴. Specifically in FIG. 27, curve 2707 corresponding to a reactively sputtered silica coating has higher PSD values at spatial frequencies greater than or equal to about 15 μm⁻¹ relative to curves 2707, 2709, and 2711 that correspond to planarization layers with thicknesses of 22 nm, 38 nm, and 76 nm, respectively disposed on the reactively sputtered silica layer. Also, as shown in FIG. 37, curves 3707 and 3709 show that the planarization layers (with thicknesses of 23 nm and 58 nm, respectively) reduce the amplitude of the PSD at spatial frequencies greater than or equal to about 15 μm⁻¹ relative to curve 3705 without the planarization layer. Likewise, as shown in FIG. 38, curves 3807, 3809, and 3811 show that the planarization layers (with thicknesses of 23 nm, 41 nm, and 58 nm, respectively) reduce the amplitude of the PSD at spatial frequencies greater than or equal to about 15 μm⁻¹ relative to curve 3805 without the planarization layer.

As discussed herein, the decrease in amplitude at higher spatial frequencies is described in terms of an amplitude of the PSD at a predetermined spatial frequency (e.g., 30 μm⁻¹ or 40 μm⁻¹) and/or in terms of a ratio of the amplitude of the PSD at a higher spatial frequency relative to a lower spatial frequency (e.g., 30 μm⁻¹ or 40 μm⁻¹ relative to 10 μm⁻¹). In aspects, the first surface area 125 of the first layer 123 can exhibit an amplitude of the PSD at a spatial frequency that is about 500 nm⁴ or less (e.g., about 2.7 log units or less), about 400 nm⁴ or less (e.g., about 2.6 log units or less), about 300 nm⁴ or less (e.g., about 2.5 log units or less), about 200 nm⁴ or less, about 10 nm⁴ or more, about 50 nm⁴ or more, or about 100 nm⁴ or more (e.g., about 2.0 log units). In aspects, the first surface area 125 of the first layer 123 can exhibit an amplitude of the PSD at a spatial frequency of 30 μm⁻¹ can be in a range from about 10 nm⁴ to about 500 nm⁴ (e.g., from about 1 log unit to about 2.7 log units), from about 50 nm⁴ to about 400 nm⁴ (e.g., from about 1.7 log units to about 2.6 log units), from about 100 nm⁴ to about 300 nm⁴ (e.g., from about 2.0 log units to about 2.5 log units), from about 100 nm⁴ to about 200 nm⁴ (e.g., from about 2.0 log units to about 2.3 log units), or any range or subrange therebetween. In aspects, a ratio of an amplitude at a first spatial frequency of 30 μm⁻¹ divided by a second amplitude at a second spatial frequency of 10 μm⁻¹ (i.e., PSD (30 μm⁻¹)/PSD (10 μm⁻¹)) can be about 0.55 or less, about 0.3 or less, about 0.1 or less, about 0.05 or less, about 0.03 or less, about 0.01 or less, about 0.008 or less, about 0.005 or less, about 0.004 or less, about 0.0001 or more, about 0.0005 or more, about 0.001 or more, about 0.002 or more, or about 0.003 or more. In aspects, a ratio of an amplitude at a first spatial frequency of 30 μm⁻¹ divided by a second amplitude at a second spatial frequency of 10 μm⁻¹ (i.e., PSD (30 μm⁻¹)/PSD (10 μm⁻¹)) can be in a range from about 0.0001 to about 0.55, from about 0.0001 to about 0.3, from about 0.0001 to about 0.1, from about 0.0005 to about 0.05, from about 0.0005 to about 0.03, from about 0.005 to about 0.01, from about 0.001 to about 0.008, from about 0.001 to about 0.005, from about 0.002 to about 0.004, or any range or subrange therebetween. In aspects, a ratio of a logarithm of an amplitude at a first spatial frequency of 30 μm⁻¹ divided by a logarithm of an amplitude at a second spatial frequency of 10 μm⁻¹ (i.e., log [PSD (30 μm⁻¹)]/log [PSD (10 μm⁻¹)]) can be about 0.65 or less, about 0.60 or less, about 0.55 or less, about 0.50 or less, about 0.45 or less, about 0.1 or more, about 0.2 or more, about 0.3 or more, about 0.4 or more, or about 0.5 or more. In aspects, a ratio of a logarithm of an amplitude at a first spatial frequency of 30 μm⁻¹ divided by a logarithm of an amplitude at a second spatial frequency of 10 μm⁻¹ (i.e., log [PSD (30 μm⁻¹)]/log [PSD (10 μm 1)]) can be in a range from about 0.1 to about 0.65, from about 0.2 to about 0.60, from about 0.3 to about 0.55, from about 0.4 to about 0.55, from about 0.5 to about 0.55, or any range or subrange therebetween. In aspects, the first surface area 125 of the first layer 123 can exhibit an amplitude of the PSD at a spatial frequency of 40 μm⁻¹, which can be in a range from about 10 nm⁴ to about 500 nm⁴ (e.g., from about 1 log unit to about 2.7 log units), from about 50 nm⁴ to about 400 nm⁴ (e.g., from about 1.7 log units to about 2.6 log units), from about 100 nm⁴ to about 300 nm⁴ (e.g., from about 2.0 log units to about 2.5 log units), from about 100 nm⁴ to about 200 nm⁴ (e.g., from about 2.0 log units to about 2.3 log units), or any range or subrange therebetween. In aspects, a ratio of an amplitude at a first spatial frequency of 40 μm⁻¹ divided by a second amplitude at a second spatial frequency of 10 μm⁻¹ (i.e., PSD (40 μm⁻¹)/PSD (10 μm⁻¹)) can be about 0.55 or less, about 0.50 or less, about 0.4 or less, about 0.3 or less, about 0.1 or less, about 0.05 or less, about 0.03 or less, about 0.01 or less, about 0.008 or less, about 0.005 or less, about 0.004 or less, about 0.0001 or more, about 0.0005 or more, about 0.001 or more, about 0.002 or more, or about 0.003 or more. In aspects, a ratio of an amplitude at a first spatial frequency of 40 μm⁻¹ divided by a second amplitude at a second spatial frequency of 10 μm⁻¹ (i.e., PSD (40 μm⁻¹)/PSD (10 μm⁻¹)) can be in a range from about 0.0001 to about 0.55, about 0.0001 to about 0.4, from about 0.0001 to about 0.3, from about 0.0001 to about 0.1, from about 0.0005 to about 0.05, from about 0.0005 to about 0.03, from about 0.005 to about 0.01, from about 0.001 to about 0.008, from about 0.001 to about 0.005, from about 0.002 to about 0.004, or any range or subrange therebetween. In aspects, a ratio of a logarithm of an amplitude at a first spatial frequency of 40 μm⁻¹ divided by a logarithm of an amplitude at a second spatial frequency of 10 μm⁻¹ (i.e., log [PSD (40 μm⁻¹)]/log [PSD (10 μm−1)]) can be about 0.65 or less, about 0.60 or less, about 0.55 or less, about 0.50 or less, about 0.45 or less, about 0.40 or less, about 0.35 or less, about 0.30 or less, about 0.25 or less, about 0.20 or less, about 0.1 or more, about 0.2 or more, about 0.3 or more, about 0.4 or more, or about 0.5 or more. In aspects, a ratio of a logarithm of an amplitude at a first spatial frequency of 40 μm⁻¹ divided by a logarithm of an amplitude at a second spatial frequency of 10 μm⁻¹ (i.e., log [PSD (40 μm⁻¹)]/log [PSD (10 μm⁻¹)]) can be in a range from about 0.1 to about 0.65, from about 0.2 to about 0.60, from about 0.3 to about 0.55, from about 0.4 to about 0.55, from about 0.5 to about 0.55, from about 0.15 to about 0.4, from about 0.18 to about 0.35, or any range or subrange therebetween.

In aspects, a ratio of a 2D isotropic power spectral density of AFM height data at the first surface area of the first layer at a spatial frequency of 30 μm⁻¹ divided by a 2D isotropic power spectral density of AFM height data of a surface in contact with the first surface area at a spatial frequency of 30 μm⁻¹ may be about 0.9 or less, about 0.8 or less, about 0.7 or less, about 0.6 or less, or about 0.5 or less. In aspects, a ratio of a 2D isotropic power spectral density of AFM height data at the first surface area of the first layer at a spatial frequency of 40 μm⁻¹ divided by a 2D isotropic power spectral density of AFM height data of a surface in contact with the first surface area at a spatial frequency of 40 μm⁻¹ may be about 0.9 or less, about 0.8 or less, about 0.7 or less, about 0.6 or less, or about 0.5 or less.

In aspects, the coated articles described herein may be characterized as having an amount of excess oxygen. As used herein, “excess oxygen” may refer to an amount of oxygen present in the coated articles that is greater than a baseline amount of oxygen that is assumed to be present as oxides of silicon and aluminum in the coated articles. For example, an amount of silicon and aluminum present in the coated article may be determined using methods known in the art, and the measured amount of silicon and aluminum present may be assumed as stoichiometric oxides of silicon and aluminum. Using XPS, the fraction of oxygen in the coated articles (or an intermediate material prior to depositing the surface-modifying layer) can be estimated from the C 1s fine structure of the XPS spectra. The excess oxygen may be associated with the silanol content of the material. In aspects, the coated articles may have an amount of excess oxygen of at least 15%, at least 16%, at least 17%, at least 18%, at least 19%, or even at least 20%.

Throughout the disclosure, “surface-modifying layer” refers to a layer that is characterized by changing a physical property or other behavior of the coated article. For example, a surface-modifying layer can modify one or more of a water contact angle, an oleic contact angle, a visibility of a fingerprint (e.g., simulated fingerprint), and/or an ability to remove a fingerprint (e.g., by wiping).

In aspects, the surface-modifying layer can be an anti-fingerprint coating. Throughout the disclosure, a surface-modifying layer is an “anti-fingerprint” coating if the coating on a glass-based substrate can reduce the visibility of, reduce a color shift of, and/or reduce droplet formation of fingerprint oil disposed thereon relative to the glass-based substrate without the coating. As used herein, the visibility of a fingerprint refers to an absolute value of a difference in brightness (e.g., CIELAB L* value) for a portion of the anti-fingerprint coating with the fingerprint oil and another portion of the anti-fingerprint coating without the fingerprint oil. As used herein, the color shift of the glass-based substrate refers to a difference in measured color as √((a₁*−a₂*)²+(b₁*−b₂*)²), where a*refers to CIELAB a*values, b*refers to CIELAB b* values, subscript 1 refers to a portion of the anti-fingerprint coating without fingerprint oil, and subscript 2 refers to a portion of the anti-fingerprint coating with fingerprint oil. An anti-fingerprint coating can reduce droplet formation, which can increase a visibility and/or color shift of fingerprint oil, by being oleophilic, as defined below. Additionally, the anti-fingerprint coating can enable the removal of aqueous material (e.g., water droplets, sweat droplets) from the coating, for example, by being hydrophobic, as defined below. In further aspects, the anti-fingerprint coating can exhibit an (e.g., as-formed) water contact angle from 90° to 120°, an (e.g., as-formed) oleic acid contact angle of 40° or less, and a coefficient of friction of 0.25 or less. In further aspects, the easy-to-clean coating can be substantially free and/or free of fluorine. In aspects, a diiodomethane contact angle of an anti-fingerprint coating (e.g., as-formed) can be about 60° or more, about 62° or more, about 65° or more, about 80° or less, about 75° or less, about 73° or less, or about 70° or less. In aspects, a diiodomethane contact angle of an anti-fingerprint coating (e.g., as-formed) can range from about 60° to about 80°, from about 62° to about 75°, from about 65° to about 72°, or any range or subrange therebetween. In aspects, an anti-fingerprint coating can be oleophilic. In aspects, a hexadecane contact angle and/or an oleic acid contact angle of an anti-fingerprint coating (e.g., as-formed) can be about 45° or less, about 40° or less, about 30° or less, about 25° or less, about 20° or less, or the anti-fingerprint coating can wet hexadecane and/or oleic acid. In further aspects, the anti-fingerprint coating (e.g., as formed) wets hexadecane and/or oleic acid. Providing a low diiodomethane contact angle (e.g., about 60° or less) and/or a low hexadecane contact angle (e.g., about 30° or less) can reduce the visibility and/or color shift associated with fingerprints by enabling fingerprint oil to be dispersed across the anti-fingerprint coating rather than beading up into pronounced droplets.

In aspects, the surface-modifying layer can be an easy-to-clean coating. Throughout the disclosure, a surface-modifying layer is an “easy-to-clean” coating if the coating on a glass-based substrate can repel material and/or facilitate removal of material disposed thereon relative to the glass-based substrate without the coating. As used herein, an ability to repel material is determined based on a contact angle with higher contact angles associated with greater repulsion. As used herein, an ability to remove material is measured by wiping the material disposed on the surface (e.g., coating or glass-based substrate) with a cheesecloth (see details from the Cheesecloth Abrasion Test with the modification that the material is disposed on the surface before wiping) and the visibility of the material is monitored. A decreased visibility (e.g., fewer wiping cycles to achieve a predetermined reduction is visibility) is associated with a coating facilitating removal of material disposed thereon. In further aspects, the easy-to-clean coating can exhibit an (e.g., as-formed) water contact angle from 90° to 120°, an (e.g., as-formed) oleic acid contact angle of 50° or more, and a coefficient of friction of 0.25 or less. In further aspects, the easy-to-clean coating can be a fluorine-containing material. Alternatively, in further aspects, the easy-to-clean coating can be substantially free and/or free of fluorine. In aspects, a diiodomethane contact angle of an anti-fingerprint coating (e.g., as-formed) can be about 60° or more, about 62° or more, about 65° or more, about 80° or less, about 75° or less, about 73° or less, or about 70° or less. In aspects, a diiodomethane contact angle of an anti-fingerprint coating (e.g., as-formed) can range from about 60° to about 80°, from about 62° to about 75°, from about 65° to about 72°, or any range or subrange therebetween. In aspects, the anti-fingerprint coating can be oleophilic. In aspects, a hexadecane contact angle of the an anti-fingerprint coating (e.g., as-formed) can be about 45° or less, about 40° or less, about 30° or less, about 25° or less, about 20° or less, or the an anti-fingerprint coating can wet hexadecane. In further aspects, the anti-fingerprint coating (e.g., as formed) wets hexadecane. Providing a low diiodomethane contact angle (e.g., about 60° or less) and/or a low hexadecane contact angle (e.g., about 30° or less) can reduce the visibility and/or color shift associated with fingerprints by enabling fingerprint oil to be dispersed across the surface-modifying layer rather than beading up into pronounced droplets.

As shown in FIGS. 1 (by dashed lines) and 2A-2C, the coated article 101, 201, 221, or 221 can comprise the surface-modifying layer 113 disposed over the first major surface 105 of the substrate 103. The surface-modifying layer 113 comprises an inner surface 117 facing the first major surface 105 of the substrate 103. In aspects, as shown in FIGS. 1 (by dashed lines) and FIGS. 2A-2C, the surface-modifying layer 113 can be disposed on the first layer 123. In further aspects, as shown, the inner surface 117 of the surface-modifying layer 113 can be face, contact, and/or otherwise be bonded to the first surface area 125 of the first layer 123. In further aspects, as shown in FIGS. 2A-2C, the first layer 123 can be positioned between the surface-modifying layer 113 and the optical stack 203, 203a, or 203b (e.g., an optical film 231, a scratch-resistant layer 233, anti-glare coating, anti-reflection coating). In aspects, as shown in FIGS. 1 and 2A-2C, the surface-modifying layer 113 comprises an exterior surface 115 that forms an exterior surface of the coated article 101, 201, 211, or 221. Consequently, a user would interact with the coated article 101, 201, 211, or 221 by, for example, touching the exterior surface 115 or viewing an image through the exterior surface 115. Alternatively, as indicated by the dashed lines in FIG. 1, the coated article 101 may not have a surface-modifying layer 113 disposed on the first layer 123.

As shown in FIGS. 1 and 2A-2C, a surface-modifying thickness 119 of the surface-modifying layer 113 is defined as an average distance between the inner surface 117 and the exterior surface 115. In aspects, the surface-modifying thickness 119 can be about 1 nm or more, about 2 nm or more, about 3 nm or more, about 5 nm or more, about 10 nm or more, about 20 nm or more, about 50 nm or more, about 500 nm or less, about 200 nm or less, about 100 nm or less, about 75 nm or less, about 50 nm or less, about 25 nm or less, about 15 nm or less, about 10 nm or less, about 8 nm or less, about 7 nm or less, about 6 nm or less, about 5 nm or less, or about 4 nm or less. In aspects, the surface-modifying thickness 119 can be in a range from about 1 nm to about 500 nm, from about 1 nm to about 200 nm, from about 1 nm to about 100 nm, from about 1 nm to about 75 nm, from about 1 nm to about 50 nm, from about 1 nm to about 25 nm, from about 1 nm to about 15 nm, from about 2 nm to about 10 nm, from about 2 nm to about 8 nm, from about 2 nm to about 5 nm, from about 3 nm to about 5 nm, or any range or subrange therebetween. The surface-modifying thickness 119 is determined from a cross-sectional image taken using a scanning electron microscope (SEM).

In aspects, the surface-modifying layer 113, the first layer 123, and/or the coated article 101, 201, 211, or 221 can comprise an average transmittance (as described above) of about 80% or more, about 85% or more, about 88% or more, about 89% or more, about 90% or more, about 91% or more, about 92% or more, or about 93% or more. In aspects, the average transmittance of the surface-modifying layer 113, the first layer 123, and/or the coated article 101, 201, 211, or 221 can range from about 80% to 100%, from about 85% to about 99%, from about 88% to about 97%, from about 89% to about 97%, from about 90% to about 96%, from about 91% to about 95%, from about 92% to about 94%, or any range or subrange therebetween. In aspects, the transmittance of the surface-modifying layer 113, the first layer 123, and/or the coated article 101, 201, 211, or 221 at 550 nm can be within one or more of the ranges mentioned above in this paragraph for the average transmittance.

As used herein, haze refers to transmission haze that is measured through the surface-modifying layer 113, the first layer 123, and/or through the coated article 101, 201, 211, or 221 (through the exterior surface 115) in accordance with ASTM D1003-21 at 0° relative to a direction normal to the exterior surface 115. Haze is measured using a HAZE-GARD PLUS available from BYK Gardner with an aperture over the source port. The aperture has a diameter of 8 mm. A CIE C illuminant is used as the light source for illuminating the surface-modifying layer 113, the first layer 123, and/or through the coated article 101, 201, 211, or 221. In aspects, the surface-modifying layer 113, the first layer 123, and/or through the coated article 101, 201, 211, or 221 comprises a haze of about 5% or less, about 2% or less, about 1.5% or less, about 1% or less, about 0.5% or less, or about 0.1% or less, for example from about 0.01% to about 5%, from about 0.01% to about 2%, from about 0.05% to about 1.5%, from about 0.05% to about 1%, from about 0.1% to about 0.5%, or any range or subrange therebetween.

Throughout the disclosure, a coefficient of friction refers to a dynamic coefficient of friction measured in accordance with ASTM D1894-14. Unless otherwise indicated, “coefficient of friction” refers to the “dynamic coefficient of friction.” In aspects, the exterior surface 115 of the surface-modifying layer 113 can comprise a dynamic coefficient of friction of about 0.25 or less, about 0.22 or less, about 0.20 or less, about 0.18 or less, or about 0.15 or less. In aspects, the exterior surface 115 of the surface-modifying layer 113 can comprise a dynamic coefficient of friction in a range from 0.05 to about 0.25, from about 0.10 to about 0.22, from about 0.12 to about 0.20, from about 0.15 to about 0.18, or any range or subrange therebetween.

Throughout the disclosure, contact angles are determined for a drop of a corresponding liquid disposed on the exterior surface (not treated with plasma nor corona) using a 30 gauge needle with the contact angle measured using a goniometer in accordance with ASTM D5946. If a contact angle cannot be reliably determined due to a high degree of droplet spread corresponding to a contact angle of 15° or less, then the coating is said to “wet” the droplet material. As used herein, water contact angles are measured using a drop of deionized water. As used herein, a coating is “hydrophobic” if it has a water contact angle of 100° or more. As used herein, a coating is “superhydrophobic” if it has a water contact angle of 130° or more. As used herein, an “as-formed” coating refers to a coating that has not been subjected to an abrasive (e.g., see Steel Wool Abrasion Test and Cheesecloth Abrasion Test below). As used herein, a coating is “oleophilic” if it has a hexadecane contact angle of less than 60°.

In aspects, the surface-modifying layer 113 (e.g., as-formed) is hydrophobic but not superhydrophobic. In aspects, the water contact angle of the surface-modifying layer 113 (e.g., as-formed) can be about 90° or more, about 100° or more, about 105° or more, about 110° or more, about 115° or more, about 120° or less, about 115° or less, or about 110° or less. In aspects, the water contact angle of the surface-modifying layer 113 (e.g., as-formed) can range from about 90° to about 120°, from about 100° to about 115°, from about 105° to about 110°, or any range or subrange therebetween. Providing a high water contact angle (e.g., about 100° or more) can enhance the removal of aqueous material (e.g., water droplets, sweat droplets) from the surface-modifying layer.

Throughout the disclosure, surface energy (e.g., total surface energy) and components thereof (e.g., polar, dispersive) are calculated using the Wu model based on contact angle measurements, as described above. In aspects, the surface-modifying layer 113 can comprise a total surface energy of about 35 milliNewtons per meter (mN/m) or less, about 32 mN/m or less, about 30 mN/m or less, about 29 mN/m or less, about 28 mN/m or less, or about 27 mN/m or less. In aspects, the surface-modifying layer 113 can comprise a total surface energy ranging from about 20 mN/m to about 35 mN/m, from about 22 mN/m to about 32 mN/m, from about 25 mN/m to about 30 mN/m, from about 25 mN/m to about 29 mN/m, from about 26 mN/m to about 28 mN/m or any range or subrange therebetween. In aspects, the surface-modifying layer 113 can comprise a dispersive surface energy of about 30 mN/m or less, about 28 mN/m or less, about 26 mN/m or less, about 25 mN/m or less, about 24 mN/m or less, or about 23 mN/m or less. In aspects, the surface-modifying layer 113 can comprise a dispersive surface energy ranging from about 15 mN/m to about 30 mN/m, from about 18 mN/m to about 28 mN/m, from about 20 mN/m to about 26 mN/m, from about 22 mN/m to about 25 mN/m, or any range or subrange therebetween. In aspects, the surface-modifying layer 113 can comprise a polar surface energy of about 6 mN/m or less, about 4 mN/m or less, about 3 mN/m or less, or about 2 mN/m or less. In aspects, the surface-modifying layer 113 can comprise a dispersive surface energy ranging from about 0.5 mN/m to about 6 mN/m, from about 1 mN/m to about 4 mN/m, from about 1 mN/m to about 3 mN/m, from about 1.5 mN/m to about 2 mN/m, or any range or subrange therebetween. For example, providing a low total surface energy (including a low dispersive surface energy and/or a low polar surface energy) can enable oils (e.g., fingerprint oil) to be dispersed across the surface-modifying surface (e.g., oleophilic), which can decrease a visibility and/or a color shift associated with fingerprints.

Throughout the disclosure, the “Steel Wool Abrasion Test” is used to determine the durability of a coating. For the Steel Wool Abrasion Test, steel wool (Bonstar #0000) was cut into strips (25 mm x12 mm) and placed on a sheet of aluminum foil to bake in an oven for 2 hours at 100° C. A steel wool strip was fitted to an attachment (10 mm x10 mm) of an abrader (5750, Taber Industries) using a zip tie. Weights totaling 720 grams were added to the Taber arm to result in a total applied load of 1 kilogram. The stroke length was set at 25 mm, the speed was set to 40 cycles per minute, and testing occurred at 23° C. The area to be abraded was marked onto the back of the sample for tracking. A sample of the coating was secured in the abraded and subjected to 2,000 cycles, 3,000 cycles, or 3,500 cycles. After the coating is abraded for the predetermined number of cycles, an abraded water contact angle is measured in accordance with the method for the contact angle described above. Unless otherwise indicated, the abraded water contact angle is calculated as the average of 12 water contact angle measurements taken at evenly spaced locations along the abraded area. A high contact angle (e.g., about 85° or more, about 90° or more) is indicative of the surface-modifying layer surviving the Steel Wool Abrasion Test. Decreases in the contact angle below 70 degrees correlate with a loss of the surface-modifying layer. In aspects, the abraded water contact angle (e.g., of the surface-modifying layer disposed on the first layer in a coated article in accordance with aspects of the present disclosure) after 2,000 cycles, 3,000 cycles, and/or 3,500 cycles in the Steel Wool Abrasion Test can be about 80° or more, about 85° or more, about 88° or more, or about 90° or more.

Throughout the disclosure, the “Cheesecloth Abrasion Test” is also used to determine the durability of a coating. In the Cheesecloth Abrasion Test, 4 layers of cheesecloth wrap (Crockmeter Squares for American Standards, 200877; SDL Atlas USA, Rock Hill, SC) are affixed to a cylindrical tip with a radius of 2 cm of a Linear Taber Abrader (Model 5750; Taber Industries, North Tonawanda, NY) with a constant load of 750 grams. The path-length of each swipe is 15 mm, with each cycle comprising a forward and backward swipe to return the tip to its original position before proceeding with the next cycle. The speed was 30 cycles per minute, testing occurred at 23° C. After the coating is abraded for 200,000 cycles, a cheesecloth-abraded water contact angle is measured in accordance with the method for the contact angle described above In aspects, a cheesecloth-abraded water contact angle of the surface-modifying layer 113 (e.g., disposed on the first layer in a coated article in accordance with aspects of the present disclosure) can be about 80° or more, about 85° or more, about 88° or more, about 90° or more, about 95° or more, or about 100° or more. In aspects a difference between the water contact angle of the surface-modifying layer (as-formed) and the cheesecloth-abraded water contact angle (after 200,000 cycles) can be about 20° or less, about 15° or less, about 12° or less, about 10° or less, or about 8° or less (e.g., when the surface-modifying layer is disposed on the first layer in a coated article in accordance with aspects of the present disclosure). As demonstrated by the results of the Steel Wool Abrasion Test and the Cheesecloth Abrasion Test, the surface-modifying layer disposed on the first layer in a coated article in accordance with aspects of the present disclosure can withstand abrasion and maintain good contact angles.

Throughout the disclosure, the “Rubber Abrasion Test” is also used to determine the durability of a coating. In the Rubber Abrasion Test, a 6 mm diameter by 20 mm rod of rubber is affixed to a cylindrical tip with a length of 5 mm of a Linear Taber Abrader (Model 5750; Taber Industries, North Tonawanda, NY) with a constant load of 1 kg. The path-length of each swipe is 15 mm, with each cycle comprising a forward and backward swipe to return the tip to its original position before proceeding with the next cycle. The speed was 40 cycles per minute, testing occurred at 23° C. After the coating is abraded for 3,000 cycles, a rubber-abraded water contact angle is measured in accordance with the method for the contact angle described above. In aspects, a rubber-abraded water contact angle of the surface-modifying layer 113 can be about 80° or more, about 85° or more, about 90° or more, about 95° or more, about 100° or more, about 105° or more, or about 110° or more. In aspects a difference between the water contact angle of the surface-modifying layer (as-formed) and the rubber-abraded water contact angle (after 3,000 cycles) can be about 15° or less, about 12° or less, about 10° or less, or about 8° or less.

In aspects, a visibility of a fingerprint on the surface-modifying layer 113, as defined above as an absolute value of a difference between CIELAB L* values for a portion of the surface-modifying layer with and without fingerprint oil, can be about 15 or less, about 10 or less, about 8 or less, about 5 or less, about 2 or less. In aspects, a visibility of a fingerprint on the surface-modifying layer can range from 0 to 15, from about 0.5 to about 10, from about 1 to about 8, from about 2 to about 5, or any range or subrange therebetween. In aspects, a color shift of a fingerprint on the surface-modifying layer 113, as defined above as √((a₁*−a₂*) 2+ (b₁*−b₂*)²), can be about 15 or less, about 10 or less, about 8 or less, about 5 or less, about 2 or less. In aspects, a color shift of a fingerprint on the surface-modifying layer 113 can range from 0 to 15, from about 0.5 to about 10, from about 1 to about 8, from about 2 to about 5, or any range or subrange therebetween.

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent to the front surface of the housing. The display can comprise liquid crystal display (LCD), an electrophoretic displays (EPD), an organic light-emitting diode (OLED) display, or a plasma display panel (PDP). The consumer electronic product can comprise a cover substrate disposed over the display. In aspects, at least one of a portion of the housing or the cover substrate comprises the coated article and/or the first layer discussed throughout the disclosure. The consumer electronic product can comprise a portable electronic device, for example, a smartphone, a tablet, a wearable device, or a laptop.

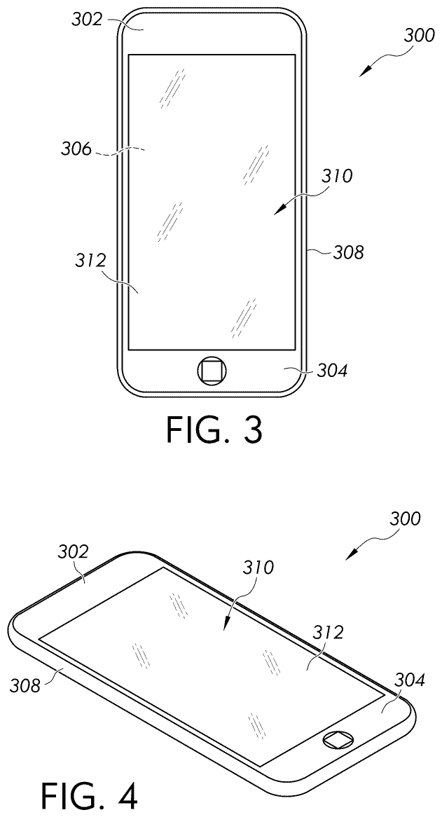

The coated article and/or first layer disclosed herein may be incorporated into another article, for example, an article with a display (or display articles) (e.g., consumer electronics, including mobile phones, tablets, computers, navigation systems, wearable devices (e.g., watches), and the like), architectural articles, transportation articles (e.g., automotive, trains, aircraft, sea craft, etc.), appliance articles, or any article that may benefit from some transparency, scratch-resistance, abrasion resistance or a combination thereof. An exemplary article incorporating any of the coated articles and/or first layer disclosed herein is shown in FIGS. 3-4. Specifically, FIGS. 3-4 show a consumer electronic device 300 including a housing 302 having front 304, back 306, and side surfaces 308. Although not shown, the consumer electronic device can comprise electrical components that are at least partially inside or entirely within the housing. For example, electrical components include at least a controller, a memory, and a display. As shown in FIGS. 3-4, the display 310 can be at or adjacent to the front surface of the housing 302. The consumer electronic device can comprise a cover substrate 312 at or over the front surface of the housing 302 such that it is over the display 310. In aspects, at least one of the cover substrate 312 or a portion of housing 302 may include any of the coated articles and/or first layers disclosed herein.

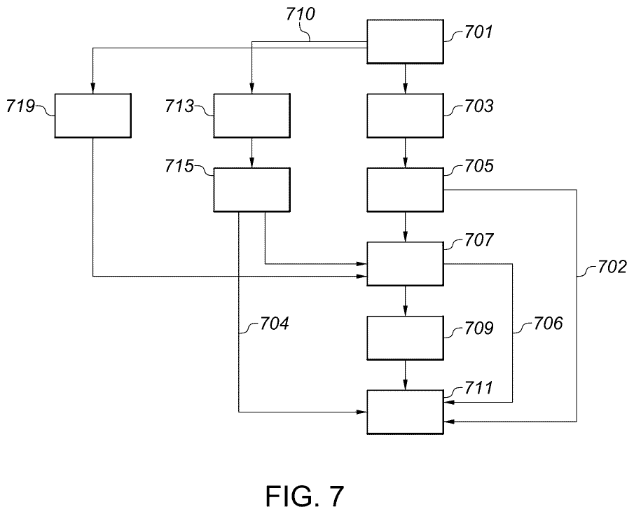

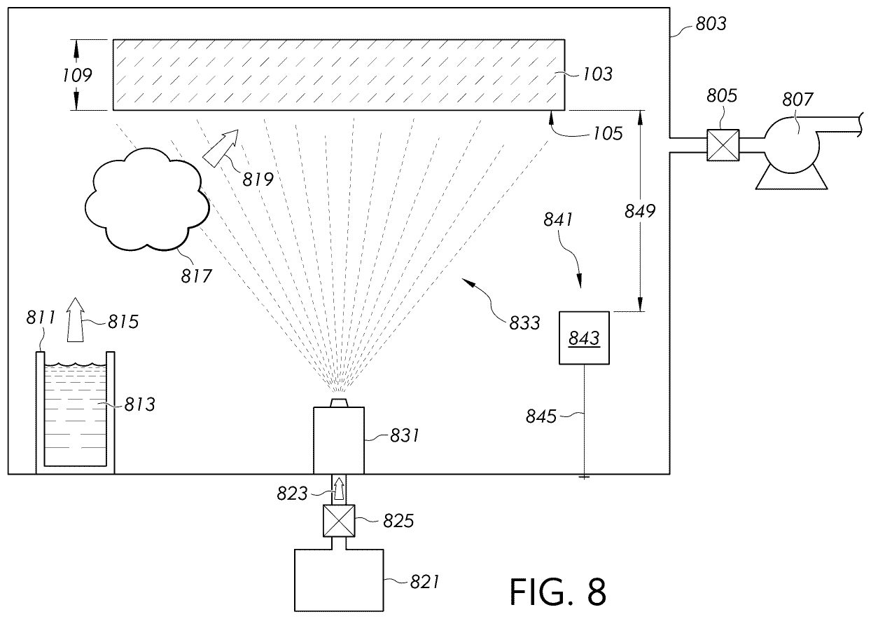

Aspects of methods of making the coated articles in accordance with aspects of the disclosure will be discussed with reference to the flow chart in FIG. 7 and example method steps illustrated in FIGS. 8-11. In a first step 701, methods can start with obtaining a substrate 103. In aspects, the substrate 103 may be provided by purchase or otherwise obtaining a substrate or by forming the substrate. In aspects, the substrate 103 can comprise a glass-based substrate and/or a ceramic-based substrate. In further aspects, glass-based substrates and/or ceramic-based substrates can be provided by forming them with a variety of ribbon forming processes, for example, slot draw, down-draw, fusion down-draw, up-draw, press roll, redraw, or float. In further aspects, ceramic-based substrates can be provided by heating a glass-based substrate to crystallize one or more ceramic crystals. The substrate 103 comprises a first major surface 105 that can extend along a first plane 104. In aspects, as indicated in FIG. 1, an optical stack 203 comprising an anti-reflective coating and/or a gradient coating comprising a refractive index gradient can be disposed on and/or bonded to the first major surface 105. Although not shown in FIGS. 8-11, it is to be understood that the optical stack 203, 203a, or 203b can be disposed on the first major surface 105. In aspects, the substrate 103 can be chemically strengthened with one or more compressive stress regions (or central tension regions) comprising any of the aspects related to depth of compression, maximum compressive stress, and/or tensile stress discussed above for the corresponding property.

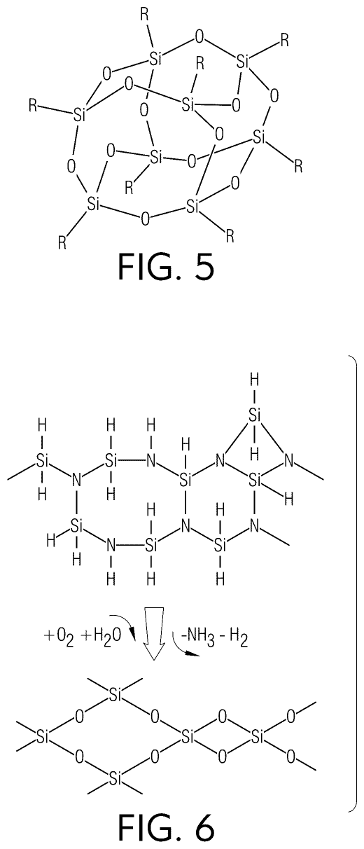

In aspects, step 701 can further comprise obtaining a functionalized polyhedral oligomeric silsesquioxane (POSS). As used herein, a polyhedral oligomeric silsesquioxane (POSS) refers to a functionalized oligomer silsesquioxane consisting of RSiO_{1.5} monomers. Exemplary aspects of functionalized POSS can comprise 6, 8, 10, or 12 RSiO_{1.5} monomers, although other aspects are possible. For example, functionalized oligomeric silsesquioxane consisting of 8 RSiO1.5 monomers is an octahedral functionalized POSS (e.g., polyoctahedral silsesquioxane). FIG. 5 shows a functionalized POSS, namely, an octahedral functionalized POSS, where R are functional groups that can be independently selected from the functional groups discussed below.

In aspects, functionalized oligomeric silsesquioxanes can be formed from condensation reactions of silane. As used herein, a condensation reaction produces an R₂O byproduct, where R can include any of the R units discussed below and can further comprise hydrogen (e.g., with a hydroxyl or water byproduct). For example, silanes (e.g., R₃OSi) can be reacted to form terminal RSiO₂ monomers. For example, a terminal RSiO₂ monomer can react with another RSiO₂ monomer (e.g., terminal, non-terminal) to form an RSiO_{1.5} monomer as an oxygen atom of one monomer forms a bond with a silicon atom of another monomer, producing the condensation byproduct. It is to be understood that the RSiO_{1.5} silsesquioxane monomers are different from siloxane monomers, which can include M-type siloxane monomers (e.g., R₃SiO_{0.5}), D-type siloxane monomers (e.g., R₂SiO₂), and/or silica-type siloxane monomers (SiO₂).

Functionalized oligomeric silsesquioxanes can be functionalized by one or more functional groups. For methods including step 703 discussed with reference to the flow chart in FIG. 7 (e.g., thermally evaporating the functionalized oligomeric silsesquioxane), a functional group functionalizing the functionalized oligomeric silsesquioxane can exclude hydrogen. In aspects, the functional group functionalizing the functionalized oligomeric silsesquioxane can exclude bisphenols, fluorine-containing functional groups isocyanates, epoxies, glycidyls, oxirane, sulfur-containing functional groups (e.g., thiols), anhydrides, acrylates, methacrylates, and/or alkynes. In aspects, the functional group functionalizing the functionalized oligomeric silsesquioxane be an alkyl group, an alkene group, an aromatic group (e.g., a phenyl group), a silane (e.g., alkyl silyl group), or combinations thereof. As used herein, an alkyl group contains a saturated hydrocarbon with carbon-carbon single bonds and hydrogen bonded to carbon atoms. In aspects, alkyl functional groups can range from 1 to 10 carbons (i.e., C₁-C₁₀ alkyl), for example, from 1 to 8 carbons (i.e., C₁-C₈ alkyl) or from 1 to 4 carbons (i.e., C₁-C₄ alkyl). Exemplary aspects of alkyl functional groups include methyl and isobutyl. An exemplary aspect of an aromatic functional group is a phenyl group. An exemplary aspect of a silane includes a dimethylsilyl group. As used herein, an alkene group contains an unsaturated hydrocarbon with one or more carbon-carbon double bonds. Alkenes can optionally include one or more carbon-carbon single bonds (e.g., alkyl chains in the alkene group). In even further aspects, the functionalized POSS can be at least partially functionalized by alkenes containing from 2 to 8 carbons (i.e., C₂-C₅ alkenes). At least partially functionalized by a functional group B means that one or more of the R-groups shown in FIG. 5 is B. Completely functionalized mean that 95% or more of all R-groups shown in FIG. 5 are B. An exemplary aspect of an alkene functionalized POSS is a vinyl POSS, for example, partially vinyl functionalized vinyl/isobutyl POSS (OL1123 available from Hybrid Plastics) or octa-vinyl POSS (OL1170 available from Hybrid Plastics). An exemplary aspect of an aromatic functionalized POSS is octaphenyl POSS (MS0840 available from Hybrid Plastics).

Exemplary aspects of alkyl functionalized POSS are octamethyl POSS (MS0830 available from Hybrid Plastics) and octa (iso-butyl) POSS (MS0825 available from Hybrid Plastics). Providing a short chain (e.g., about 8 carbons or less) for functionalizing the functionalized POSS can enable the functionalized POSS to be evaporated during step 703. Providing one or more of the functional groups discussed above functionalizing the functionalizing POSS can reduce the reactivity of the functionalized POSS before it is impinged by the ion beam and/or disposed on the substrate (e.g., by sterically hindering interactions between functionalized POSS), which can enable be used to produce the partially condensed silica-like network described above.

Alternatively, for example, when methods include step 713 with reference to the flow chart in FIG. 7 (e.g., applying a solution comprising the functionalized oligomeric silsesquioxane or a polysilazane), the functional group functionalizing the functionalized oligomeric silsesquioxane can be hydrogen or an alkyl group. In aspects, the functional group functionalizing the functionalized oligomeric silsesquioxane can exclude bisphenols, fluorine-containing functional groups isocyanates, epoxies, glycidyls, oxirane, sulfur-containing functional groups (e.g., thiols), anhydrides, acrylates, methacrylates, and/or alkynes. In aspects, the functional group functionalizing the functionalized oligomeric silsesquioxane can be hydrogen, an alkyl group, an alkene group, an aromatic group, a silane, or combinations thereof. For example, the functional group can be one or more of the functional groups discussed above in the previous paragraph in addition to hydrogen. In further aspects, the functional group functionalizing the functionalized oligomeric silsesquioxane can consist of carbon and/or hydrogen. In even further aspects, the functionalized oligomeric silsesquioxane can be at least partially functionalized by and/or completely functionalized by hydrogen. In further aspects, the functionalized POSS can be at least partially functionalized by alkanes containing from 2 to 8 carbons (i.e., C₂-C₈ alkanes), for example, an ethane, a propane, a butane, an isobutane, a pentane, an isopentane, a hexane, a branched C₆ alkane (e.g., isohexane, ethylbutane, propylpropane) a heptane, a branched C_{z} heptane (e.g., isoheptane, ethylpentane, propylbutane), an octane, or a branched C₈ octane (e.g., isooctane, ethylheptane, propylhexane, butylheptane). In even further aspects, the functionalized POSS can be at least partially functionalized by alkanes containing from 2 to 8 carbons (i.e., C₂-C₈ alkanes). In exemplary aspects, the functionalized POSS can be functionalized by a C₂-C₈ alkane, including branched C₂-C₈ alkanes, for example an isobutyl group.

Throughout the disclosure, an effective diameter of a molecule (e.g., functionalized POSS) is measured using dynamic light scattering in accordance with ISO 22412:2017. In aspects, an effective diameter of a functionalized POSS can be about 20 nm or less, about 15 nm or less, about 10 nm or less, about 6 nm or less, about 1 nm or more, about 2 nm or more, or about 4 nm or more. In aspects, an effective diameter of a functionalized POSS can be in a range from about 1 nm to about 20 nm, from about 1 nm to about 15 nm, from about 2 nm to about 15 nm, from about 2 nm to about 10 nm, from about 4 nm to about 10 nm, from about 4 nm to about 6 nm, from about 1 nm to about 6 nm, from about 2 nm to about 6 nm, or any range or subrange therebetween. In further aspects, a mean effective diameter of the functionalized POSS can be within one or more of the ranges discussed above in this paragraph. In further aspects, substantially all and/or all of the functionalized POSS can be within one or more of the ranges for the effective diameter of a functionalized oligomeric silsesquioxane discussed above.

After step 701, as shown in FIG. 8, methods can proceed to step 703 comprising evaporating a functionalized POSS onto the first major surface 105 of the substrate 103. In aspects, as shown, step 703 can comprise placing the substrate 103 in a chamber 803 (e.g., vacuum chamber) that can be maintained at a reduced pressure. In aspects, the reduced pressure can be about 50,000 Pascals (Pa) or less, about 1,000 Pa or less, about 1 Pa or less, about 0.5 Pa or less, about 10⁻⁶ Pa or more, about 10⁻⁴ Pa or more, or about 10⁻³ Pa. In aspects, the reduced pressure can range from about 10⁻⁶ Pa to about 1,000 Pa, from about 104 to about 1 Pa, from about 10⁻³ to about 0.5 Pa, from about 10⁻³ Pa to about 10⁻¹ Pa, or any range or subrange therebetween. In aspects, the pressure (e.g., reduced pressure) of the chamber 803 can be maintained by operating one or more of the valve 805 and 825. In further aspects, the pressure of the chamber 803 can be reduced or maintained by opening the valve 805 connected to a pump 807 that can remove gas from the chamber 803. In further aspects, the pressure of the chamber 803 can be increased or maintained by opening the valve 825 connected to a gas source 821, which adds gas to the chamber, as indicated by arrow 823. In aspects, the gas source 821 can provide a non-reactive gas (e.g., argon, helium, krypton), oxygen, nitrogen, air, or a combination thereof. Providing a reduced pressure when evaporating the functionalized POSS can increase a rate of evaporation and/or enable a wide range of functionalized POSS materials to be used.

As shown in FIG. 8, the functionalized POSS 813 can be positioned in a container 811 placed within the chamber 803. In the chamber 803, the functionalized POSS 813 can evaporate (as indicated by arrow 815) into the gas phase (as indicated by cloud 817) that can be disposed on the first major surface 105 of the substrate 103 (as indicated by arrow 819). Exemplary aspects of the container 811 include a Knudsen cell or an effusion cell. In aspects, the container 811 can be maintained at a temperature of about 50° C. or more, about 65° C. or more, about 75° C. or more, about 90° C. or more, about 110° C. or less, about 200° C. or less, about 170° C. or less, about 150° C. or less, about 135° C. or less, about 120° C. or less, or about 110° C. or less. In aspects, the container 811 can be maintained at a temperature ranging from about 50° C. to about 200° C., from about 65° C. to about 170° C., from about 75° C. to about 150° C., from about 90° C. to about 135° C., from about 110° C. to about 135° C., or any range or subrange therebetween. Heating the container can facilitate evaporation of the functionalized POSS, which can increase a deposition rate.

In aspects, as shown in FIG. 8, a deposition rate of the functionalized POSS 813 can be monitored using a sensor 841 comprising a surface 843 that is positioned a predetermined distance 849 from the surface (e.g., first major surface 105 of the substrate 103), for example, with the position being maintained by a support 845. In further aspects, the sensor 841 can be configured to detect nanogram differences in mass from material deposited on the surface 843 during step 703 and/or 705, where the increase in mass and predetermined surface area of the surface 843 can be used to determine an effective deposition rate. It is to be understood that the “effective deposition rate” is not necessarily the actual deposition rate on the surface (e.g., first major surface 105), and, in fact, may overestimate the actual deposition rate by as much as a factor or 2 or 3. An exemplary aspect of the sensor 841 is a quartz crystal microbalance (QCM). As used herein, the “deposition rate” refers to the effective deposition rate as measured by a QCM (sensor 841) positioned 500 mm below the surface (predetermined distance 849) and 150 mm above the container 811. In aspects, a deposition rate (e.g., effective deposition rate from QCM) of the functionalized POSS 813 in step 703 can be about 0.01 nanometers per second (nm/s) (0.1 A/s) or more, about 0.03 nm/s (0.3 A/s) or more, about 0.05 nm/s or more (0.5 A/s), about 0.07 nm/s (0.7 A/s) or more, about 0.1 nm/s (1 A/s) or more, less than about 0.20 nm/s (2.0 A/s), about 0.18 nm/s (⅛ A/s) or less, about 0.15 nm/s (1.5 A/s) or less, about 0.13 nm/s (1.3 A/s) or less, or about 0.10 nm/s (1.0 A/s or less). In aspects, a deposition rate (e.g., effective deposition rate from QCM) of the functionalized POSS 813 in step 703 can range from about 0.01 nm/to less than about 0.20 nm/s, from about 0.03 nm/s to about 0.18 nm/s, from about 0.05 to about 0.15 nm/s, from about 0.07 nm/s to about 0.12 nm/s, from about 0.07 nm/s to about 0.10 nm/s, or any range or subrange therebetween. As demonstrated in FIGS. 12 and 20, deposition rates (e.g., effective deposition rates from QCM) of less than 0.20 nm/s for the specific conditions tested produced a first layer (e.g. planarization layer) within the scope of the present disclosure. Controlling the deposition rate and/or evaporation rate of the functionalized POSS within one or more of the above-mentioned ranges can efficiently (e.g., quickly) deposit a substantially uniform coating of the functionalized POSS on the first major surface. In aspects, at the end of step 703, a thickness of the functionalized POSS disposed on the first major surface 105 can be within one or more of the ranges discussed above with reference to the first layer thickness 129. Without wishing to be bound by theory, it is believed that the evaporation of the functionalized POSS and deposition onto the first major surface does not in itself chemically (e.g., covalently) bond the functionalized POSS to the first major surface or modify the structure of the functionalized POSS. An Exemplary aspect of the container 811 in a Radak II cell that can be used in the chamber 803, for example, an Angstrom Engineering Evovac chamber. Although not shown, it is to be understood that if an optical stack 203 was disposed on the first major surface 105 that the functionalized POSS 813 would be disposed over the first major surface 105 and disposed on the optical stack 203.

After step 703 (or concurrent with step 703), as shown in FIG. 7, methods can proceed to step 705 comprising impinging an ion beam traveling as a plume 833 on the surface (e.g., first major surface 105 of the substrate 103). As shown, the substrate 103 can be in the chamber 803, which can be the same chamber 803 discussed above with reference to step 703. In aspects, as shown in FIG. 8, a beam source 831 can be configured to emit an ion beam traveling as a plume 833 that is incident on the first major surface 105 of the substrate 103. The beam source 831 can be operated such that the ion beam traveling as a plume 833 impinges the entire surface (e.g., first major surface 105). In aspects, the ion beam source 831 can comprise an end-Hall ion source, a grided ion source, or an inductively coupled plasma (ICP) ion source. An exemplary aspect of a beam source 831 is an end-Hall ion source. In aspects, the beam source 831 can generate the ion beam using a discharge current. Without wishing to be bound by theory, it is believed that an extent of reaction (e.g., from functionalized POSS to partial silica-like network) is influenced by the ion beam energy and discharge current. In further aspects, the discharge current can be about 0.25 Amps (A) or more, about 0.3 A or more, about 0.35 A or more, about 1 A or less, about 0.75 A or less, or about 0.5 A or less. In further aspects, the discharge current can range from about 0.25 A to about 1 A, from about 0.3 A to about 0.75 A, from about 0.35 A to about 0.5 Å, or any range or subrange therebetween. In aspects, the beam source 831 can be operated at a voltage of about 100 Volts (V), for example, from about 50 V to about 220 V, from about 70 V to about 120 V, from about 90 V to about 110 V, or any range or subrange therebetween. In aspects, the ion beam can comprise ions of oxygen, ions of argon, or combinations thereof. The composition of the ion beam can be adjusted through choice of the gas source 821 and controlling an amount of gas released from the gas source 821 (e.g., using the valve 825). In aspects, the chamber 803 (e.g., vacuum chamber) can be maintained at a reduced pressure within one or more of the ranges discussed above for the reduced pressure in step 703 (e.g., from about 10⁻⁸ Pa to about 10⁻⁷ Pa).

Without wishing to be bound by theory, it is believed that the ion beam disrupts the cage structure of the functionalized POSS, volatilizes the functional groups functionalizing the functionalized POSS, and/or causes the functionalized POSS to become bonded to the surface it is disposed on (e.g., the first major surface 105 as shown in FIG. 8 or the fourth major surface 207 of the optical stack 203, if present). At the end of step 705, the first layer 123 (e.g. planarization layer) (see FIGS. 1, 2A-2C, and 11) formed can comprise a silica or a partial silica-like network, for example, with a percentage of silicon atoms in the coating being in a silica-like network within one or more of the ranges discussed above for the percentage of silica atoms in the planarization layer in a silica or a silica-like network. Additionally or alternatively, at the end of step 705, the planarization layer (see FIGA. 1, 2A-2C, and 11) formed can comprise a ratio of Si—O—Si bonds to silicon atoms within one or more of the ranges discussed above for the ratio of Si—O—Si bonds to silicon atoms. In aspects, at the end of step 705, the planarization layer (see FIGA. 1, 2A-2C, and 11) formed can comprise any of the aspects discussed above with reference to the surface roughness Ra and/or the power spectral density (PSD). In further aspects, impinging the ion beam in step 705 can convert at least a fraction of the silicon atoms in a cage structure of the functionalized POSS to a partial Si—O—Si network (i.e., Si—O—Si bonds). In even further aspects, the fraction of silicon atoms converted in step 705 can range from about 50% to about 90%, from about 60% to about 80%, from about 65% to about 75%, or any range or subrange therebetween.

In aspects, the evaporating the functionalized POSS 813 of step 703 and the impinging the ion beam of step 705 can occur simultaneously. As used herein, steps 703 and 705 occurring “simultaneously” means that there is at least one point in time where the activities of steps 703 and 705 are both occurring. It is to be understood that it can still be simultaneous if one of the steps begins before the other step ends and/or if one of the steps ends before the other one ends, although both steps 703 and 705 can begin at the same time and/or end at the same time in further aspects. As shown in FIG. 8, the container 811 (e.g., Knudsen cell or an effusion cell), the substrate 103, and at least a portion of a path travelled by the ion beam can be positioned in the chamber 803 such that the functionalized POSS 813 in the gas phase (as indicated by 817) and/or disposed on the first major surface 105 can be impinged by the ion beam. Performing steps 703 and 705 simultaneously can facilitate the formation of the planarization layer with good adhesion to the substrate 103 and/or that is relatively homogenous. Providing a discharge current of about 0.25 A or more can facilitate the formation of the planarization layer, for example, producing an ion beam with sufficient energy to cause the functionalized POSS to react with other functionalized POSS and/or the first major surface 105 of the substrate 103 at an appreciable rate (e.g., compared to lower discharge currents). Providing a discharge current of about 1 A or less can provide an ion beam that is not so strong as to remove any POSS material being disposed by the evaporating. Additionally, performing steps 703 and 705 simultaneously can decrease processing time.

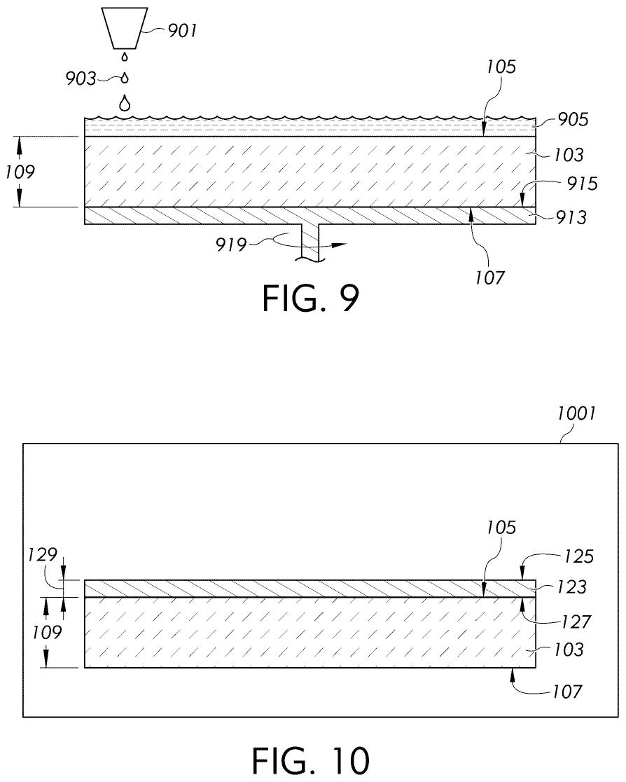

Alternatively, after step 701, as shown in FIG. 9, methods can proceed to step 713 comprising disposing the precursor solution 903 containing the functionalized POSS and/or polysilazane over the first major surface 105 of the substrate 103. In aspects, as shown FIG. 9, the precursor solution 903 can be dispensed from a container 901 (e.g., conduit, flexible tube, micropipette, ink-jet print head, or syringe) over (e.g., onto) the first major surface 105 of the substrate 103 to form a precursor layer 905. In further aspects, the precursor solution can comprise a polysilazane. As used herein, “polysilazane” is a polymer comprising a backbone of silicon and nitrogen. An exemplary polysilazane is perhydropolysilazane. For example, as shown by the top compound in FIG. 6, the polysilazane can consist of alternating silicon and nitrogen atoms in a backbone of the polysilazane with hydrogen atoms bonded thereto. In further aspects, a concentration of the polysilazane or the POSS the precursor solution 903 can be about 0.1 wt % or more, about 0.2 wt % or more, about 0.5 wt % or more, about 1 wt % or more, about 1.5 wt % or more, about 2 wt % or more, about 25 wt % or less, about 15 wt % or less, about 6 wt % or less, about 5 wt % or less, about 4 wt % or less, about 3 wt % or less, about 2.5 wt % or less, or about 2 wt % or less. In further aspects, a concentration of wherein a concentration of the polysilazane or the POSS the precursor solution 903 can range from about 0.1 wt % to about 25 wt %, from about 0.2 wt % to about 25 wt %, from about 0.2 wt % to about 15 wt %, from about 0.2 wt % to about 6 wt %, from about 0.2 wt % to about 5 wt %, from about 0.5 wt % to about 4 wt %, from about 1 wt % to about 3 wt %, from about 1.5 wt % to about 2.5 wt %, or any range or subrange therebetween.

In further aspects, as shown, step 713 can comprise spin coating the precursor solution 903 over (e.g., onto) the first major surface 105, for example, by disposing the second major surface 107 of the substrate over a surface 915 of a holder 913 and the holder can be rotated (as shown by arrow 919) while and/or after the precursor solution 903 is disposed over the first major surface 105. In even further aspects, the holder 913 can be rotated at 200 revolutions per minute (rpm) or more, about 500 rpm or more, about 700 rpm or more, about 4,000 rpm or less, about 2,500 rpm or less, or about 1,500 rpm or less. In even further aspects, the holder 913 can be rotated from 200 rpm to about 4,000 rpm, from about 500 rpm to about 2,500 rpm, from about 700 rpm to about 1,500 rpm, or any range or subrange therebetween. Spin coating the precursor solution can form a substantially uniform precursor layer over the first major surface of the substrate.

After step 713, as shown in FIG. 10, methods can proceed to step 715 comprising heating the precursor layer 905 of the precursor solution 903 (see FIG. 9) at a first temperature for a first period of time to form the planarization layer. In aspects, as shown, the substrate 103 can be placed in an oven 1001 maintained at the first temperature for the first period of time. In aspects, the first temperature can be about 150° C. or more, about 170° C. or more, about 190° C. or more, about 400° C. or less, about 300° C. or less, about 250° C. or less, about 230° C. or less, or about 210° C. or less. In aspects, the first temperature can range from about 150° C. to about 400° C., from about 150° C. to about 300° C., from about 150° C. to about 250° C., from about 170° C. to about 230° C., from about 190° C. to about 210° C., or any range or subrange therebetween. In aspects, the first period of time can be about 5 minutes or more, about 10 minutes or more, about 20 minutes or more, about 25 minutes or more, about 2 hours or less, about 1.5 hours or less, about 1 hour or less, or about 40 minutes or less. In aspects, the first period of time can range from about 5 minutes to about 2 hours, from about 10 minutes to about 1.5 hours, from about 20 minutes to about 1 hour, from about 25 minutes to about 40 minutes, or any range or subrange therebetween. In aspects, the precursor solution 903 can comprise a catalyst or be free from a catalyst. In aspects, the precursor solution 903 can contain a silane in addition to the functionalized POSS. The silane can comprise any of the aspects discussed above for silanes.

Without wishing to be bound by theory, heating the precursor layer of the precursor solution can remove solvent from the precursor layer and/or partially cure the functionalized POSS, for example, to form a silica or a partial silica-like network. For example, heating the POSS can cause the silicon-oxygen network to rearrange to a silica-like network and/or bond to a surface (e.g., first major surface 105) that the precursor solution is disposed on. Also, it is to be understood that these reactions may continue in subsequent steps (e.g., step 707).

Alternatively, after step 701, methods can proceed to step 719 comprising impinging a plasma at the first major surface 105 of the substrate 103. Such embodiments may produce the first layer 123 referred herein as a “hydroxyl-modified layer”, which may form on the first major surface 105 of the substrate 103. In aspects, the impinging may occur in a chamber comprising a chamber pressure ranging from about 1 Pascal (Pa) to about 100 Pa. For example, in aspects, the chamber pressure may be from about 1 P to about 90 Pa, from about 3 P to about 85 Pa, from about 5 P to about 80 Pa, from about 10 P to about 75 Pa, from about 20 P to about 70 Pa, or any range or subrange therebetween. In aspects, the chamber may comprise molecules or ions of oxygen, hydrogen, hydroxyl, or combinations thereof. In aspects, water vapor may be introduced into the chamber to produce the molecules or ions of oxygen, hydrogen, hydroxyl, or combinations thereof. Such embodiments may be referred to as using a “water vapor plasma”. Without intending to be bound by any particular theory, it is believed that methods that use a water vapor plasma may provide an appropriate proportion of O₂ and H₂ used to produce the hydroxyl-modified layer described herein. Embodiments utilizing a water vapor plasma may also reduce operation cost over embodiments utilizing separate gas containers. In aspects, the method may not include separately adding O₂ and/or H₂ in the chamber and instead may introduce water vapor in the chamber. In aspects, O₂ and H₂ may be introduced sequentially or simultaneously to the chamber prior to the impinging, during the impinging, subsequent to the impinging, or combinations thereof. In aspects, O₂ may be introduced into the chamber for a first duration of time, and H₂ may be introduced into the chamber for a second duration of time. The introduction of O₂ and H₂ sequentially into the chamber may be repeated any number of times, such as at least two times, at least 5 times, at least 10 times, or even at least 20 times. In aspects during the first duration of time, a concentration of O₂ in the chamber may be at least 60 mol. % relative to a total volume of gases in the chamber. For example, in aspects, during the first duration of time, a concentration of 02 in the chamber may be at least 60 mol. %, at least 70 mol. %, at least 80 mol. %, at least 90 mol. %, at least 95 mol. %, at least 99 mol. %, or at least 99.99 mol. % relative to a total volume of gases in the chamber. In aspects during the second duration of time, a concentration of H₂ in the chamber may be at least 60 mol. % relative to a total volume of gases in the chamber. For example, in aspects, during the second duration of time, a concentration of H₂ in the chamber may be at least 60 mol. %, at least 70 mol. %, at least 80 mol. %, at least 90 mol. %, at least 95 mol. %, at least 99 mol. %, or at least 99.99 mol. % relative to a total volume of gases in the chamber. In aspects, the plasma may be a radio frequency plasma. An areal power density of the radio frequency plasma during the impinging may be at least 0.2 watts per cm² (W/cm²). For example, an areal power density of the radio frequency plasma during the impinging may be at least 0.2 W/cm², at least 0.3 W/cm², at least 0.4 W/cm², at least 0.5 W/cm², at least 0.6 W/cm², at least 0.7 W/cm², at least 0.8 W/cm², at least 0.9 W/cm², at least 1.0 W/cm², at least 1.5 W/cm², or at least 2.0 W/cm². An areal power density of the radio frequency plasma during the impinging may be less than or equal to 5.0 W/cm². For example, a power of the radio frequency plasma during the impinging may be less than or equal to 4.0 W/cm², less than or equal to 3.0 W/cm², less than or equal to 2.5 W/cm², less than or equal to 2.0 W/cm², or less than or equal to 1.5 W/cm². In particular aspects, the areal power density of the radio frequency plasma during the impinging may be may be greater than or equal to 0.2 W/cm² and less than or equal to 1.0 W/cm². In aspects, a duration of the impinging the plasma at the first major surface 105 of the substrate 103 may be for a treatment time of greater than or equal to about 10 seconds and less than or equal to about 30 minutes. For example, in aspects, the duration of the impinging the plasma at the first major surface 105 of the substrate 103 may be for a treatment time of greater than or equal to about 20 seconds and less than or equal to about 15 minutes, greater than or equal to about 30 seconds and less than or equal to about 12 minutes, greater than or equal to about 45 seconds and less than or equal to about 10 minutes, greater than or equal to about 60 seconds and less than or equal to about 5 minutes, or any range or subrange therebetween. In aspects, a temperature of the chamber during the impinging the plasma at the first major surface of the substrate is greater than or equal to about 10° C. and less than or equal to about 200° C. For example, in aspects, a temperature of the chamber during the impinging the plasma at the first major surface of the substrate is greater than or equal to about 10° C., greater than or equal to about 20° C., or greater than or equal to about 30° C., and less than or equal to about 200° C., less than or equal to about 175° C., less than or equal to about 150° C., less than or equal to about 100° C., less than or equal to about 75° C., or less than or equal to about 50° C., and less than or equal to about 200° C. In particular aspects, the temperature of the chamber during the impinging the plasma at the first major surface of the substrate may be greater than or equal to about 30° C. and less than or equal to about 50° C.

The method step of 719 may result in a reduced change in thickness of the substrate 103 compared to other methods such as those demonstrated in FIG. 8 and FIG. 9 described herein. For example, in aspects, prior to impinging the plasma at the first major surface 105 of the substrate 103, a thickness of the substrate 103 may be an initial thickness, and subsequent to impinging the plasma at the first major surface 105 of the substrate 103, a combined thickness of the substrate 103 and the hydroxyl-modified layer is referred to a modified thickness, and a difference between the initial thickness and the modified thickness may be less than or equal to about 10 nm. In aspects, the difference between the initial thickness and the modified thickness may be less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, less than or equal to about 2 nm, or less than or equal to about 1 nm.

Without intending to be bound by any particular theory, it is believed that the plasma impacted surface layer of the article may possess a high concentration of silanol groups which allows the surface to be readily modified to form a surface-modifying layer, such as a silane-based easy to clean (ETC) coatings (non-fluorinated or perfluorinated) on the hydroxyl-modified layer. Further, it is believed that for a radio frequency plasma operating in a chamber comprising molecules or ions of oxygen, hydrogen, hydroxyl, or combinations thereof, the method can facilitate the breaking of Si—O bonds while simultaneously or sequentially modifying the surface with hydrogen. The hydrogen plasma exposure under or immediately after oxygen plasma ion bombardment may lead to the formation of a hydroxyl enriched surface layer extending at into the surface. Such embodiments may reduce the surface roughness of the coated article at high spatial frequencies while minimally changing the overall thickness of the substrate and/or the coated article. Further, it is believed that the methods described herein utilizing the plasma may be adjusted to result in significant reduction in surface roughness at high frequencies while maintaining a relatively high overall surface roughness Ra if desired. For example, in embodiments, the coated article may have a first layer having a 2D isotropic power spectral density of AFM height data at the first surface area of the first layer with a value of about 400 nm⁴ or less, about 300 nm⁴ or less, or about 250 nm⁴ or less at a spatial frequency of 40 μm⁻¹ and the first surface area of the first layer exhibits a surface roughness Ra of at least 0.5 nm, at least 1.5 nm, at least 2.0 nm, or even at least 2.5 nm.

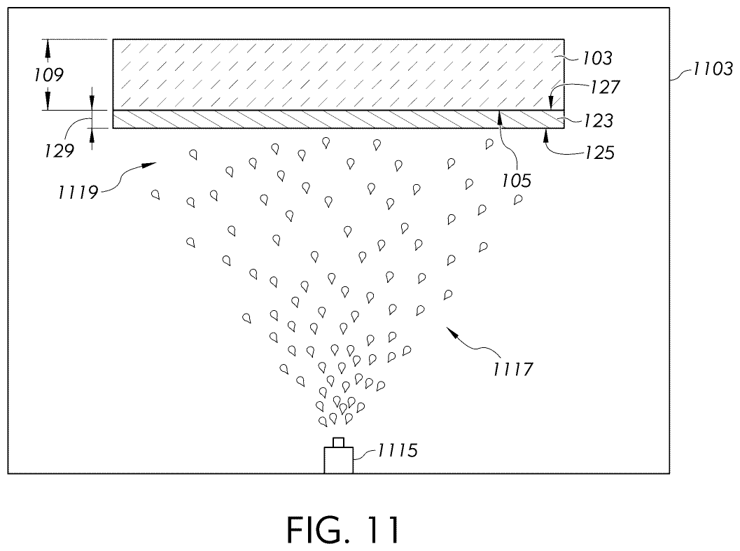

In aspects, after step 705, 715, or 719 as shown in FIG. 11, methods can proceed to step 707 comprising disposing a surface-modifying layer 113 (see FIGS. 1 and 2A-2C) on the first surface area 125 of the first layer 123. In further aspects, as shown, step 707 can comprise spraying droplets 1117 of a solution from a nozzle 1115 towards the first surface area 125 of the first layer 123 (e.g., as a cone 1119). In further aspects, the solution can be spray coated on the first layer 123 to form the surface-modifying layer 113. In further aspects, the droplets 1117 of the solution can comprise an alkyl silane. As used herein, an “alkyl silane” refers to a compound comprising an alkyl chain directly bonded to a silicon atom of a silane group, and the silane group can be bonded to other silane groups (e.g., forming a siloxane or siloxane-like network). In further aspects, step 707 can be performed at atmospheric pressure and/or a pressure within one or more of the ranges discussed above for step 703. In further aspects, step 707 can further comprise heating the deposited solution (e.g., from droplets 1117), for example by placing the substrate 103 in an oven 1103. For example, the chamber 1003 can be an inert ampoule is heated by an oven at from about 60° C. to about 200° C. (e.g., about 60° C. or more, about 80° C. or more, about 90° C. or more, about 100° C. or more, about 120° C. or more, about 140° C. or more, about 250° C. or less, about 220° C. or less, about 200° C. or less, about 180° C. or less, or about 160° C. or less). Samples with a silane-containing surface modification layer can be optionally plasma treated for surface activation with an O₂ or Ar plasma, and placed in the ampoule with a drop of silane, sealed and heated for from about 2 hours to about 5 hours. Providing an elevated temperature when evaporating the silane and reacting the silane with the coating can increase a rate of evaporation, enable a wide range of coating materials (e.g., silanes) to be used, increase a reaction rate or reactivity of the silane, and/or promote the formation of a covalent bonding to first surface area 125 of the first layer 123. Without wishing to be bound by theory, a coating material (e.g., silane) reacting with the first surface area 125 of the first layer 123 is believed to leave a majority (e.g., 50% or more, 60% or more, 70% or more, 75% or more) of surface hydroxyls (at the first surface area 125) of the first layer 123 unreacted and that such reaction will still leave a bulk concentration of hydroxyl groups in the first layer 123 within one or more of the corresponding ranges discussed above.

In particular aspects, the coated article may include a glass substrate, a hydroxyl-modified layer positioned on the glass substrate, and a surface-modifying layer disposed on the hydroxyl-modified layer, wherein the hydroxyl-modified layer is positioned between the glass substrate and the surface-modifying layer. In particular aspects, the coated article may include a glass-ceramic substrate, a hydroxyl-modified layer positioned on the glass-ceramic substrate, and a surface-modifying layer disposed on the hydroxyl-modified layer, wherein the hydroxyl-modified layer is positioned between the glass-ceramic substrate and the surface-modifying layer.

In particular aspects, the coated article may include a glass-ceramic substrate, an AR coating, a hydroxyl-modified layer, and a surface-modifying layer. In particular aspects, the coated article may include an AR coating, positioned between a glass-ceramic substrate and the hydroxyl-modified layer, and a surface-modifying layer positioned on the hydroxyl-modified layer.

Another embodiment which we also have demonstrated is using a low vacuum chamber with a vapor source such as a YES-1124P (available from Yield Engineering Systems). Other manufacturers have similar systems. For example, the chamber can be heated at a temperature from about 100° C. to about 200° C. and evacuated to a pressure of about 10 Pa. Substrates are optionally exposed to a Ar or O₂ capacitively coupled plasma generated by low or high frequency RF. After pumping to base pressure the silane precursor vapor is introduced to the chamber. One method of silane vaporization is using a liquid vaporizer. Liquid can be injected by a pulse pump into a heated vaporization cell with independent temperature control where it is vaporized and travels through independently heated passage into the chamber. With independent temperature control condensation in the passage can be prevented. Vaporization of the silane can raise the chamber pressure by from about 1 Pa to about 100 Pa, and the substrates are exposed to the vapor for a time (e.g., from about 2 minutes to about 20 minutes) and the chamber is evacuated with the pump to remove excess vapors and condensation products.

In another embodiment, a high vacuum coating chamber similar to FIG. 8. Substrates are cleaned with the End-Hall or ICP ion source and the silane is vaporized from either a liquid injection source similar to that described above, or desorbed from a sorbate (typically enclosed in a canister) using a thermal source such as a resistively heated tungsten boat, an effusion or Knudsen cell, or an electron beam evaporator. Deposition rate and total thickness can be monitored in these systems with a quartz crystal monitor (QCM). This type of chamber is commonly used in production of fluorinated ETC coatings on handheld devices such as cellphones.

In aspects, after step 707, methods can proceed to step 709 comprising assembling the coated article comprising the surface-modifying layer 113 into a consumer electronic device. For example, the surface-modifying layer 113 can comprise an exterior surface of a display portion of a display device and/or a touch-sensor. For example, the surface-modifying layer 113 can comprise an exterior surface of at least a portion of a consumer electronic device.

After step 705, 707, 709, 715, or 719 methods can proceed to step 711, where methods of making the coated article can be complete. In aspects, methods of making a coated article in accordance with aspects of the disclosure can proceed along steps 701, 703, 705, 707, 709, and 711 of the flow chart in FIG. 7 sequentially, as discussed above. In aspects, methods can follow arrow 710 from step 701 to step 713 if the planarization layer is to be formed by solution coating (see FIGS. 9-10) in steps 713 and 715 rather than evaporation and ion-beam impingement (see FIG. 8) in steps 703 and 705. In aspects, methods can follow arrow 702 from step 705 to step 711, for example, if methods of making the coated article are complete at the end of step 705. In aspects, methods can follow arrow 704 from step 715 to step 711, for example, if methods of making the coated article are complete at the end of step 715. In aspects, methods can follow arrow 706 from step 707 to step 711, for example, if methods of making the coated article are complete at the end of step 707. In aspects, methods can follow arrow 717 from step 701 to step 719 if the first layer (e.g. hydroxyl-modified layer) is to be formed by plasma treatment in step 719 rather than solution coating (see FIGS. 9-10) in steps 713 and 715 or evaporation and ion-beam impingement (see FIG. 8) in steps 703 and 705. Any of the above options may be combined to make a coated article in accordance with the embodiments of the disclosure.

It is known that POSS materials can be cured at high temperatures (e.g., about 600° C. or more). However, the methods discussed above with reference to the flow chart in FIG. 7 can subject the functionalized POSS to a maximum temperature (e.g., through the evaporating of the functionalized POSS, impingement with the ion-beam, and subsequent functionalization with a silane) of about 250° C. or less (e.g., about 220° C. or less, about 200° C. or less, about 180° C. or less, about 160° C. or less, about 120° C. or less, or about 50° C. or less) to obtain the surface-modifying layer 113. Consequently, the properties of the surface-modifying layer 113 formed in this way can exhibit a partial silica-like network (e.g., from about 50% to about 90%) as opposed to a substantially complete silica-like network, which could be formed from higher temperature treatments. As discussed below, the increased elastic modulus associated with exposing functionalized POSS materials to higher temperatures is associated with poor abrasion resistance.

### EXAMPLES

Various aspects will be further clarified by the following examples. Examples 1-5 and 11-44, Comparative Examples AA-KK, Assemblies A-T, and Assemblies AAA-JJJ comprised an exemplary glass-based substrate (Coating 1, (C1) according to Table 3) with a thickness of 0.55 mm. Unless otherwise states, the glass-based substrate had a surface roughness Ra of about 0.2 nm. Examples 6-10 comprised a silicon substrate for analysis by infrared spectroscopy. Examples 45-107 comprised the exemplary glass-based substrate (Coating 1), an exemplary glass-based substrate (Coating 2, (C2), according to Table 3), or an exemplary glass-based substrate (Coating 3, according to Table 4). Comparative Example AA consisted of the glass-based substrate without any coatings thereon. Comparative Examples BB-II comprised silica (SiO₂) layers of various thicknesses disposed on the glass-based substrate. Unless otherwise indicated, the silica layers were formed by reactive sputtering. Comparative Example CC was formed by high-density plasma chemical vapor deposition (HDPCVD). Comparative Example JJ was formed by plasma-enhanced chemical vapor deposition (PECVD). The reactively sputtered silica layers were formed using an Evovac sputter tool (Angstrom Engineering) impinging a p-type silicon target with 525 Watt pulses with a pulse length of 40 microseconds (μs) and repetition rate of 50 kiloHertz (kHz) in vacuum chamber with a pressure of 0.27 Pa (0.002 Torr) maintained by 40 sccm Ar and 10 sccm O2, which achieved a deposition rate of 2.5 A/s at 23° C. The HDPCVD deposited silica layers were deposited in a Versaline HDPCVD (Plasma-Therm) at 150° C. with feeds of 28 sccm SiH₄, 56 sccm O₂, and 25 sccm Ar with the vacuum chamber at 0.67 Pa (0.005 Torr) and a 600 W inductively coupled plasma (ICP) with a 10 Watt bias, which achieved a deposition rate of about 23 nm/s. Table 9 presents the thickness of the silica layer in Comparative Examples AA-II.

TABLE 3
Coating 1 (C1)

| Layer # | Material | Thickness | |
|---|---|---|---|
| 13 | SiO₂ | 90.5 | nm |
| 12 | SiOₓN_{y} | 150.2 | nm |
| 11 | SiO₂ | 16.6 | nm |
| 10 | SiOₓN_{y} | 46.3 | nm |
| 9 | SiO₂ | 9 | nm |
| 8 | SiOₓN_{y} | 2000 | nm |
| 7 | SiO₂ | 8.71 | nm |
| 6 | SiOₓN_{y} | 44.88 | nm |
| 5 | SiO₂ | 30.12 | nm |
| 4 | SiOₓN_{y} | 26.14 | nm |
| 3 | SiO₂ | 53.7 | nm |
| 2 | SiOₓN_{y} | 9.62 | nm |
| 1 | SiO₂ | 25 | nm |

| | |
|---|---|
| Substrate | Gorilla Glass (GG3) |
| | 13 layers, 2.5 μm, ≥17.5 H |

TABLE 4
Composition of Gorilla Glass III ® (commercially available from
Corning, Inc.).

| Composition | (mol %) |
|---|---|
| SiO₂ | 67.23 |
| B₂O₃ | 3.63 |
| K₂O | 0.01 |
| Al₂O₅ | 12.72 |
| Na₂O | 13.91 |
| CaO | 0.05 |
| ZrO₂ | 0.01 |
| SnO₂ | 0.09 |
| Fe₂O₃ | 0.01 |
| MgO | 2.34 |

TABLE 5
Coating 2 (C2)

| Layer # | Material | Thickness (nm) |
|---|---|---|
| 7 | SiO₂ | 104 |
| 6 | Nb₂O₅ | 31.8 |
| 5 | SiO₂ | 29.7 |
| 4 | Nb₂O₅ | 35.1 |
| 3 | SiO₂ | 48.9 |
| 2 | Nb₂O₅ | 12.1 |
| 1 | SiO₂ | 25 |

SUBSTRATE

TABLE 6
Coating 3 (C3)

| Layer # | Material | Thickness (nm) |
|---|---|---|
| 7 | SiO₂ | 95.2 |
| 6 | ZrO₂ + Al₂O₃ Nanolaminate | 55.5 |
| 5 | SiO₂ | 10.3 |
| 4 | ZrO₂ + Al₂O₃ Nanolaminate | 52.4 |
| 3 | SiO₂ | 42.2 |
| 2 | ZrO₂ + Al₂O₃ Nanolaminate | 14.1 |
| 1 | SiO₂ | 25 |

SUBSTRATE

TABLE 7
Composition of Comparative Examples AA-II

| Comparative Example | SiO₂ Thickness (nm) |
|---|---|
| AA | n/a |
| BB | 80-500 |
| CC | 50-800 |
| DD | 54 |
| EE | 253 |
| FF | 2840 |
| GG | 65 |
| HH | 455 |
| II | 1620 |

Examples 1-34, Assemblies F-T, and Assemblies BBB-DDD, FFF-HHH, and JJJ comprised a planarization layer formed by thermally evaporating a functionalized POSS, namely, octa-isobutyl POSS (OBPOSS), and impinging the evaporated functionalized POSS with an ion beam (discussed below) to form the planarization layer by ion-assisted deposition (IAD). Unless otherwise indicated, thermal evaporation of functionalized POSS occurred using a Radak II cell in an Angstrom Engineering Evovac chamber. As used in this section, the ion beam formed from an end-Hall source (KRI 400 from Kaufman & Robinson) operated at a voltage of 60 V and a discharge current of 0.25 amps (A). The chamber pressure was about 6.7×10⁻³ Pa (5×10⁻⁵ Torr) of oxygen (O₂) gas (maintained with a flow of 6.6 sccm O₂). As used in this section, the “deposition rate” is measured by QCM positioned 500 nm above the Radak II cell and 150 nm below the surface.

Table 6 presents the composition and properties Examples 1-5. Examples 1-5 comprised 200 nm of the planarization layer formed at the deposition rate (as measured by QCM) stated in Table 2. FIGS. 12-13 also present the properties of Examples 1-5. In FIGS. 12-13, the horizontal axis 1201 and 1301 (i.e., x-axis) is deposition rate in Angstroms per second (A/s). In FIG. 12, the left-side vertical axis 1203 (i.e., y-axis on the left side) corresponds to the refractive index measured at an optical wavelength of 550 nm (as described above) and points 1205 (squares) represent the refractive index of Examples 1-5. As shown in FIG. 12 and Table 8, Examples 1-5 exhibit a refractive index from 1.46 to about 1.49 (e.g., from 1.47 to about 1.49). Examples 1˜4 exhibit a refractive index from 1.47 to 1.48. In FIG. 12, the right-side vertical axis 1213 (i.e., y-axis on the right side) corresponds to the extinction coefficient measured at an optical wavelength of 400 nm and points 1215 (circles) represent the extinction coefficient of Examples 1-5. The extinction coefficient is related to the absorptivity and transmittance of the material. As shown in FIG. 12 and Table 8, Examples 1-5 exhibit an extinction coefficient of about 0.01 or less. Examples 1-4 exhibit an extinction coefficient less than 0.01 and less than 0.001. Experimentally, it was observed that Example 5 had a gray appearance whereas Examples 1-4 were transparent. As discussed herein, it is believed that a deposition rate of 2.0 A/s (0.2 nm/s) or more under the experimental conditions of Example 5 does not adequately remove the alkyl functionalization (i.e., isobutyl groups) from the POSS and/or sufficiently condense the functionalized POSS into a silica or partial silica-like network.

TABLE 8
Composition of Examples 1-5

| | Deposition | Refractive | Extinction | Elastic | |
|---|---|---|---|---|---|
| | Rate (A/s) | Index (n) | Coefficient | Modulus | Hardness |
| Example | by QCM | at 550 nm | (k) at 400 nm | (GPa) | (GPa) |
| 1 | 0.5 | 1.478 | <0.001 | 65 | 7.0 |
| 2 | 0.7 | 1.472 | <0.001 | 55 | 5.2 |
| 3 | 0.9 | 1.466 | <0.001 | 50 | 4.8 |
| 4 | 1.3 | 1.474 | <0.001 | 40 | 3.5 |
| 5 | 2.0 | 1.496 | 0.01 | 32 | 2.5 |

In FIG. 13, the left-side vertical axis 1303 (i.e., y-axis on the left side) corresponds to the elastic modulus in GigaPascals (measured by nanoindentation with a Berkovich diamond indenter tip as described above) and points 1305 (squares) represents the elastic modulus of Examples 1-5. As shown in FIG. 13 and Table 8, the elastic modulus decreases as the deposition rate increases. Examples 1-5 comprise an elastic modulus from 30 GPa to 70 GPa. Examples 1-4 comprise an elastic modulus from 35 GPa to 70 GPa (e.g., from 40 GPa to 65 GPa). In FIG. 13, the right-side vertical axis 1313 (i.e., y-axis) corresponds to hardness in GigaPascals (measured by the Berkovich Indenter Hardness test described above) and points 1315 (circles) represents the hardness of Examples 1-5. As shown in FIG. 13 and Table 8, the hardness decreases as the deposition rate increases. Examples 1-5 comprise a hardness from 2.5 GPa to 8 GPa. Examples 1-4 comprise a hardness from 3 GPa to 8 GPa (e.g., from 3.5 GPa to 7.0 GPa). Without wishing to be bound by theory, the elastic modulus and hardness are believed to be associated with the porosity of the planarization layer (with lower porosity associated with decreased elastic modulus and decreased hardness), suggesting that the higher deposition rates are associated with more porous planarization layers.

FIGS. 14-16 present infrared (IR) spectroscopy of Examples 6-10. IR spectroscopy was measured using a Nicolet iS50 FTIR Spectrometer (Thermo Scientific) with a DTGS (deuterated triglycine sulfate) detector element, where the absorbance was measured with 4 wavenumber (cm⁻¹) resolution and averaged from 256 individual scans. In FIGS. 14-16, the horizontal axis 1401, 1501, and 1601 (i.e., x-axis) corresponds to wavenumber (cm⁻¹) and the vertical axis 1403, 1503, and 1603 (i.e., y-axis) corresponds to a normalized absorbance. Curves 1405, 1505, and 1605 correspond to the absorbance of Example 6 and a deposition rate of 0.5 A/s; curves 1407, 1507, and 1607 correspond to the absorbance of Example 7 and a deposition rate of 0.7 A/s; curves 1409, 1509, and 1609 correspond to the absorbance of Example 8 and a deposition rate of 0.9 A/s; curves 1411, 1511, and 1611 correspond to the absorbance of Example 9 and a deposition rate of 1.3 A/s; and curves 1413, 1513, and 1613 correspond to the absorbance of Example 10 and a deposition rate of 2.0 A/s.

FIG. 14 presents the entire wavenumber range measured from 400 cm⁻¹ to 4000 cm⁻¹ while FIG. 15 presents the subset of the spectra from 800 cm⁻¹ to 1400 cm⁻¹ and FIG. 16 presents the subset of the spectra from 2800 cm⁻¹ to 4000 cm⁻¹. In FIG. 15, a broad absorbance is seen at 1059 cm⁻¹, which is attributed to an Si—O—Si structure. Modeling (based on the model of Devine, J. Non. Cryst. Sol. 152 (1993): 50-58) suggests that the peak corresponds to a bond angle of 136° for Si—O—Si with a fictive temperature of about 5300K. This corresponds to a highly strained non-equilibrium structure in the planarization layers of Examples 6-10. The fictive temperature calculated here is higher than what is typically seen for sputtered silica films. Also, curves 1505, 1507, 1509, 1511, and 1513 differ in the absorbance from about 800 cm⁻¹ to about 980 cm⁻¹, which is attributed to C—H stretches from the organic functional group on the functionalized POSS. As the deposition rate increased from Example 7 to Example 10 (from curve 1507 to curve 1513), the amount of residual organic material appears to increase.

In FIG. 16, an OH stretch associated with free water is seen around 3550 cm-1 for curves. The free water absorption increases with increased deposition rate (e.g., from curve 1605 to curve 1613). Although not shown, it was observed that the free water absorption largely disappeared for Example 10 (2.0 A/s) after vacuum annealing for 1 hour at 200° C., which also decreased the refractive index to below 1.48 and increased the elastic modulus to above 40 GPa.

In FIG. 16, a broad hydroxyl (OH) stretch associated with alcohols (e.g., silanols-Si—O—H) is seen from about 3200 cm⁻¹ to about 3500 cm⁻¹. The hydroxyl absorption also increases with increased deposition rate (e.g., from curve 1605 to curve 1613). FIG. 17 presents a relationship between deposition rate and a “hydroxyl ratio”, which is a peak absorbance of the broad hydroxyl signal (centered around 3420 cm⁻¹) divided by a peak absorbance of the Si—O—Si signal (centered at about 1060 cm⁻¹). As shown in FIG. 14, the peak of the Si—O—Si absorbance is much stronger than the hydroxyl absorbance. In FIG. 17, the horizonal axis 1701 correspond to the deposition rate (as measured by QCM) in A/s, and the vertical axis 1703 (i.e., y-axis) is the value of the “hydroxyl ratio” defined above. Points 1705 (circles) correspond to the hydroxyl ratio for Examples 6-10. As shown, the hydroxyl ratio increases as deposition rate increases (going from Example 6 to Example 10). Examples 6-10 have a hydroxyl ratio of from 0.005 to 0.07. Examples 6-9 have a hydroxyl ratio from 0.005 to 0.06 (e.g., from 0.008 to 0.05 or from 0.01 to 0.045). Although not shown, a hydroxyl ratio for a reactively sputtered silica layer is much lower than the hydroxyl ratios shown in FIG. 17. For example, the hydroxyl ratio of the planarization layer (e.g., Examples 6-10) is greater than the hydroxyl ratio of a reactively sputtered silica layer by a multiple of from 2 to 20 (e.g., from 3 to 10 or from 3 to 5).

FIG. 18 presents a relationship between layer thickness in nm on the horizontal axis 1801 (i.e., x-axis) and surface roughness Ra in nm on the vertical axis 1803 (i.e., y-axis) for Example 11 and Comparative Examples BB-CC. Comparative Example BB comprised a silica layer deposited by HDPCVD (described above) and points 1809 (squares) correspond to the surface roughness Ra observed for Comparative Example BB. Comparative Example CC comprised a reactive sputtered silica layer (described above) and points 1807 (triangles) correspond to the surface roughness Ra observed for Comparative Example CC. Example 11 used a deposition rate of 0.9 A/s (as measured by QCM) to form planarization layers of different thickness with the surface roughness Ra indicated by points 1805 (circles)

As noted above, the surface roughness Ra of the glass-based substrate was about 0.2 nm (as is the case for Comparative Examples BB-CC and Example 11), which is indicated by dashed line 1811. As shown, points 1807 (Comparative Example CC, triangles) increase the surface roughness Ra by more than 2 times (e.g., about 0.5 nm or more) relative to dashed line 1811. Similarly, points 1809 (Comparative Example BB, squares) increases the surface roughness Ra by more than 3 times (e.g., greater than 0.6 nm) relative to dashed line 1811. In contrast, points 1805 (Example 11, circles) do not significantly deviate from dashed line 1811 with a surface roughness less than 0.3 nm (e.g., about 0.25 nm or less), which is observed for all of the thicknesses tested (from about 15 nm to about 200 nm for Example 11). As such, the planarization layers in accordance with aspects of the present disclosure (including Example 11) provide unexpected low surface roughness Ra.

FIG. 20 presents a relationship between the surface roughness Ra of the underlying surface (e.g., substrate) in nm as indicated by horizontal axis 2001 (i.e., x-axis) and the surface roughness of the deposited layer (e.g., planarization layer) as indicated by the vertical axis 2003 (i.e., y-axis) for Comparative Example BB (reactively sputtered silica) and Examples 12-16. For Examples 12-16, the different underlying surface roughness Ra values were obtained by reactively sputtering silica on the glass-based substrate with the roughness of the reactively sputtered silica on the horizontal axis 2001 (i.e., x-axis) and the surface roughness after any additional material was deposited thereon indicated by the vertical axis 2003 (i.e., y-axis). Consequently, curve 2005 (corresponding to Comparative Example BB) is a straight line since no additional layer was deposited thereon, meaning that the surface roughness Ra values are the same (for the horizontal and vertical axes).

The conditions for the planarization layers deposited in Examples 12-22 are presented in Table 9. Curves 2007, 2009, 2011, 2013, and 2015 correspond to Examples 12-16, respectively. As shown, curves 2007, 2009, 2011, 2013, and 2015 (Examples 12-16) are all below curve 2005, indicating that the planarization layer of Examples 12-16 decreases surface roughness Ra relative to the layer that it is deposited on. As discussed above with reference to FIG. 18, this reduction in surface roughness Ra from deposition of another layer (e.g., planarization layer in accordance with aspects of the present disclosure) is unexpected. Further, the thicker layers (86 nm for Example 15—see curve 2013—and 82 nm for Example 16—see curve 2015) are associated with greater reductions in surface roughness Ra relative to thinner layers (19 nm for Example 13—see curve 2009). The deposition rate (between 0.5 A/s for Example 12 and 0.9 A/s for Examples 14-15) appears to have little to no effect on the roughness reduction since curve 2007 is between curves 2011 and 2013, which is in-line with the thickness trend discussed above (34 nm for Example 12 is between 33 nm for Example 14 and 86 nm for Example 15). For the data shown in FIG. 20, the largest surface roughness reduction was observed when the initial surface roughness was from about 1.0 nm to about 1.5 nm.

TABLE 9
Deposition Conditions for Examples 12-22

| | Deposition | Deposited |
|---|---|---|
| | Rate (A/s) | Thickness |
| Example | by QCM | (nm) |
| 12 | 0.5 | 43 |
| 13 | 0.9 | 19 |
| 14 | 0.9 | 33 |
| 15 | 0.9 | 86 |
| 16 | 2.0 | 82 |
| 17, 20 | 0.9 | 22 |
| 18, 21 | 0.9 | 38 |
| 19, 22 | 0.9 | 76 |

FIG. 21 presents a relationship between the surface roughness Ra of the underlying surface (e.g., substrate) in nm as indicated by horizontal axis 2101 (i.e., x-axis) and the surface roughness of the deposited layer (e.g., planarization layer) as indicated by the vertical axis 2103 (i.e., y-axis) for Examples 17-19 Comparative Example BB. Just like Examples 13-15, Examples 17 were formed at a deposition rate of 0.9 A/s, but to slightly different thicknesses than Examples 13-15. As discussed above for curve 2005, curve 2105 is a since no additional layer was deposited thereon, meaning that the surface roughness Ra values are the same (for the horizontal and vertical axes) because the initial surface was formed by depositing the material of Example BB on the glass-based substrate. Curves 2107, 2109, and 2111 correspond to Examples 17-19, respectively. As shown, curves 2107, 2109, and 2111 all lie below curve 2105, indicating that the planarization layer of Examples 17-19 reduce surface roughness Ra relative to the surface roughness Ra of the underlying surface.

FIG. 19 presents the results of 3,000 abrasion cycles in the Steel Wool Abrasion Test for Examples 20-22 and Comparative Example CC (reactively sputtered silica on the glass-based substrate). Examples 20-22 were prepared identically to Examples 17-19 with the addition that the surface was subsequently cleaned with an O₂ ion beam from the end-Hall ion beam for 10 minutes before spray coating an easy-to-clean material (i.e., Daiken UD-509 ETC) thereon. In FIG. 19, the horizontal axis 1901 (i.e., x-axis) corresponds to the surface roughness Ra at the beginning of the Steel Wool Abrasion Test, which is the same as the vertical axis 2003 (i.e., y-axis) in FIG. 21 (discussed above). The vertical axis 1903 (i.e., y-axis) is the water contact angle in degrees measured after the abrasion (other than the top left cluster of points, which correspond to the as-formed water contact angle before abrasion of deposited easy-to-clean coating). Points 1907 (squares) correspond to the abraded water contact angle of Comparative Example BB with dashed line 1905 showing the trend for points 1907 (squares). As shown, the abraded water contact angle drops to about 90° or less when the surface roughness Ra is 0.5 nm or more, and the abraded water contact angle continues to drop as surface roughness Ra increases (e.g., less than 80° for a surface roughness Ra of greater than 1.5 nm). Points 1911 (diamonds), 1913 (circles), and 1915 (triangles) correspond to Examples 20-22, respectively. Examples 20-22 (points 1911, 1913, and 1915) exhibit an abraded water contact angle greater than 90° (e.g., about 95° or more, about 98° or more, or about 100° or more) for all surface roughness Ra conditions tested. This demonstrates that the planarization layer of Examples 20-22 improves the adhesion and/or abrasion resistance of surface-modifying layers (e.g., easy-to-clean coatings) disposed thereon, for example, by maintaining a high water contact angle after abrasion.

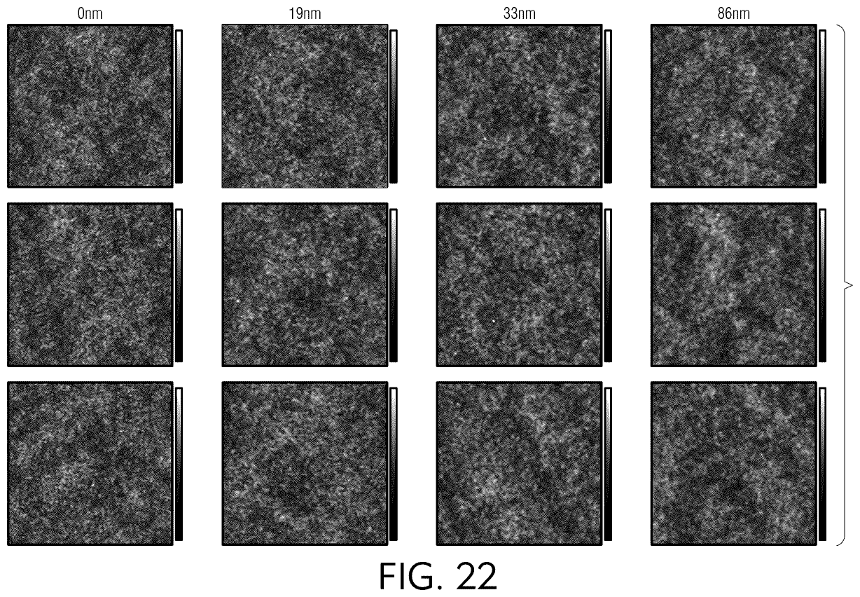

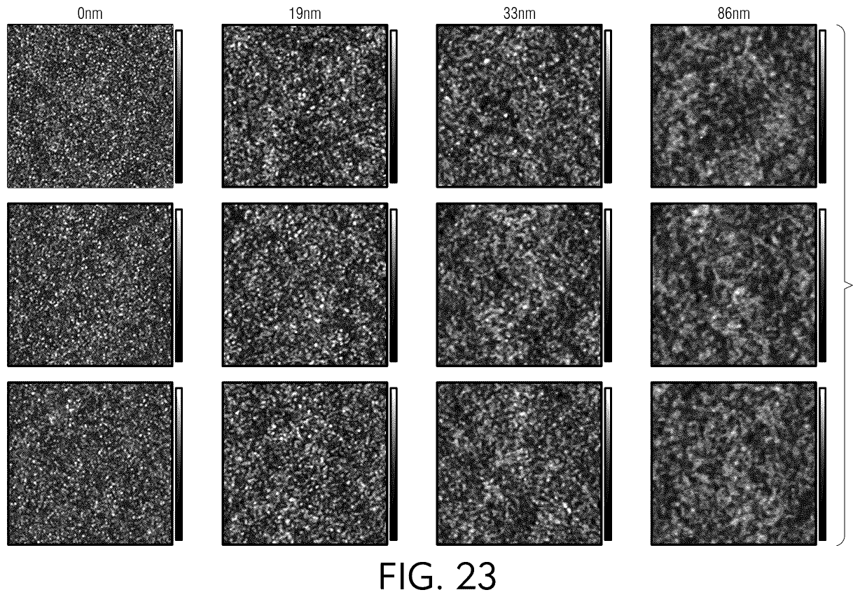

FIGS. 22-25 and 31 schematically show AFM images of 2 μm by 2 μm areas of Examples 17-19 and 23-31 and Comparative Examples AA and DD-FF with the composition of Examples 17-19 and 23-31 and Comparative Examples AA and DD-FF indicated in Table 10 by the combinations of reactively sputtered silica coating (thickness in nm indicated by the top row) and (any) planarization layer formed thereon (thickness in nm indicated by the first-left-most-column) with a deposition rate of 0.9 A/s. For example, Example 23 was formed by reactively sputtering 54 nm of silica on the glass-based substrate followed by forming a 19 nm planarization layer (by IAD), as indicated by the intersection of the 54 nm silica column (top row label) and the 19 nm planarization layer row (1st column) at the cell labeled Example 23.

TABLE 10
Composition of Examples 17-19 and 23-31 and
Comparative Examples AA and DD-FF

| silica (row)/ | none | | | |
|---|---|---|---|---|
| planarization (column) | (0 nm) | 54 nm | 253 nm | 2840 nm |
| none (0 nm) | AA | DD | EE | FF |
| 19 nm | 17 | 23 | 26 | 29 |
| 33 nm | 18 | 24 | 27 | 30 |
| 86 nm | 19 | 25 | 28 | 31 |

In each of FIGS. 22-25 three (3) AFM images are shown for each Example taken from different locations on the same sample with each set of images for the sample presented as a column. In FIG. 22, going from left to right, the columns correspond to Comparative Example AA and Examples 17-19, respectively. Consequently, the planarization layer in Examples 17-19 was deposited directly on the glass-based substrate. Consistent with the results discussed in FIG. 18 (see points 1805 (circles) and dashed line 1811), the texture and/or surface roughness of Examples 17-19 appears to be substantially the same as Comparative Example AA. This demonstrates that the planarization layer (e.g., Examples 17-19) does not increase surface roughness when deposited on a low roughness surface.

In FIG. 23, going from left to right, the columns correspond to Comparative Example DD and Examples 23-25, respectively. Consequently, Examples 23-25 were deposited on the 54 nm silica layer of Comparative Example DD. As the thickness of the planarization layer increases (going from left to right in FIG. 23), the resolution of the features appears to coarsen, which is a result of high spatial frequency roughness being removed by the planarization layer that, in turn, reduces the surface roughness (and/or high frequency texture) of the resulting surface. This suggests that the planarization layers (e.g., Examples 23-25) reduce surface roughness and/or texture by eliminating high spatial frequency roughness (discussed further below with reference to FIG. 27).

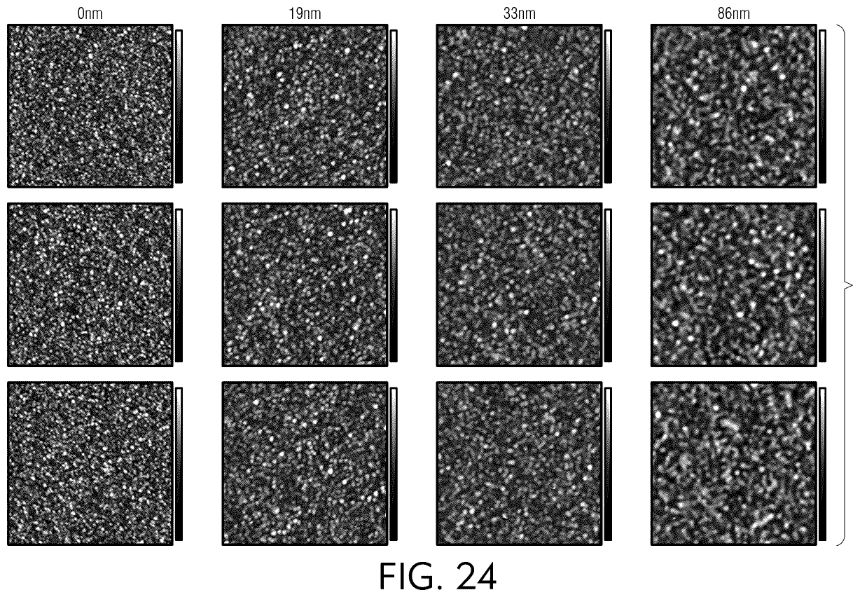

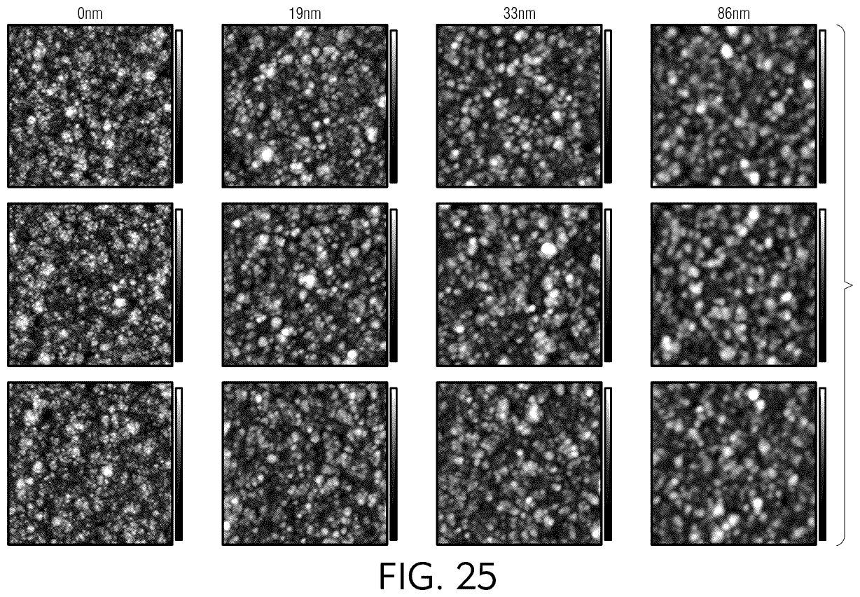

In FIG. 24, going from left to right, the columns correspond to Comparative Example EE and Examples 26-28, respectively. Consequently, Examples 26-28 were deposited on the 253 nm silica layer of Comparative Example EE. While Comparative Example EE has more surface roughness and/or texture than Comparative Example DD, the effect of the planarization layer in Examples 26-28 appears to be largely the same as Examples 23-25, namely, a coarsening of the resolution of features associated with the planarization layer removing high spatial frequency roughness.

In FIG. 25, going from left to right, the columns correspond to Comparative Example FF and Examples 29-31, respectively. Consequently, Examples 29-31 were deposited on the 2840 nm silica layer of Comparative Example FF. While Comparative Example FF has more surface roughness and/or texture than Comparative Example DD or EE, the effect of the planarization layer in Examples 29-31 appears to be largely the same as Examples 23-28, namely, a coarsening of the resolution of features associated with the planarization layer removing high spatial frequency roughness. Notably, a relatively thin planarization layer (e.g., from about 10 nm to about 600 nm or from about 15 nm to about 100 nm, or from about 20 nm to about 90 nm) is able to reduce high spatial frequency roughness relative to underlying reactively sputtered silica layers (Comparative Examples DD-FF) with thicknesses over several orders of magnitude (e.g., from about 50 nm to about 250 nm to about 2840 nm).

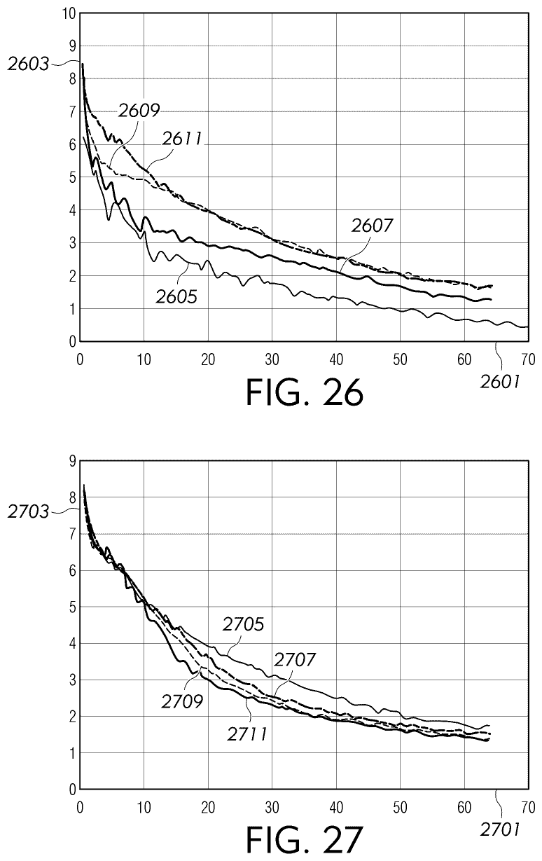

FIGS. 26-27 present power spectral density (PSD) of Examples 32-34 and Comparative Examples AA and GG-II. As discussed above, the PSD refers to the two-dimensional (2D) isotropic power spectral density (PSD) determined from height data measured using atomic force microscopy (AFM) for a 2 μm by 2 μm test area of the surface. Comparative Examples GG-II comprised reactively sputtered silica layers with thicknesses of 65 nm, 455 nm, and 1620 nm, respectively. Examples 32-34 comprised the 1620 nm reactively sputtered silica layer (of Comparative Example II) with planarization layers of 22 nm, 38 nm, or 76 nm, respectively, deposited thereon by IAD with a deposition rate of 0.9 A/s.

In FIGS. 26-27, the horizontal axis 2601 and 2701 (i.e., x-axis) corresponds to spatial frequencies in μm⁻¹, and the vertical axis 2603 and 2703 (i.e., y-axis) is a logarithm (base 10) of the power spectral density (in nm⁴). FIG. 26 shows curves 2605, 2607, 2609, and 2611 that correspond to Comparative Examples AA, GG, HH, and II, respectively. As shown, the entirety of curves 2607, 2609, and 2611 (Comparative Examples GG-II) are greater (i.e., higher amplitude) than curve 2605 (Comparative Example AA), which indicates that reactively sputtered silica layers increase surface roughness at all spatial frequencies measured. Similarly, increasing the thickness of the reactively sputtered silica layer from Comparative Example GG (curve 2607, 65 nm) to Comparative Examples HH-II (curves 2609 and 2611, 455 nm and 1620 nm) also increases the amplitude at essentially all spatial frequencies measured. Further increasing the thickness of the reactively sputtered layer from Comparative Example HH (curve 2609, 455 nm) to Comparative Example II (curve 2611, 1620 nm) primarily increases the amplitude of lower spatial frequencies (e.g., from 1 μm⁻¹ to about 13 μm⁻¹).

FIG. 27 shows curves 2705, 2707, 2709, and 2711 that correspond to Comparative Example II, Example 32, Example 33, and Example 34, respectively. Curve 2611 (FIG. 26) and curve 2705 are the same (Comparative Example II) for comparison. The low spatial frequencies (e.g., 10 μm⁻¹ or less) of Examples 32-34 (curves 2707, 2709, and 2711) is substantially the same as for Comparative Example II (curve 2705). However, the amplitude at higher spatial frequencies of Examples 32-34 (curves 2707, 2709, and 2711) is lower than for Comparative Example II (curve 2705), which is most pronounced from 20 μm⁻¹ to 40 μm-1. For example, the amplitude of the PSD at a spatial frequency of 30 μm⁻¹ decreases from about 1000 nm⁴ (3 log units) of Comparative Example II (curve 2705) to less than 500 nm⁴ (less than 2.7 log units) (e.g., 400 nm⁴ or less (2.6 log units), 300 nm⁴ or less (2.5 log units or less), or 200 nm⁴ or less (2.3 log units)) for Examples 32-34 (curves 2707, 2709, and 2711). Another way to characterize the reduction in amplitude at higher spatial frequencies (relative to lower spatial frequencies) is to look at a ratio of the amplitude at a first spatial frequency of 30 μm⁻¹ to a second amplitude at a second spatial frequency of 10 μm⁻¹. As shown, the amplitude of the PSD for Comparative Example II and Examples 32-34 is about 100,000 (5.0 log units). Consequently, a ratio of the amplitude at a first spatial frequency of 30 μm⁻¹ to a second amplitude at a second spatial frequency of 10 μm⁻¹ (i.e., PSD (30 μm⁻¹)/PSD (10 μm⁻¹)) for Comparative Example II is about 0.01. In contrast, the corresponding ratio PSD (30 μm-1)/PSD (10 μm⁻¹) for Examples 32-34 is less than 0.1 (e.g., about 0.05 or less, about 0.03 or less, about 0.01 or less, about 0.008 or less, about 0.005 or less, or about 0.004 or less). Viewed as a ratio of the log units of the amplitudes (i.e., log [PSD (30 μm⁻¹)]/log [PSD (10 μm⁻¹)]), Comparative Example II has a ratio of 0.6 while Examples 32-34 have a ratio less than 0.6 (e.g., about 0.55 or less, about 0.50 or less, or about 0.45 or less).

FIGS. 37-38 present power spectral density (PSD) of Assemblies AAA, BBB, and DDD-HHH. In FIGS. 37-38, the horizontal axis 3701 (i.e., x-axis) corresponds to spatial frequencies in μm⁻¹, and the vertical axis 3703 (i.e., y-axis) is a logarithm (base 10) of the power spectral density (in nm⁴). As discussed below, Assemblies AAA, BBB, and DDD comprise the optical stack with the composition shown in Table 12. Assembly AAA did not comprise a planarization layer. However, Assemblies BBB and DDD comprised 23 nm and 58 nm, respectively, thick planarization layers disposed on the optical stack. For determining the PSD, Assemblies AAA, BBB, and DDD did not include the easy-to-clean coating (i.e., the optical stack or planarization layer was the exterior surface analyzed by AFM). In FIG. 37, curve 3705 corresponds to Assembly AAA, curve 3707 corresponds to Assembly BBB, and curve 3709 corresponds to Assembly DDD. As shown, the low spatial frequencies (e.g., 10 μm⁻¹ or less) of Assemblies AAA and BBB (curves 3705 and 3707, and 3709) is substantially the same. However, the amplitude at higher spatial frequencies of Assemblies BBB and DDD (curves 3707 and 3709) is lower than for Assembly AAA (curve 3705), which is most pronounced from 20 μm⁻¹ to 40 μm⁻¹. For example, a ratio of the amplitude at a first spatial frequency of 30 μm⁻¹ to a second amplitude at a second spatial frequency of 10 μm⁻¹ (i.e., PSD (30 μm⁻¹)/PSD (10 μm⁻¹)) for Assembly AAA is about 0.1, but it is about 0.03 or less for Assemblies BBB and DDD. Viewed as a ratio of the log units of the amplitudes (i.e., log [PSD (30 μm⁻¹)]/log [PSD (10 μm⁻¹)]), Assembly AAA has a ratio of about 0.75 while Assemblies BBB and DDD have a ratio less than 0.6 (e.g., about 0.55 or less, about 0.50 or less). Notably Assembly DDD has a lower amplitude PSD than Assembly AAA at all spatial frequencies shown in FIG. 37.

As discussed below, Assemblies EEE-HHH comprise the optical stack with the composition shown in Table 13. Assembly EEE did not include a planarization layer. However, Assemblies FFF-HHH comprised 23 nm, 41 nm, and 58 nm, respectively, thick the planarization layers disposed on the optical stack. For determining the PSD, Assemblies EEE-HHH did not include the easy-to-clean coating (i.e., the optical stack or planarization layer was the exterior surface analyzed by AFM). In FIG. 38, curve 3805 corresponds to Assembly EEE, curve 3807 corresponds to Assembly FFF, curve 3809 corresponds to Assembly GGG, and curve 3811 corresponds to Assembly HHH. As shown, the low spatial frequencies (e.g., 10 μm⁻¹ or less) of Assemblies EEE-HHH (curves 3805, 3807, 3809, and 3811) is substantially the same. However, the amplitude at higher spatial frequencies of Assemblies FFF-HHH (curves 3807, 3809, and 3811) is lower than for Assembly EEE (curve 3805), which is most pronounced from 20 μm⁻¹ to 40 μm⁻¹. For example, a ratio of the amplitude at a first spatial frequency of 30 μm⁻¹ to a second amplitude at a second spatial frequency of 10 μm⁻¹ (i.e., PSD (30 μm⁻¹)/PSD (10 μm⁻¹)) for Assembly EEE is about 0.01, but it is about 0.003 or less for Assemblies FFF-HHH. Viewed as a ratio of the log units of the amplitudes (i.e., log [PSD (30 μm⁻¹)]/log [PSD (10 μm⁻¹)]), Assembly EEE has a ratio of about 0.6 while Assemblies FFF-HHH have a ratio less than 0.6 (e.g., about 0.55 or less, about 0.50 or less).

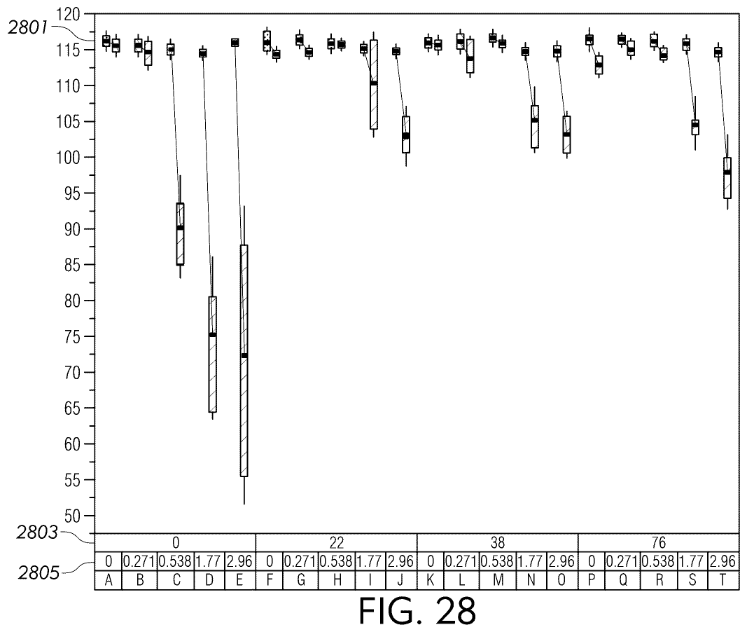

FIGS. 28-30 presents water contact angles before and after 3,000 abrasion cycles in the Steel Wool Abrasion Test for Assemblies A-T and AAA-HHH. The composition of Assemblies A-T (excluding the easy-to-clean coating) is indicated in Table 11 by the combinations of reactively sputtered silica coating (thickness in nm indicated by the top row) and (any) planarization layer formed thereon (thickness in nm indicated by the first-left-most column) with a deposition rate of 0.9 A/s. For example, Assembly G was formed by reactively sputtering 271 nm of silica on the glass-based substrate followed by forming a 22 nm planarization layer (by IAD), as indicated by the intersection of the 271 nm silica column (top row label) and the 22 nm planarization layer row (1^{st} column) at the cell labeled Assembly G. In FIG. 28, the label in row 2805 refers to the thickness of the reactively sputtered silica in micrometers (although reported in nanometers in Table 11), and the label in row 2803 refers to the thickness of the planarization layer formed thereon with a deposition rate of 0.9 A/s (planarization thickness reported in nanometers in FIG. 28 and Table 11). The vertical axis 2801 (i.e., y-axis) corresponds to the water contact angle in degrees. The easy-to-clean coating was formed on Assemblies A-T (after depositing any reactively sputtered silica and then any planarization layer) by cleaning with an O₂ ion beam from the end-Hall ion beam for 10 minutes before spray coating an easy-to-clean material (i.e., Daiken UD-509 ETC) thereon.

TABLE 11
Composition of Assemblies A-T below ETC

| silica (row)/ | none | | | | |
|---|---|---|---|---|---|
| planarization (column) | (0 nm) | 271 nm | 538 nm | 1770 nm | 2960 nm |
| none (0 nm) | A | B | C | D | E |
| 22 nm | F | G | H | I | J |
| 38 nm | K | L | M | N | O |
| 76 nm | P | Q | R | S | T |

As shown in FIG. 28, Assemblies A-E without a planarization layer, the abraded water contact angle decreases to less than 100° (e.g., less 95° or about 90° or less) when the silica layer is greater than about 500 nm with Examples D-E having even lower abrasion water contact angles (e.g., less than 85° or less than) 80°. Assemblies F, K, and P with the planarization layer deposited directly on the glass-based substrate had abraded water contact angles greater than 100° (e.g., greater than 105°, greater than 110°, or about) 115°. Likewise, Assemblies G, L, and Q with a silica layer of 271 nm between the glass-based substrate and the planarization layer also had abraded water contact angles greater than 100° (e.g., greater than 105°, greater than 110°, or about) 115°. For the assemblies with a 538 nm silica layer, Assemblies H, M, and R still achieves an abraded water contact angle substantially the same as the initial (as-formed) water contact angle while Assembly C had an abraded water contact about 25° less than the initial water contact angle. For the assemblies with a 1770 nm silica layer, Assemblies I, N, and S have abraded water contact angles greater than 100° (e.g., about 105° or more) while Assembly D had a water contact angle less than 90° (e.g., less than 85° or less than) 80°. For the assemblies with a 2960 nm silica layer, Assemblies J, O, and T had abraded water contact angle greater than 90° (e.g., greater than 95° or about 98° or more) with Assemblies J and O have water contact angles of 100° or more (e.g., about 102° or more) while Assembly E had a water contact angle less than 80°. Consequently, the planarization layer (e.g., from 10 nm to 600 nm, from 15 nm to 200 nm, or from 20 nm to 100 nm) is able to achieve high abraded water contact angles (e.g., about 90° or more, about 95° or more, about 98° or more, or about 100° or more).

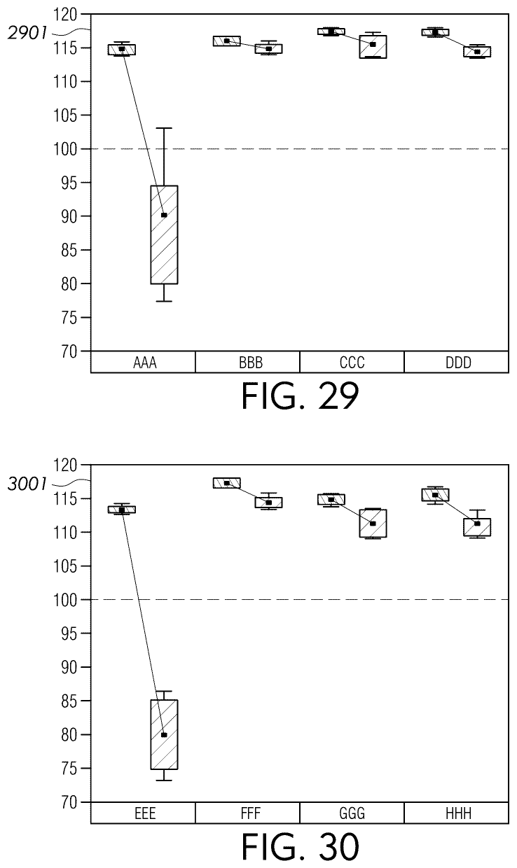

Instead of a reactively sputtered silica layer between the glass-based substrate and (any) planarization layer (in Assemblies A-T), Assemblies AAA-DDD comprises an optical stack with the composition shown in Table 12 (corresponding to the order that the layers are deposited-meaning that the first row is the closest to the glass-based substrate and the last row is the furthest from the glass-based substrate). In Tables 6-9, the substrate (i.e., glass-based substrate) and air are shown to help orient the optical stack, but the substrate and air are not actually elements of the optical stack. As used in Tables 12-13, “SiNₓ” refers to silicon nitride, which can have a non-stoichiometric (i.e., other than Si₃N₄) ratio of the constituent atoms. FIG. 29 presents the water contact angles before and after 3,000 abrasion cycles in the Steel Wool Abrasion Test for Assemblies AAA-DDD with Assemblies AAA-DDD having the following thicknesses for the planarization layers: 0 nm (none), 23 nm, 41 nm, and 58 nm, respectively. The vertical axis 2901 (i.e., y-axis) corresponds to the water contact angle in degrees. The easy-to-clean coating was formed on Assemblies AAA-HHH (after depositing the optical stack in Table 12 and then any planarization layer) by cleaning with an O₂ ion beam from the end-Hall ion beam for 10 minutes before spray coating an easy-to-clean material (i.e., Daiken UD-509 ETC) thereon.

TABLE 12
Composition of Optical Stack for Assemblies AAA-DDD

| | Refractive | Thickness |
|---|---|---|
| Material | Index | (nm) |
| (substrate) | 1.50 | |
| SiO₂ | 1.48 | 24.70 |
| SiNₓ | 2.06 | 20.88 |
| SiO₂ | 1.48 | 22.00 |
| SiNₓ | 2.06 | 103.44 |
| SiO₂ | 1.48 | 84.80 |
| (air) | 1.00 | |

As shown in FIG. 29, Assembly AAA without a planarization layer has an abraded water contact angle of about 90° or less. In contrast, Assemblies BBB-DDD (with planarization layers from about 20 nm to about 60 nm, namely, 23 nm, 41 nm, and 58 nm, respectively) have abraded water contract angles greater than 95° (e.g., greater than 98°, greater than 100°, or greater than) 105°. Indeed, the difference between the initial (as-formed) water contact angle and the abraded water contact angle for Assemblies BBB-DDD is less than 10° (e.g., about 5° or less) while the corresponding difference for Assemblies AAA is about 20° or more.

Instead of a reactively sputtered silica layer between the glass-based substrate and (any) planarization layer (in Assemblies A-T), Assemblies EEE-HHH comprises an optical stack with the composition shown in Table 13 (corresponding to the order that the layers are deposited-meaning that the first row is the closest to the glass-based substrate and the last row is the furthest from the glass-based substrate). In Table 13, “SiON” refers to silicon oxynitride (i.e., SiOₓN_{y} with non-zero amounts of both silicon and oxygen-x>0, y>O—and x+y is less than or equal to 1). FIG. 30 presents the water contact angles before and after 3,000 abrasion cycles in the Steel Wool Abrasion Test for Assemblies EEE-HHH with Assemblies EEE-HHH having the following thicknesses for the planarization layers: 0 nm (none), 23 nm, 41 nm, and 58 nm, respectively. The vertical axis 3001 (i.e., y-axis) corresponds to the water contact angle in degrees. The vertical axis 2901 (i.e., y-axis) corresponds to the water contact angle in degrees. The easy-to-clean coating was formed on Assemblies AAA-HHH (after depositing the optical stack in Table 12 and then any planarization layer) by cleaning with an O₂ ion beam from the end-Hall ion beam for 10 minutes before spray coating an easy-to-clean material (i.e., Daiken UD-509 ETC) thereon.

TABLE 13
Composition of Optical Stack for Assemblies EEE-HHH

| | Refractive | Thickness |
|---|---|---|
| Material | Index | (nm) |
| (substrate) | 1.50 | |
| SiO₂ | 1.48 | 20.0 |
| SiON | 1.94 | 8.0 |
| SiO₂ | 1.48 | 64.0 |
| SiON | 1.94 | 20.0 |
| SiO₂ | 1.48 | 49.2 |
| SiON | 1.94 | 35.9 |
| SiO₂ | 1.48 | 26.4 |
| SiON | 1.94 | 50.6 |
| SiO₂ | 1.48 | 8.0 |
| SiON | 1.94 | 1500. |
| SiO₂ | 1.48 | 16.0 |
| SiNₓ | 2.01 | 39.4 |
| SiO₂ | 1.48 | 50.4 |
| SiNₓ | 2.01 | 25.2 |
| SiO₂ | 1.48 | 85.6 |
| SiNₓ | 2.01 | 26.0 |
| SiO₂ | 1.48 | 45.1 |
| SiNₓ | 2.01 | 154.4 |
| SiO₂ | 1.48 | 101.5 |
| (air) | 1.00 | |

As shown in FIG. 30, Assembly EEE without a planarization layer has an abraded water contact angle of less than 90° (e.g., 85° or less or about 80° or less). In contrast, Assemblies FFF-HHH (with planarization layers from about 20 nm to about 60 nm) have abraded water contract angles greater than 95° (e.g., greater than 98°, greater than 100°, or greater than) 105°. Indeed, the difference between the initial (as-formed) water contact angle and the abraded water contact angle for Assemblies FFF-HHH is less than 10° (e.g., about 5° or less) while the corresponding difference for Assemblies EEE is greater than 20° (e.g., 25° or more or about 30° or more).

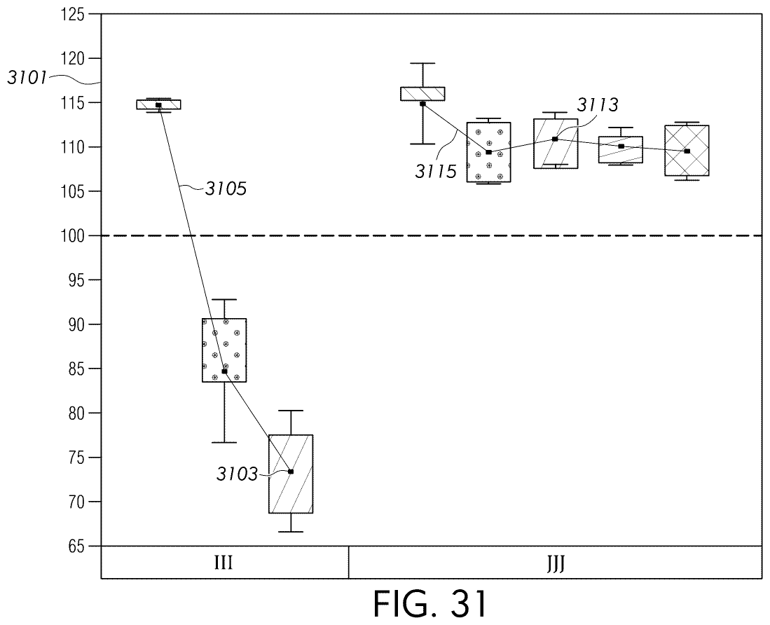

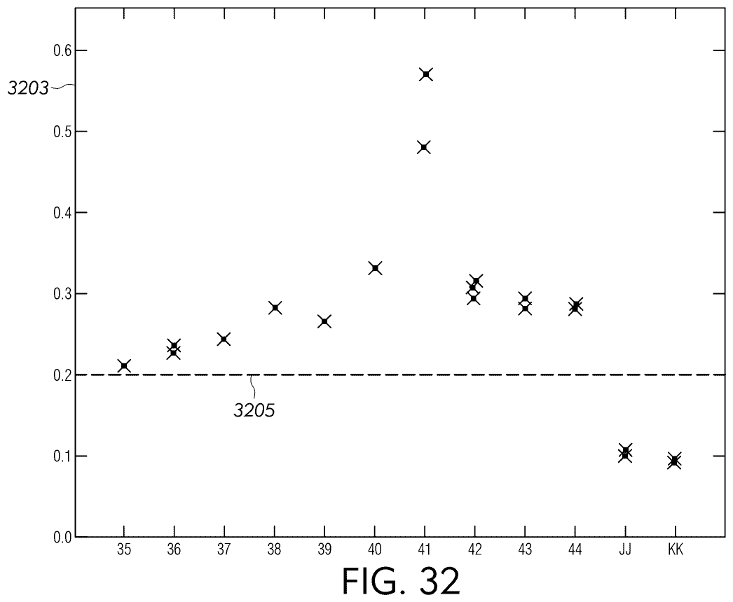

FIG. 31 presents the water contact angles before and after 100,000 to 400,000 abrasion cycles in the Cheesecloth Abrasion Test for Assemblies III-JJJ. Instead of a reactively sputtered silica layer between the glass-based substrate and (any) planarization layer (in Assemblies A-T), Assemblies III and JJJ comprises an optical stack with the composition shown in Table 14 (corresponding to the order that the layers are deposited-meaning that the first row is the closest to the glass-based substrate and the last row is the furthest from the glass-based substrate). Assembly III does not comprise a planarization layer on the optical stack, but Assembly JJJ comprised a planarization layer with a thickness of 33 nm with a deposition rate of 0.9 A/s. The easy-to-clean coating was formed on Assemblies III-JJJ (after depositing the optical stack in Table 15 and then any planarization layer) by cleaning with an O₂ ion beam from the end-Hall ion beam for 10 minutes before spray coating an easy-to-clean material (i.e., Daiken UD-509 ETC) thereon.

TABLE 14
Composition of Optical Stack for Assemblies III-JJJ

| | Refractive | Thickness |
|---|---|---|
| Material | Index | (nm) |
| (substrate) | 1.50 | |
| SiO₂ | 1.48 | 25.0 |
| Nb₂O₅ | 2.36 | 12.4 |
| SiO₂ | 1.48 | 40.4 |
| Nb₂O₅ | 2.36 | 116.0 |
| SiO₂ | 1.48 | 83.8 |
| (air) | 1.00 | |

In FIG. 31, the vertical axis 3101 (i.e., y-axis) corresponds to the water contact angle in degrees. Points 3103 correspond to the water contact angles of Assembly III with line 3105 showing the trend from as-formed (0 cycles), 100,000 cycles, and 200,000 cycles (going from left to right). As shown, the water contact angle decreases to less than 90° (e.g., about) 85° after 100,000 and further decreases to less than 80° after 200,000 cycles. The difference between the initial water contact angle and the abraded water contact angle after 100,000 cycles or 200,000 cycles is greater than 20° (e.g., greater than 25° or about 30° or more). Points 3113 correspond to the water contact angles of Assembly JJJ with line 3115 showing the trend from as-formed (0 cycles) to 400,000 cycles (with points corresponding to water contact angles after every 100,000 cycles). As shown, points 3113 (Assembly JJJ) maintain a water contact angle greater than 90°, greater than 95°, greater than 98°, greater than 100°, and greater than 105° (e.g., about 110° or more) for all cycles measured (e.g., after 100,000 cycles, after 200,000 cycles, after 300,000 cycles, and after 400,000 cycles). The difference between the initial water contact angle and the braded contact angle (e.g., after 200,000 cycles) is less than 10° (e.g., about 5° or less).

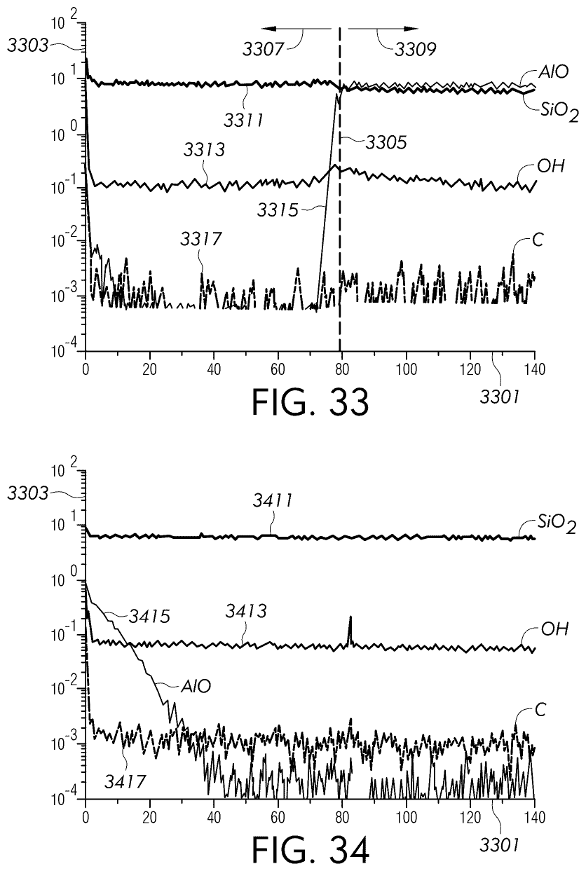

FIGS. 33-36 present compositional profiles relative to signal intensity of silicon (²⁸Si⁻) as measured by dynamic SIMS (D-SIMS) for Comparative Examples JJ and LL and Examples 37 and 41, respectively; while FIG. 32 presents the molar ratio of hydrogen to silicon in Examples 35-44 and Comparative Examples JJ-KK as measured by SIMS. As discussed above, D-SIMS was conducted using a time-of-flight secondary ion mass spectrometer (ToF-SIMS) with a dual beam configuration. Unless otherwise indicated, the TOF-SIMS used for the results reported herein was a TOF-SIMS M6 instrument (available from IONTOF GmbH) equipped with a Nanoprobe50 bismuth source. The TOF-SIMS M6 instrument was operated with a dual-beam configuration, where the analysis beam was a 30 kilo-electron Volts (keV) Bi₃⁺ beam with a current of about 0.1 pA and the sputter beam was 2 keV Cs⁺ with a current of about 120 nA. The sputter beam was configured form a 300 μm by 300 μm sputter “crater,” and the analysis beam was configured to impinge a 75 μm by 75 μm area centered in the sputter “crater.” Charge compensation was achieved using an electron flood gun operating with 20 nA beam current, 20 eV electron energy, and a 1.5 mm spot size focused on the location impinged by the analysis beam. The chamber was evacuated to a pressure of 5×10⁻⁷ Pascals (5×10⁻⁹ millibar) before being brought to and maintained at a pressure of 5×10⁻⁵ Pascals (5×10⁻⁷ millibar) using argon (e.g., 99.99999% purity). Data was collected in negative ion mode with the analyzer in the “all purpose” mode, an analyzer energy of 3000 V and a cycle time of 100 microseconds. Data was processed using Surface Lab software (version 7.3.125519 available from IONTOF GmbH). To obtain molar ratios, from ¹⁶O¹H⁻, ¹⁸O⁻, and ²⁸Si⁻ signals, the known isotope ratio between ¹⁸O⁻ and ¹⁷O⁻ was used to calculate and subtract the ¹⁷O⁻ interference from the ¹⁶O¹H⁻ signal. A normalized intensity was defined as the mass-interference-corrected ¹⁶O¹H signal divided by the ²⁸Si-signal. The normalized intensity (¹⁶O¹H⁻/²⁸Si⁻) further corrected to remove background signals (as determined from the normalized intensity (¹⁶O¹H⁻/²⁸Si⁻) measured from fused quartz-Comparative Example LL shown in FIG. 34) to determine a “corrected signal.” to determine a “corrected signal.” The corrected signal was converted to a hydrogen to silicon molar ratio (“molar ratio”) using a calibration curve (derived from a series of natural mid-ocean-ridge basaltic (MORB) glasses with known-OH concentrations and other silica and silicate minerals covering a range from 0.0 wt % to 1.98 wt %) with an equation of “molar ratio”=1.26*“corrected signal”−0.025.

As discussed above, it is believed that hydrogen is indicative of hydroxyl groups (e.g., silanol, Si—O—H). In FIGS. 33-36, the horizontal axis 3301 (i.e., x-axis) corresponds to a depth from the exterior surface of the sample (i.e., planarization layer in FIGS. 33 and 35-36) in nanometers, and the vertical axis 3303 (i.e., y-axis) is the compositional profile (normalized by the ²⁸Si⁻ signal. FIG. 34 shows the compositional profiles (relative to an amount of ²⁸Si⁻ as measured by dynamic SIMS) for Comparative Example LL, which is a fused quartz reference sample. Curve 3411 corresponds to SiO₂⁻, curve 3413 corresponds to OH, curve 3415 corresponds to AlO⁻, and curve 3417 corresponds to C⁻. As shown, the silicon and hydroxyl (hydrogen) content (curves 3411 and 3413) stabilized within the first 5 nm of the surface to produce a constant ratio (about 0.01) that is used to correct the signals, as discussed above. Curve 3415 (alumina) decreases to a background level over the first 40 nm from the surface, while carbon (curve 3417) is relatively constant after the first 5 nm or so from the surface.

FIG. 33 corresponds to the compositional profiles (relative to an amount of ²⁸Si⁻ as measured by dynamic SIMS) for Comparative Example JJ, which is PECVD deposited silica. Line 3305 corresponds to the thickness of the silica layer with portions of the sample closer to the surface than line 3305 (i.e., direction 3307) corresponding to the silica layer and portions further from the surface than line 3305 (i.e., direction 3309) corresponding to the glass-based substrate, which is easily discernably from the dramatic change in alumina (AlO⁻) content (curve 3315) leading up to 80 nm on the horizontal axis 3301. In FIG. 33, curve 3311 corresponds to SiO₂⁻, curve 3313 corresponds to OH⁻, curve 3315 corresponds to AlO⁻, and curve 3317 corresponds to C⁻. As shown, curves 3311 and 3313 stabilized to roughly the same ratio seen in FIG. 34. Also, carbon (curve 3317) and alumina (curve 3315) contents are negligible (e.g., at or below the measurement threshold) in the silica layer.

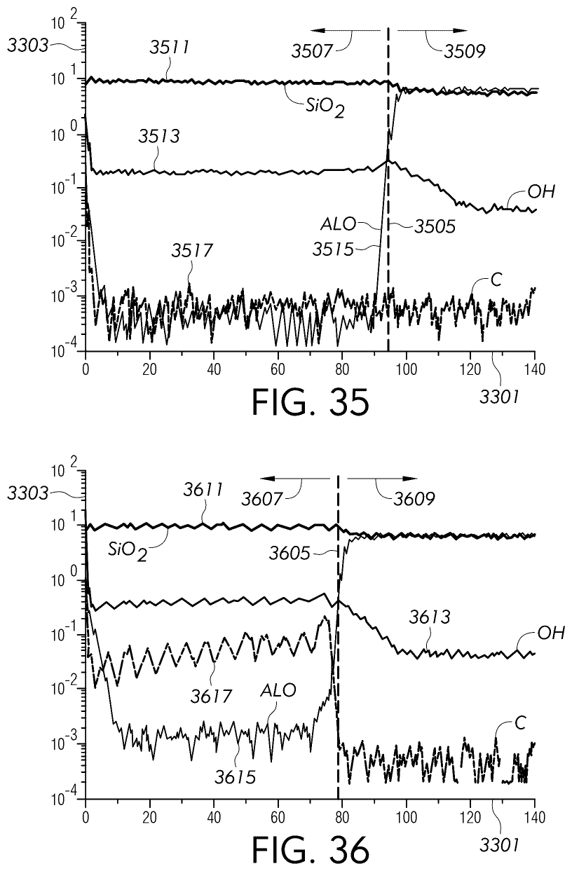

FIG. 35 corresponds to the compositional profiles (relative to an amount of ²⁸Si⁻as measured by dynamic SIMS) for Example 37, which is a planarization layer formed from octa-iso-butyl-functionalized POSS (OBPOSS) by IAD at a deposition rate of 0.5 A/s. Line 3505 corresponds to the thickness of the planarization layer with portions of the sample closer to the surface than line 3505 (i.e., direction 3507) corresponding to the planarization layer and portions further from the surface than line 3505 (i.e., direction 3509) corresponding to the glass-based substrate, which is easily discernably from the dramatic change in alumina (AlO⁻) content (curve 3515) leading up to 95 nm on the horizontal axis 3501 (i.e., x-axis). In FIG. 35, curve 3511 corresponds to SiO₂″, curve 3513 corresponds to OH, curve 3515 corresponds to AlO⁻, and curve 3517 corresponds to C—. As shown, curve 3513 (hydroxyl or hydrogen) is higher than curves 3313 and 3413 in FIGS. 33-34. Also, carbon (curve 3517) and alumina (curve 3515) contents are negligible (e.g., at or below the measurement threshold) in the planarization layer.

FIG. 36 corresponds to the compositional profiles (relative to an amount of ²⁸Si⁻ as measured by dynamic SIMS) for Example 41, which is a planarization layer formed from octa-iso-butyl-functionalized POSS (OBPOSS) by IAD at a deposition rate of 2.0 A/s. Line 3605 corresponds to the thickness of the silica layer with portions of the sample closer to the surface than line 3605 (i.e., direction 3607) corresponding to the planarization layer and portions further from the surface than line 3605 (i.e., direction 3609) corresponding to the glass-based substrate, which is easily discernably from the dramatic change in alumina (AlO⁻) content (curve 3615) leading up to 80 nm on the horizontal axis 3601 (i.e., x-axis). In FIG. 36, curve 3611 corresponds to SiO₂⁻, curve 3613 corresponds to OH, curve 3615 corresponds to AlO⁻, and curve 3317 corresponds to C⁻. As shown, curve 3613 (hydroxyl or hydrogen) is higher than curves 3313 and 3413 in FIGS. 33-34. Also, the alumina (curve 3315) content is negligible (e.g., at or below the measurement threshold) in the planarization layer. However, the carbon content (curve 3617) is much higher than curves 3317, 3417, and 3517 in FIGS. 33-35, indicating that the higher deposition rate does not fully remove the organic functional group on the functionalized POSS (e.g., OBPOSS), which is consistent with the gray appearance noted for Example 5 (same deposition rate with the same functionalized POSS).

In FIG. 32, the vertical axis 3203 (i.e., y-axis) is the molar ratio of hydrogen to silicon. The deposition conditions for Examples 35-44 and Comparative Examples JJ-KK are shown in Table 15. Example 35 was formed by spin coating a of 1% by volume (% v/v) solution of hydrogen POSS (i.e., POSS with R=H in FIG. 5) (HSQ) on the glass-based substrate at 1,200 rpm for 30 seconds before being heated at 400° C. for 30 minutes. Example 36 was formed by spin coating a 3% by volume (% v/v) solution of perhydropolysilazane (PHPS-see FIG. 6) without catalyst in dibutyl ether (Durazane 2250) on the glass-based substrate at 1,000 rpm for 30 seconds before being heated at 250° C. for 30 minutes. Examples 37-41 used octa-iso-butyl-functionalized POSS (OBPOSS) (i.e., POSS with R=iso-butyl in FIG. 5) in the IAD process (described above) with the deposition rates from 0.5 A/s to 2.0 A/s stated in Table 15. Examples 42-44 used octa-vinyl POSS (OVPOSS) ((i.e., POSS with R=vinyl in FIG. 5) in the IAD process (described above) to achieve a thickness from 50 nm to 200 nm as shown in Table 15. As discussed above, Comparative Example JJ was formed by PECVD while Comparative Example KK was formed by reactive sputtering.

TABLE 15
Deposition Conditions for Examples 35-44 and
Comparative Examples JJ-KK

| | | | Molar |
|---|---|---|---|
| Example | Material | Method | Ratio (H/Si) |
| 35 | HSQ | Spin Coating | 0.21 |
| 36 | PHPS | Spin Coating | 0.23 |
| 37 | OBPOSS | IAD: 0.5 A/s | 0.24 |
| 38 | OBPOSS | IAD: 0.7 A/s | 0.28 |
| 39 | OBPOSS | IAD 0.9 A/s | 0.26 |
| 40 | OBPOSS | IAD: 1.3 A/s | 0.31 |
| 41 | OBPOSS | IAD 2.0 A/s | 0.52 |
| 42 | OVPOSS | IAD: 50 nm | 0.30 |
| 43 | OVPOSS | IAD: 100 nm | 0.28 |
| 44 | OVPOSS | IAD: 200 nm | 0.28 |
| JJ | Silica | PECVD: 80 nm | 0.10 |
| KK | Silica | Reactive Sputter: 80 nm | 0.09 |

Dashed line 3205 corresponds to a molar ratio of hydrogen to silicon of 0.20. As shown in FIG. 32, Comparative Examples JJ-KK have molar ratios of hydrogen to silicon of about 0.10 (about half of dashed line 3205). As shown in FIG. 32, Examples 35-44 all have molar ratios of 0.2 or more. Consequently, Examples 35-44 have at least about double (2×) the molar ratio of Comparative Examples JJ-KK. Increasing the deposition rate for OBPSS (Examples 37-41) generally increases the molar ratio. However, increasing the thickness formed by OVPSS IAD from 50 nm to 200 nm (Examples 42-44) slightly decreases or does not substantially change the molar ratio. Also, Examples 35-40 and 42-44 have a molar ratio from 0.2 to 0.4 or from 0.22 to 0.35.

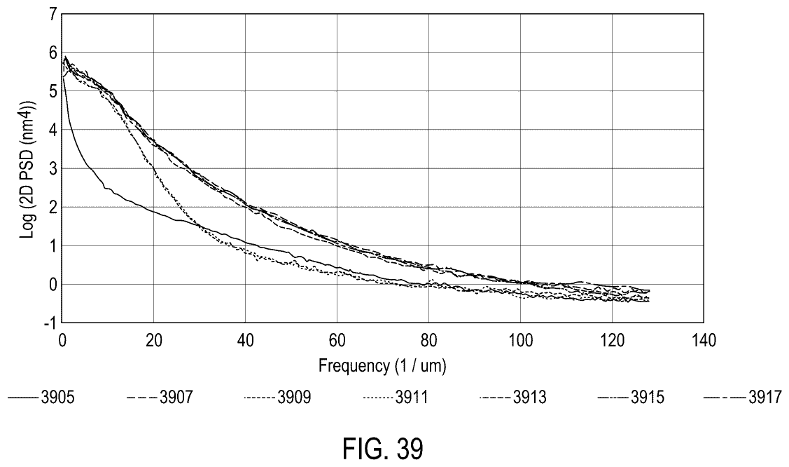

FIG. 39 presents power spectral density (PSD) of Examples 45-49 and Comparative Examples LL and MM. As discussed above, the PSD refers to the two-dimensional (2D) isotropic power spectral density (PSD) determined from height data measured using atomic force microscopy (AFM) for a 2 μm by 2 μm test area of the surface. Comparative LL comprised an uncoated substrate (GG3). Comparative MM comprised an 870 nm SiO₂ deposited on GG3. Examples 45-49 comprised a hydroxyl-modified layer formed by impinging a radio frequency plasma (discussed below) on MM to form the hydroxyl-modified layer. Unless otherwise indicated, plasma treatment occurred using a Plasmatherm 790 RIE plasma system. As used in this section, the samples were treated with the plasma for 2 minutes at 40° C. under the conditions shown in Table 16.

TABLE 16
Plasma Conditions and Results for Examples
45-49 and Comparative Examples KK and LL

| | | Pressure | RF | H₂ | O₂ | Ave |
|---|---|---|---|---|---|---|
| Example | Substrate | (mT) | (W) | (sccm) | (sccm) | (nm) |
| LL | GG3 | 0 | 0 | 0 | 0 | 1.26 |
| MM | 870 nm SiO₂/GG3 | 0 | 0 | 0 | 0 | 8.91 |
| Ex. 45 | 870 nm SiO₂/GG3 | 100 | 300 | 60 | 30 | 7.50 |
| Ex. 46 | 870 nm SiO₂/GG3 | 10 | 300 | 30 | 15 | 6.44 |
| Ex. 47 | 870 nm SiO₂/GG3 | 10 | 50 | 30 | 15 | 8.46 |
| Ex. 48 | 870 nm SiO₂/GG3 | 20 | 20 | 30 | 15 | 8.92 |
| Ex. 49 | 870 nm SiO₂/GG3 | 100 | 50 | 60 | 30 | 9.75 |

| | | | | | Peak to valley (PV) | |
|---|---|---|---|---|---|---|
| | Rq (nm) | Ra (nm) | Skew | kurtosis | (nm) | Volume |
| LL | 0.29 | 0.23 | 0.08 | 0.02 | 2.62 | 4.95 |
| MM | 2.32 | 1.85 | 0.17 | 0.06 | 20.15 | 35.63 |
| Ex. 45 | 1.82 | 1.43 | 0.17 | 0.34 | 16.82 | 30.00 |
| Ex. 46 | 1.76 | 1.39 | 0.15 | 0.26 | 15.67 | 25.74 |
| Ex. 47 | 2.28 | 1.82 | 0.07 | −0.04 | 19.47 | 33.82 |
| Ex. 48 | 2.44 | 1.94 | 0.12 | −5.55 | 18.92 | 35.70 |
| Ex. 49 | 2.37 | 1.89 | 0.05 | −0.07 | 20.29 | 39.01 |

| | L2PSD10 | L2PSD20 | L2PSD40 | L2PSD100 | L2PSD(40/10) |
|---|---|---|---|---|---|
| LL | 2.50 | 1.90 | 1.09 | −0.26 | 0.44 |
| MM | 4.97 | 3.61 | 2.00 | 0.07 | 0.40 |
| Ex. 45 | 4.82 | 2.97 | 0.88 | −0.29 | 0.18 |
| Ex. 46 | 4.77 | 2.98 | 0.82 | −0.15 | 0.17 |
| Ex. 47 | 4.89 | 3.69 | 1.98 | 0.00 | 0.40 |
| Ex. 48 | 4.98 | 3.74 | 2.13 | 0.05 | 0.43 |
| Ex. 49 | 4.97 | 3.72 | 2.10 | 0.01 | 0.42 |

FIG. 39 shows curves 3905, 3907, 3909, 3911, 3913, 3915, and 3917 that correspond to Comparative Example LL, Comparative Example MM, Example 45, Example 46, Example 47, Example 48, and Example 49, respectively. In FIG. 39, the horizontal axis 3901 (i.e., x-axis) corresponds to spatial frequencies in μm⁻¹, and the vertical axis 3903 (i.e., y-axis) is a logarithm (base 10) of the power spectral density (in nm⁴). As shown in FIG. 39, the curves 3909 and 3911 corresponding to Examples 45 and 46, both of which were treated at a power of 300 W but different pressure (100 mT and 10 mT, respectively) resulted in a relatively low roughness at high spatial frequencies (e.g. 40 μm⁻¹) while maintaining higher roughness at low spatial frequencies (e.g. 10 μm⁻¹). As shown in Table 16, the ratio of the logarithmic 2D power spectral density at 40 μm⁻¹ to the logarithmic 2D power spectral density at 10 μm⁻¹ of Examples 45 and 46 were 0.18 and 0.17, respectively. Examples 47, 48, and 49, which used a lower power plasma did not result in significant reduction in the ratio of the logarithmic 2D power spectral density at 40 μm⁻¹ to the logarithmic 2D power spectral density at 10 μm⁻¹. Without intending to be bound by any particular theory, it is believed that these results are surprising as reducing the pressure from 10 mT to 100 mT decreased self-bias from 600 to 487 V, and the mean free path was reduced from 7 mm to 0.7 mm, about twice the Debye length. Collisions should thermalize the plasma and reduce surface sputtering. However, the observed roughness reduction was correlated strongly with RF power, and pressure had little measurable impact even though theory predicts collisions should significantly reduce ion energy as pressure is increased from 10 to 100 mT.

The average change in SiO₂ thickness after the plasma treatments of Examples 45-49 is shown in Table 17. As shown in Table 17, near zero change in the thickness of the sample is observed for all conditions except Example 46, which included a relatively lower pressure and higher power (10 mT, 300 W) condition, where a 3 nm etch was observed.

TABLE 17
Change in Thickness for Examples 45-49

| | | | | Δ Th |
|---|---|---|---|---|
| Example | mT | RF (W) | sccm | (nm) |
| Ex. 45 | 100 | 300 | 90 | 0.28 |
| Ex. 46 | 10 | 300 | 45 | −3.12 |
| Ex. 47 | 10 | 50 | 45 | 0.43 |
| Ex. 48 | 20 | 20 | 45 | 0.24 |
| Ex. 49 | 100 | 50 | 90 | 0.44 |

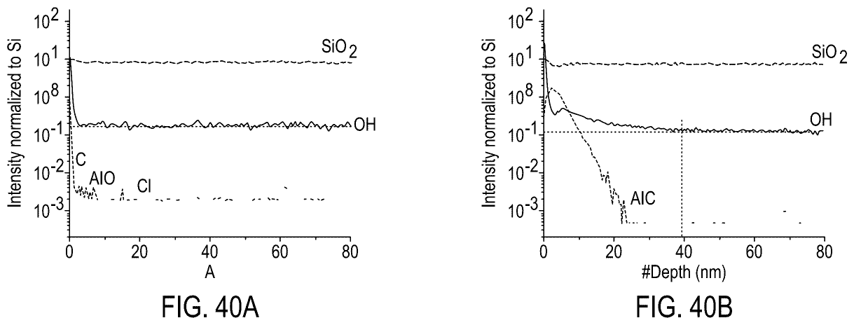

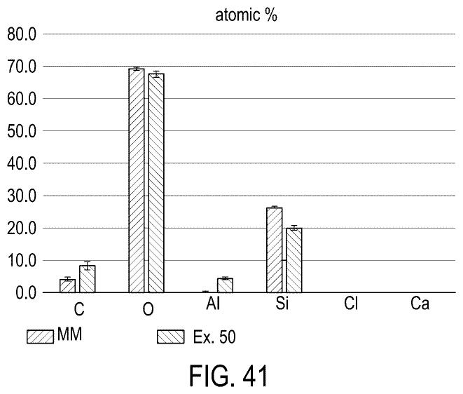

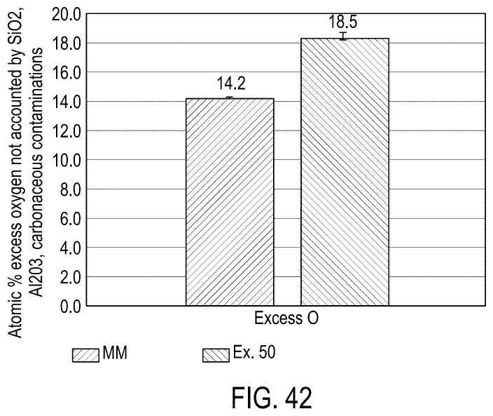

This unexpected significant change in surface morphology without change in silica thickness was explored by SIMS depth profiling, XPS, excess oxygen calculation, and spectroscopic ellipsometry as shown in FIGS. 40, 41, and 42 and Table 18, respectively. To produce Example 50, the substrate used in Comparative Example MM and Examples 45-49 were plasma treated under the following conditions: 3 min, 100 mT 2:1 H₂:O₂, and 500W RF plasma. FIGS. 40A and 40B correspond to the SIMS depth profile of Comparative Example MM and Example 50, respectively. As shown in FIG. 40, significant hydroxyl enrichment was observed in the top 40 nm of Example 50, compared to Comparative Example MM. As shown in FIG. 41, the XPS data showed slightly more C and significant (˜4.4 atomic %) Al contamination in Example 50. Al contamination arises from sputtering of the Al cathode in the Plasmatherm. More importantly, the O concentration was diminished only slightly while the Si concentration was diminished substantially more in Example 50 relative to Comparative Example MM. Assuming the Si and Al are present as stoichiometric oxides, and the fraction of oxygen in the carbonaceous material was estimated from the C 1s fine structure, the excess oxygen present in the top 6 nm in which XPS samples can be calculated. This excess oxygen is observed in silica films and is associated with the silanol content. FIG. 42 graphically depicts the excess oxygen measured in Comparative Example MM and Example 50. As shown in FIG. 42, Example 50 had 18.5% excess oxygen while Comparative Example had only 14.2% excess oxygen.

It is believed that the reaction of hydrogen plasma with the SiO₂ surface could also create Si—H bonding in addition to the Si—OH. Such formation of Si—H bonding may produce an observable UV absorption in the top surface of the plasma treated silica. This was tested by depositing uniform 73 nm thick PETEOS silica films on 150 mm Si wafers in an Applied Materials P5000, mapping wafer thickness and index by spectroscopic ellipsometry on a Woollam M-2000, exposing the samples to the following plasma conditions: 3 min, 2:1 H₂:O₂, 500 W RF plasma at 10 and 100 mT, and remapping in the same locations on the Woollam to produce Examples 51 and 52. Table 18 provides the spectroscopic ellipsometry data for Examples 51 and 52 prior to and subsequent the plasma treatment. The average over the 13 point wafer maps are presented in Table 18.

TABLE 18
Average change in SiO₂ thickness as measured by spectroscopic
ellipsometry in Example 51 and Example 52

| | | | | 2:1 H₂:O₂ Plasma Treated | | | | | |
|---|---|---|---|---|---|---|---|---|---|
| | As Deposited | | | Water | | Δ Th | std Δ | PI | std PI |
| Example | Thickness | std | n550 | P1 | | (nm) | Th | (nm) | (nm) |
| Ex. 51 | 73.43 | 0.73 | 1.4727 | 100 | mT | 1.39 | 0.10 | 8.11 | 0.51 |
| Ex. 52 | 72.89 | 0.69 | 1.4722 | 10 | mT | 4.26 | 0.11 | 7.76 | 0.20 |

The results were obtained by fitting the dispersion of the PETEOS silica film with a Tauc-Lorentz. The plasma treated films were fit as a bilayer with the dispersion of the bottom layer fixed as the as-deposited film while varying thickness, and the top layer was a linear gradient between the bulk film below and a surface layer of variable thickness which added a Gaussian oscillator in the UV to simulate the Si—H absorption to the Tauc-Lorentz. Table 18 shows the thickness of the plasma interaction layer (PI) and the total change in thickness. As shown in Table 18, the plasma reaction conditions of 3 min, 2:1 H₂: O₂, 500 W, and an RF plasma at 10 mT (Example 52) removed 4.3 nm of silica, while only 1.4 nm was removed at 100 mT (Example 51). The thickness of the PI layer was about 8 nm for both Example 51 and 52.

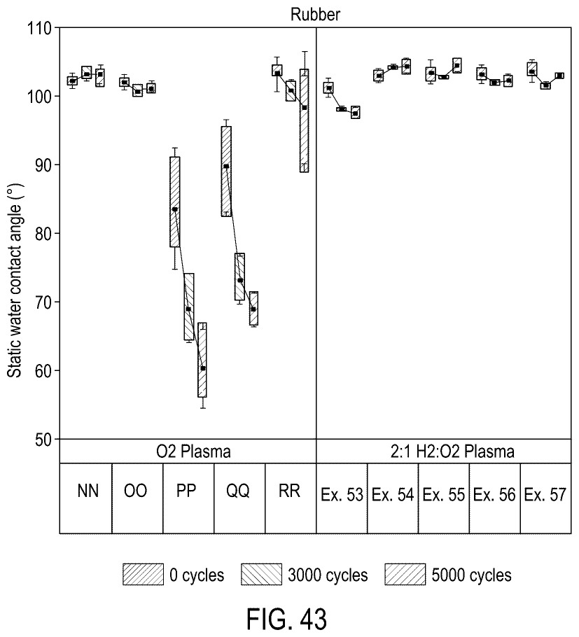

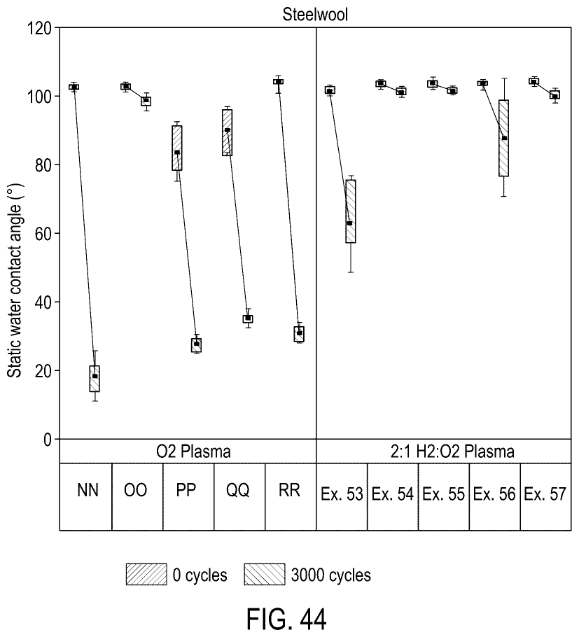

In Examples 53-57 and Comparative Examples NN, OO, PP, QQ, and RR, the impact of 2:1 H₂:O₂ plasma treatment on surface functionalization was investigated by comparing conventional O₂ plasma barrel ashing and 2:1 H₂: O₂ plasma treatment for surface activation immediately prior to spray coating functionalization with octadecyltrimethoxysilane (OTS) dissolved 2% in PGMEA. Samples were sprayed and cured by annealing in air at 150° C. for 30 min. The effectiveness of the silanization was determined by mapping water contact angle mapped over the 50 mm square substrates, measuring COF with a linear abrader, and testing durability with a rubber and steel wool abrasion testing. The results of these tests are shown in Table 19 and FIGS. 43 and 44.

TABLE 19
COF, WCA after OTS, and WCA after 3k cycles of rubber
abrasion for Examples NN-RR and Ex. 53-57

| | | | COF | COF | WCA | WCA | WCA |
|---|---|---|---|---|---|---|---|
| Example | Type | Activation | Avg | stdev | ave | std | min |
| NN | GG3 | Branson | 0.15 | 0 | 102.3 | 1.2 | 99.3 |
| OO | GG3 + OB POSS | Branson | 0.11 | 0 | 102.2 | 1.0 | 100.9 |
| PP | GG3 + 14 nm SiO2 | Branson | 0.14 | 0 | 83.7 | 8.9 | 68.8 |
| QQ | C1 | Branson | 0.44 | 0.02 | 89.9 | 6.7 | 81.1 |
| RR | C1 + OB POSS | Branson | 0.17 | 0 | 103.2 | 2.5 | 94.3 |
| Ex. 53 | GG3 | 2:1 H₂:O₂ plasma | 0.15 | 0 | 101.3 | 1.4 | 98.7 |
| Ex. 54 | GG3 + OB POSS | 2:1 H₂:O₂ plasma | 0.13 | 0 | 103.0 | 1.0 | 100.9 |
| Ex. 55 | GG3 + 14nm SiO2 | 2:1 H₂:O₂ plasma | 0.12 | 0 | 103.6 | 1.7 | 101.3 |
| Ex. 56 | C1 | 2:1 H₂:O₂ plasma | 0.17 | 0 | 103.2 | 1.4 | 101.0 |
| Ex. 57 | C1 + OB POSS | 2:1 H₂:O₂ plasma | 0.16 | 0 | 103.7 | 1.5 | 101.1 |

| | WCA | WCA | Rubber | Rubber | Rubber | Rubber |
|---|---|---|---|---|---|---|
| Example | max | uni | 3k ave | 3k std | 5k ave | 5k std |
| NN | 104.3 | 2.4% | 103.3 | 0.9 | 103.2 | 1.4 |
| OO | 104.1 | 1.6% | 100.8 | 0.9 | 101.5 | 0.8 |
| PP | 96.9 | 16.8% | 69.0 | 4.9 | 60.4 | 5.8 |
| QQ | 100.7 | 10.9% | 73.3 | 3.6 | 69.0 | 2.5 |
| RR | 105.3 | 5.3% | 100.9 | 1.6 | 98.4 | 8.1 |
| Ex. 53 | 104.3 | 2.8% | 98.1 | 0.2 | 97.6 | 0.8 |
| Ex. 54 | 104.5 | 1.7% | 104.3 | 0.1 | 104.4 | 1.0 |
| Ex. 55 | 107.3 | 2.9% | 102.8 | 0.1 | 104.5 | 1.0 |
| Ex. 56 | 105.9 | 2.4% | 102.1 | 0.4 | 102.4 | 0.8 |
| Ex. 57 | 106.0 | 2.4% | 101.7 | 0.6 | 103.1 | 0.4 |

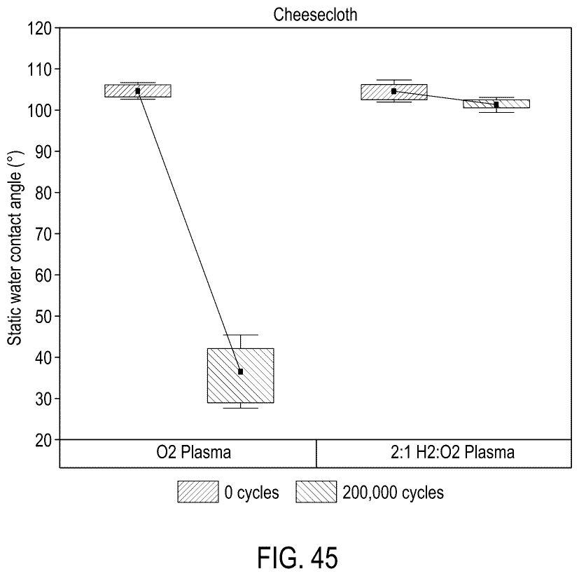

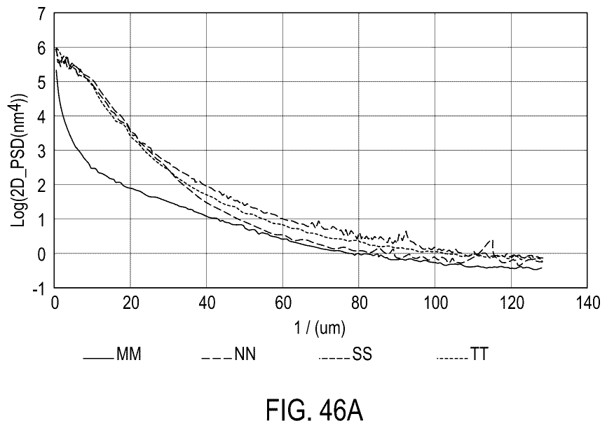

As shown in Table 19, the COF for Examples 53-57 and Comparative Examples NN, OO, PP, QQ, and RR was comparable except for the Branson treated C1 which exhibited about 3× higher COF. Both this Branson treated C1 and a Branson treated 14 nm SiO₂ coated GG3 also exhibited low and non-uniform WCA after silanization. This is consistent with poor activation of these SiO₂ coated surfaces in the Branson O₂ barrel asher. In contrast, all samples exhibited low COF and high WCA after 2:1 H₂: O₂ plasma treatment. FIG. 43 depicts the rubber abrasion performance of the Branson activated samples with SiO₂ surfaces. The C1 and 14 nm SiO₂ coated GG3, also exhibited poor rubber abrasion durability. Degradation was also noted in the Branson treated OB POSS coated C1. In contrast all the 2:1 H₂: O₂ plasma treated samples passed rubber abrasion. FIG. 44 depicts the WCA before and after 3000 cycles of steel wool abrasion. Branson activated 14 nm SiO₂ on GG3 and OB POSS coated C1 failed steel wool abrasion while 2:1 H₂:O₂ plasma treated samples passed steel wool abrasion. C1 samples failed both with Branson and 2:1 H₂:O₂ plasma treatment, but the failure was less extreme with the 2:1 H₂: O₂ plasma. Similarly, using C2, the samples failed 200,000 cycles of cheesecloth abrasion with Branson O₂ activation but passed with 2:1 H₂:O₂ plasma treatment, as shown in FIG. 45.

In Examples 58-60 and Comparative Examples SS, and TT, the mechanism by which the simultaneous 2:1 H₂:O₂ plasma reduces surface roughness and hydroxylates the SiO₂ surface was investigated by examining separately and sequentially the impact of the O₂ and H₂ plasma treatments as shown in Table 20.

TABLE 20
Reaction Conditions for Comparative Examples SS and TT and
Examples 58-60

| Ex- | Plasma | |
|---|---|---|
| ample | Process | Process Conditions |
| SS | O₂ | 2 min 40 C., 40 sccm O₂, 10 mT, 300 W |
| TT | H₂ | 2 min 40 C. 40 sccm H₂ 5 mT 300 W |
| Ex. 58 | 1X(O₂—H₂) | (A) 2 min 40 C., 40 sccm O₂, 10 mT |
| | | 300 W, + |
| | | (B) 5 s 40 C. 40 sccm H₂, 5 mT 300 W |
| Ex. 59 | 5X(O₂—H₂) | (A) 2 min, 40 C., 40 sccm O₂, 10 mT, |
| | | 300 W, + |
| | | (B) 5X (5 s, 40 C., 40 sccm O₂, 10 mT, |
| | | 300 W, + |
| | | (C) 5 s, 40 C., 40 sccm H₂, 5 mT 300 W ) |
| Ex. 60 | 20X(O₂—H₂) | (A) 2 min, 40 C., 40 sccm O₂, 10 mT, |
| | | 300 W + |
| | | (B) 20X (5 s, 40 C., 40 sccm O₂, 10 mT, |
| | | 300 W + |
| | | (C) 5 s, 40 C., 40 sccm H₂, 5 mT, 300 W ) |

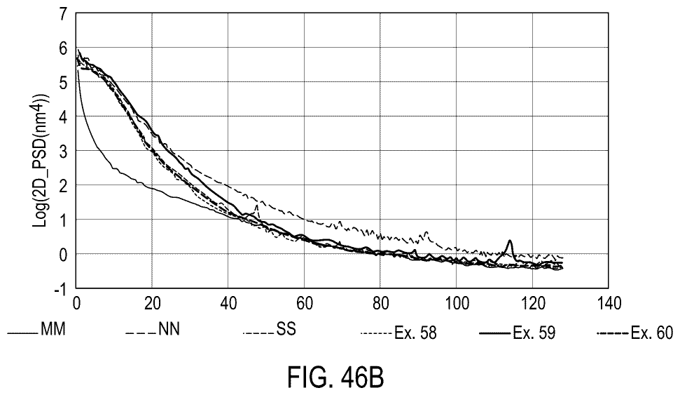

FIG. 46A depicts the 2D power spectral density plots of Comparative Example LL (untreated), Comparative Example MM (untreated), Comparative Example SS, and TT. FIG. 46B depicts the 2D power spectral density plots of Comparative Example LL (untreated), Comparative Example MM (untreated), Comparative Example SS, and Examples 58-60. The surface roughness parameters of Comparative Example LL, MM, SS, and TT and Examples 58-60 are presented in Table 21.

TABLE 21
Surface Roughness Parameters for Comparative Examples
LL, MM, SS, and TT and Examples 58-60

| Example | LL | MM | SS | TT | Ex. 58 | Ex. 59 | Ex. 60 |
|---|---|---|---|---|---|---|---|
| Treatment | Untreated | Untreated | O₂ | H₂ | 1X(O₂- | 5X(O₂- | 20X(O₂- |
| | | | | | H₂) | H₂) | H₂) |
| Rq (nm) | 0.30 | 2.19 | 2.21 | 2.09 | 1.77 | 1.84 | 1.72 |
| Ra (nm) | 0.24 | 1.73 | 1.76 | 1.66 | 1.41 | 1.46 | 1.36 |
| Skew | 0.06 | 0.24 | 0.10 | 0.27 | 0.22 | 0.24 | 0.26 |
| kurtosis | 0.06 | 0.11 | 0.09 | 0.16 | 0.06 | 0.04 | 0.34 |
| PV (nm) | 3.18 | 17.61 | 19.64 | 17.73 | 14.20 | 14.96 | 15.66 |
| L2PSD(40/10) | 0.44 | 0.40 | 0.30 | 0.35 | 0.26 | 0.28 | 0.24 |

As shown in FIGS. 46A and 46B, a low pressure intense H₂ plasma has only a small impact on surface morphology (Comparative Example TT). In contrast, the 2 min O₂ plasma reduced roughness Ra from 1.73 to 1.66 nm, and reduces L2PSD (40/10) from 0.40 to 0.30 (Comparative Example SS). This result is consistent with sputter etching. That is, at this pressure the mean free path should be on the order of 7 mm, about twenty times the Debye length. Surprisingly, it was found a 2 min O₂ plasma followed by a brief 5s H₂ plasma reduced roughness to 1.41 nm Ra, and L2PSD (40/10) to 0.26 (Example 58). Extending the number of 5 s O₂+5s H₂ cycles to 20 further reduced roughness and L2PSD (40/10) (Example 60).

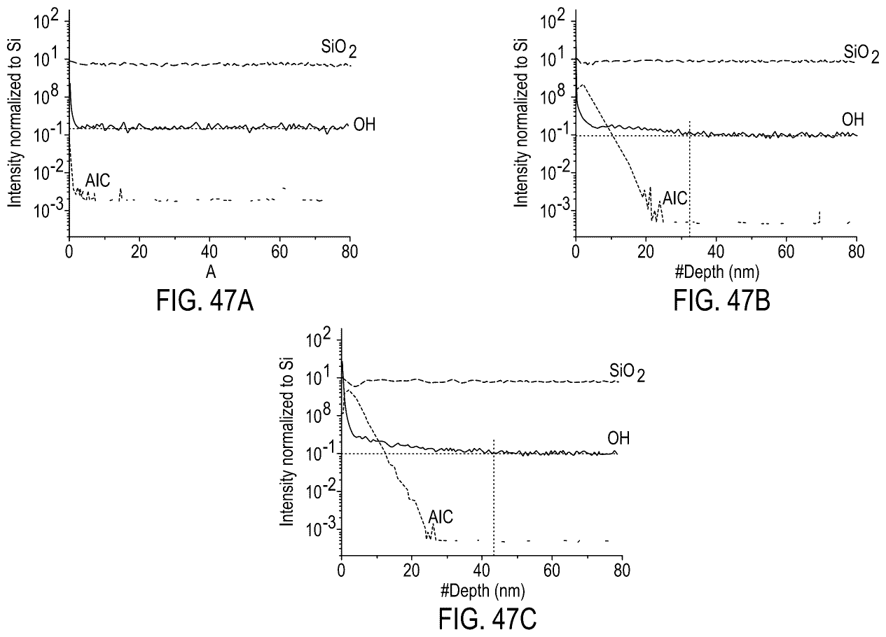

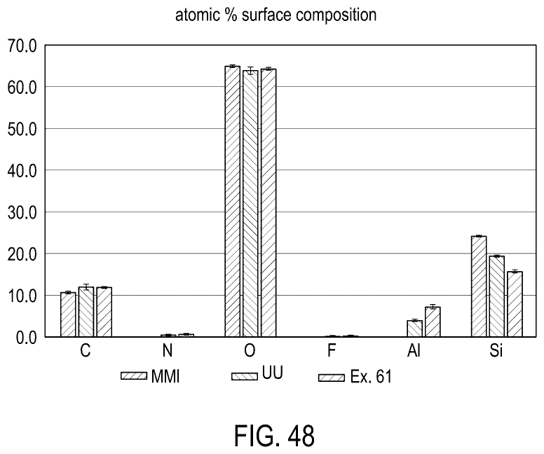

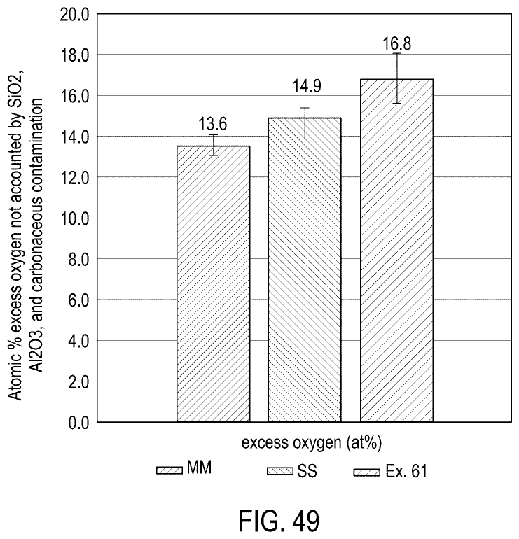

In Example 61 and Comparative Example UU, additional samples were prepared with a 400 nm SiO₂ coating on C1 and were either hydrogen plasma treated under the conditions used in Comparative Example TT (Comparative Example UU) or plasma treated 10X(O₂—H₂) under the conditions used in Examples 58-60 (Example 61). The surface composition changes of Example 61 and Comparative Example UU were characterized by SIMS depth profiling and XPS as shown in FIGS. 47 and 48, respectively. FIG. 47A, 47B, and 47C depict the SIMS profile of the untreated substrate (Comparative Example MM), Comparative Example UU, and Example 61, respectively. As shown in FIGS. 47B and 47C, a surface oxygen enrichment layer extended approximately 35 nm deep in the H₂ plasma treated sample (Comparative Example UU), and about 45 nm deep in the sequential O₂—H₂ treated sample (Example 61). The atomic surface composition and excess oxygen was determined using XPS for the control substrate, Comparative Example UU, and Example 61, as shown in FIGS. 48 and 49. These results in combination with Example 50 suggest that the highest surface oxygen enrichment is achieved using simultaneous H₂—O₂ plasma treatment.

In Examples 62-71, the impact of sequential O₂—H₂ (SEQ) and 2:1 H₂:O₂ plasma treatment (SIM) on surface functionalization were investigated using the samples according to Table 22.

TABLE 22
WCA after OTS, and COF for Examples 62-71

| | Samples | | | WCA Maps | | | | | COF | |
|---|---|---|---|---|---|---|---|---|---|---|
| Ex. | Substrate | Surface | Activation | ave | std | min | max | uni | Avg | stdev |
| Ex. 62 | GG3 | GG | SEQ | 94.76 | 2.63 | 87.60 | 100.40 | 6.8% | 0.23 | 0.01 |
| Ex. 63 | GG3 +OB- | OB-PSS | SEQ | 103.43 | 1.33 | 95.00 | 105.50 | 5.1% | 0.13 | 0 |
| | POSS | | | | | | | | | |
| Ex. 64 | GG3 + | SiO2 | SEQ | 104.68 | 1.48 | 101.70 | 107.80 | 2.9% | 0.13 | 0 |
| | 12 nm | | | | | | | | | |
| | SiO2 | | | | | | | | | |
| Ex. 65 | C1 | SiO2 | SEQ | 104.04 | 1.51 | 98.90 | 106.10 | 3.5% | 0.19 | 0 |
| Ex. 66 | C1 + OB | OB-PSS | SEQ | 103.93 | 1.61 | 92.40 | 105.30 | 6.2% | 0.16 | 0 |
| | POSS | | | | | | | | | |
| Ex. 67 | GG3 | GG | SIM | 97.27 | 1.38 | 93.40 | 100.50 | 3.6% | 0.2 | 0 |
| Ex. 68 | GG3 +OB- | OB-PSS | SIM | 102.16 | 3.45 | 87.70 | 104.50 | 8.2% | 0.15 | 0 |
| | POSS | | | | | | | | | |
| Ex. 69 | GG3 + | SiO2 | SIM | 103.47 | 1.27 | 97.20 | 105.40 | 4.0% | 0.12 | 0 |
| | 12 nm | | | | | | | | | |
| | SiO2 | | | | | | | | | |
| Ex. 70 | C1 | SiO2 | SIM | 104.83 | 0.72 | 103.00 | 106.20 | 1.5% | 0.17 | 0 |
| Ex. 71 | C1+ OB | OB-PSS | SIM | 104.25 | 1.16 | 101.90 | 107.30 | 2.6% | 0.17 | 0 |
| | POSS | | | | | | | | | |

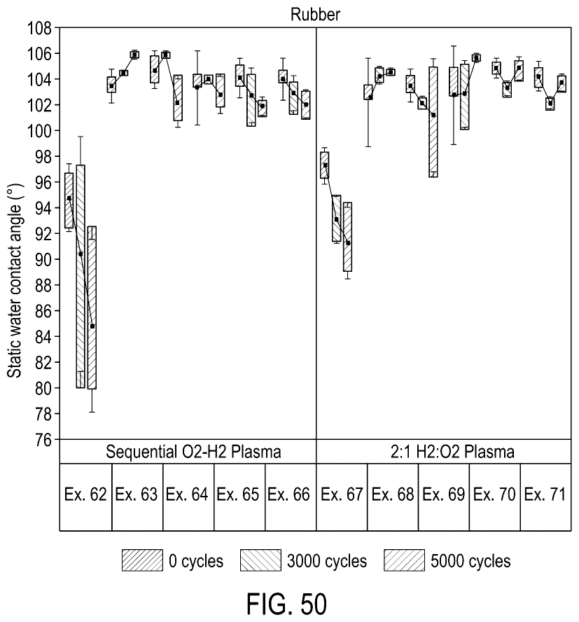

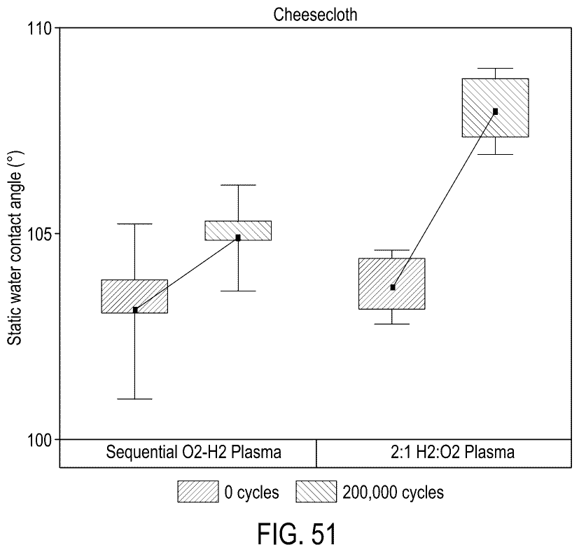

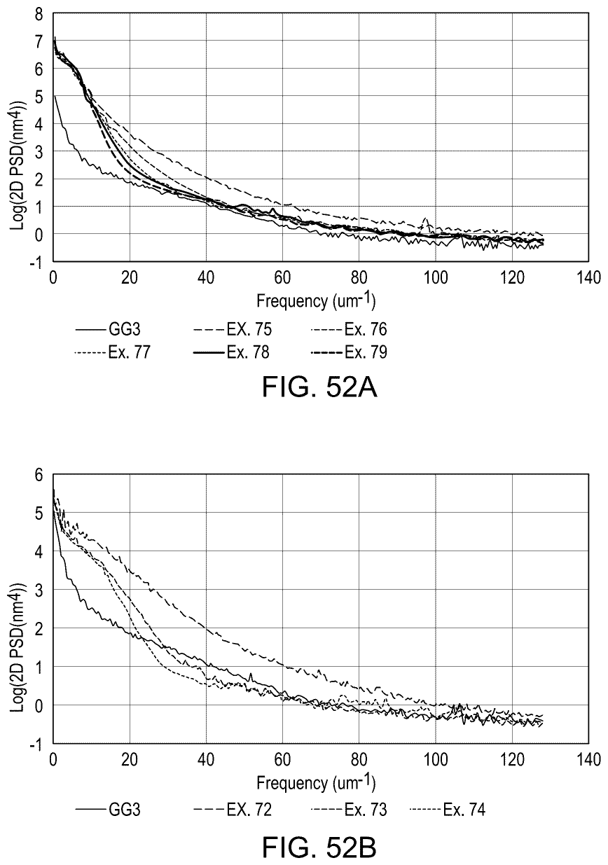

Table 22 compares WCA maps and COF of Examples 62-71. FIGS. 50 and 51 depict rubber and cheesecloth abrasion after OTS functionalization. As shown in Table 22 and FIGS. 50 and 51, the WCA, COF, rubber abrasion, and cheesecloth were comparable for both sequential and simultaneous O₂—H₂ plasma treatments. The rubber and cheesecloth abrasion samples used for Examples 62-71 were cleaned and surfaces outside of the abrasion area were characterized by AFM. The measured roughness measurements for Examples 72-79 are summarized in Table 23 and power square density plots are depicted in FIG. 52.

| | | | Ave | Rq | Ra | | | PV | | |
|---|---|---|---|---|---|---|---|---|---|---|
| Ex. | Sample | Method | (nm) | (nm) | (nm) | Skew | Kurtosis | (nm) | Volume | L2PSD(40/10) |
| Ex. | C2 | Branson | 5.284 | 1.349 | 1.078 | 0.273 | 6.123 | 11.367 | 21.136 | 0.47 |
| 72 | | | | | | | | | | |
| Ex. | C2 | SEQ | 2.629 | 0.72 | 0.569 | 0.303 | 0.446 | 7.001 | 10.518 | 0.19 |
| 73 | | O2 + H2 | | | | | | | | |
| Ex. | C2 | SIM | 2.298 | 0.641 | 0.508 | 0.248 | 0.205 | 5.198 | 9.194 | 0.14 |
| 74 | | H2 + 02 | | | | | | | | |
| Ex. | C1 | Branson + | 14.038 | 3.334 | 2.65 | −0.037 | 0.043 | 25.4 | 56.151 | 0.41 |
| 75 | | OTS | | | | | | | | |
| Ex. | C2 | SEQ | 11.505 | 2.871 | 2.29 | 19.63 | 0.036 | 24.63 | 46.02 | 0.27 |
| 76 | | O2 + H2 | | | | | | | | |
| Ex. | C2 | SIM | 10.663 | 2.728 | 2.185 | 0.039 | −0.059 | 20.836 | 42.653 | 0.24 |
| 77 | | H2 + O2 | | | | | | | | |
| Ex. | C2 OB- | SEQ | 9.59 | 2.774 | 2.205 | 28.016 | 0.108 | 20.613 | 38.358 | 0.26 |
| 78 | POSS | O2 + H2 | | | | | | | | |
| Ex. | C1 + OB- | SIM | 9.623 | 2.506 | 1.993 | 0.136 | 0.131 | 19.961 | 38.49 | 0.23 |
| 79 | POSS | H2 + O2 | | | | | | | | |

As shown in Table 23, the Branson O₂ barrel ashed surfaces exhibited roughness comparable to the as-deposited surfaces. Simultaneous H₂—O₂ plasma treatment reduced surface roughness more effectively than sequential O₂—H₂ plasma treatment. OB-POSS deposition reduced roughness to a similar degree as simultaneous O₂—H₂ plasma treatment, but combined OB-POSS and simultaneous O₂—H₂ plasma treatment produced the smoothest surfaces.

The results demonstrated in Examples 45-79 suggest a mechanism of oxygen sputter etch ablating silica and enabling hydrogen addition across the 5 eV Si—O bond near room temperature. To further explore this theory, Examples 80-88 were prepared by treating sample MM (GC3+579 nm SiO₂) using an Ar—Cl₂—O₂ plasma, according to Table 24.

TABLE 24
Substrate, pressure and RF power of 1 min Ar-Cl₂-O₂ plasma process,
and summary of AFM roughness and PSD parameters for Examples 80-88

| Example | Flow (sccm) | Pr (mT) | RF (W) | % C12 | % O2 | Ave (nm) |
|---|---|---|---|---|---|---|
| MM | | | | | | 9.141 |
| (untreated) | | | | | | |
| Ex. 80 | 50 | 10 | 300 | 20% | 0% | 8.043 |
| Ex. 81 | 50 | 10 | 300 | 40% | 0% | 6.354 |
| Ex. 82 | 50 | 10 | 300 | 20% | 30% | 6.395 |
| Ex. 83 | 50 | 10 | 300 | 40% | 30% | 5.401 |
| Ex. 84 | 80 | 30 | 300 | 20% | 0% | 5.834 |
| Ex. 85 | 80 | 30 | 300 | 40% | 0% | 6.925 |
| Ex. 86 | 80 | 30 | 300 | 20% | 30% | 5.755 |
| Ex. 87 | 80 | 30 | 300 | 40% | 30% | 5.454 |
| Ex. 88 | 65 | 20 | 300 | 30% | 15% | 6.622 |
| Example | Rq (nm) | Ra (nm) | Skew | kurtosis | PV (nm) | L2PSD(40/10) |
| LL | 0.303 | 0.241 | 0.048 | 0.157 | 5.598 | 0.44 |
| (untreated) | | | | | | |
| MM | 2.168 | 1.742 | 0.014 | −0.152 | 17.756 | 0.53 |
| (untreated) | | | | | | |
| Ex. 80 | 1.610 | 1.279 | 0.123 | 0.101 | 14.629 | 0.29 |
| Ex. 81 | 1.504 | 1.194 | 0.117 | 0.175 | 13.436 | 0.27 |
| Ex. 82 | 1.568 | 1.244 | 0.159 | 0.189 | 14.120 | 0.28 |
| Ex. 83 | 1.263 | 0.997 | 0.224 | 0.224 | 11.681 | 0.22 |
| Ex. 84 | 1.424 | 1.130 | 0.168 | 0.172 | 11.924 | 0.23 |
| Ex. 85 | 1.407 | 1.112 | 0.146 | 0.219 | 12.843 | 0.23 |
| Ex. 86 | 1.513 | 1.201 | 0.158 | 0.118 | 11.802 | 0.24 |
| Ex. 87 | 1.391 | 1.112 | 0.173 | 0.051 | 11.321 | 0.24 |
| Ex. 88 | 1.509 | 1.198 | 0.165 | 0.083 | 13.274 | 0.26 |

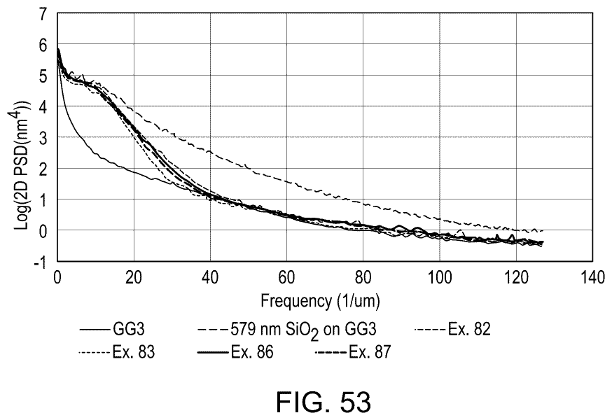

The Examples were treated in an Oxford Plasmalab 100 ICP etcher. 579 nm thick SiO₂ on GG samples were etched for 60 sec at 23° C. under the RIE etch conditions (bias power applied no power to ICP coil). The thickness of the SiO₂ on GG samples was measured by fringe fitting with a Filmetrics F50 before and after plasma treatment and the change in thickness is reported in Table 24. FIG. 53 depicts the two-dimensional power spectral density plots of Examples 82, 83, 86, and 87. The Ar—Cl₂—O₂ plasma treatment resulted in both considerable roughness reduction and sputter etching of the SiO₂ on GG as shown in Table 24 and FIG. 53. Ar—Cl₂ plasma treatment resulted in excess SiO₂ sputter etching, while Ar—Cl₂—O₂ plasma treatment yielded similar roughness reduction with less sputter etching. The PSD curves shown in FIG. 53 show the Ar—Cl₂—O₂ plasma treatment yields roughness reduction similar to that of sequential O₂—H₂ plasma or simultaneous 2:1 H₂:O₂ plasma treatment.

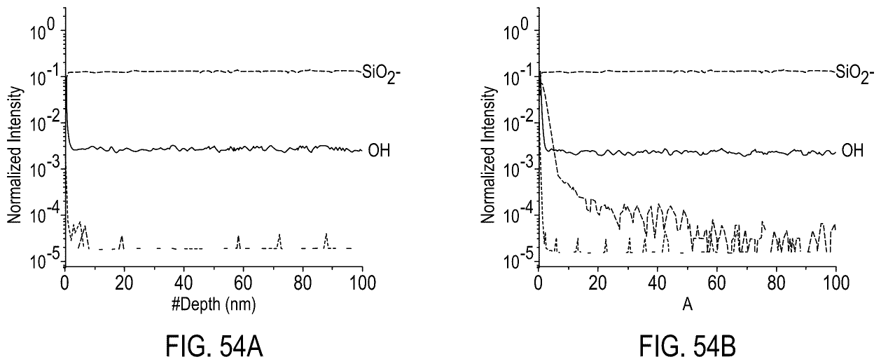

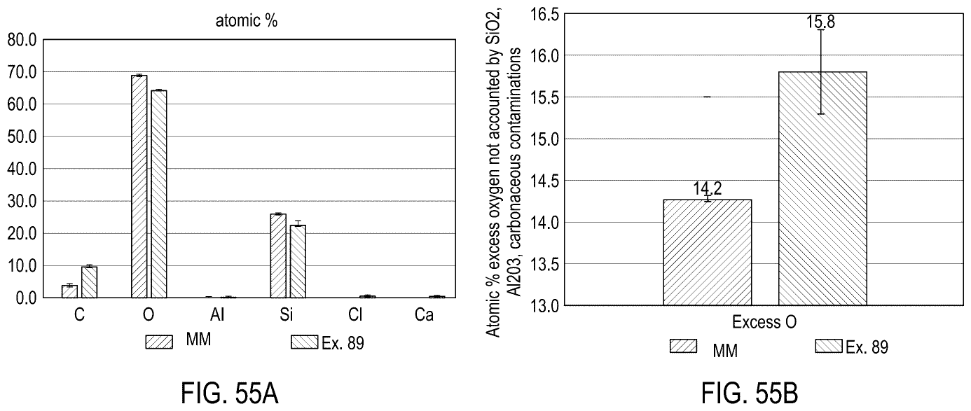

In Example 89, the surface composition of MM (579 nm SiO₂ on GG3) was plasma treated under the following conditions: 1 min, 10 mT, 15 sccm Ar₂, 20 sccm Cl₂, 15 sccm O₂, 300 W. Example 89 was characterized by SIMS and XPS as shown in FIGS. 54 and 55, respectively. FIGS. 54A and 54B depict the compositional profiles relative to signal intensity of silicon as measured by dynamic SIMS (D-SIMS) on the vertical axis (y-axis) as a function of a distance from the surface in nanometers on the horizontal axis (x-axis) for Comparative Example MM and Example 89, respectively. As shown in FIGS. 54A and 54B, a surface enrichment of Cl⁻ extended about 7 nm into Example 89 while the OH-concentration was similar to that of the control. As shown in FIG. 55, the XPS data shows more extraneous carbon on the Ar—Cl₂—O₂ plasma treated MM, as well as some Cl. Si and O concentrations are slightly lower, and the surface has about 1.5% more excess oxygen than the as-deposited MM control. That is, the reaction conditions of Example 89 resulted is less excess oxygen relative to the 2:1 H₂: O₂ plasma treated sample.

In Examples 90-94, Ar—Cl₂—O₂ plasma treated SiO₂ on GG surfaces were functionalized with OTS by the standard spray process, and water contact angle was mapped over the 50 mm square substrates. The COF and WCA of Examples 90-94 are reported in Table 25.

TABLE 25
COF and WCA of Ar-Cl₂-O₂ plasma treated samples of Examples 90-94

| Example | Description | COF ave | stdev | WCA ave | stddev | min | max | uniformity |
|---|---|---|---|---|---|---|---|---|
| Ex. 90 | GG3 | 0.17 | 0 | 100 | 0.9 | 96.2 | 102.1 | 3% |
| Ex. 91 | GG3 + OB- | 0.43 | 0.02 | 85.4 | 4.2 | 76.5 | 94.4 | 10.50% |
| | POSS | | | | | | | |
| Ex. 92 | GG3 + 12 nm | 0.18 | 0 | 101 | 0.9 | 99.1 | 102.6 | 1.70% |
| | SiO₂ | | | | | | | |
| Ex. 93 | C1 | 0.14 | 0 | 85.8 | 3.8 | 78.3 | 94.9 | 9.70% |
| Ex. 94 | C1 + OB- | 0.27 | 0.01 | 86.8 | 3.7 | 75.2 | 93.6 | 10.60% |
| | POSS | | | | | | | |

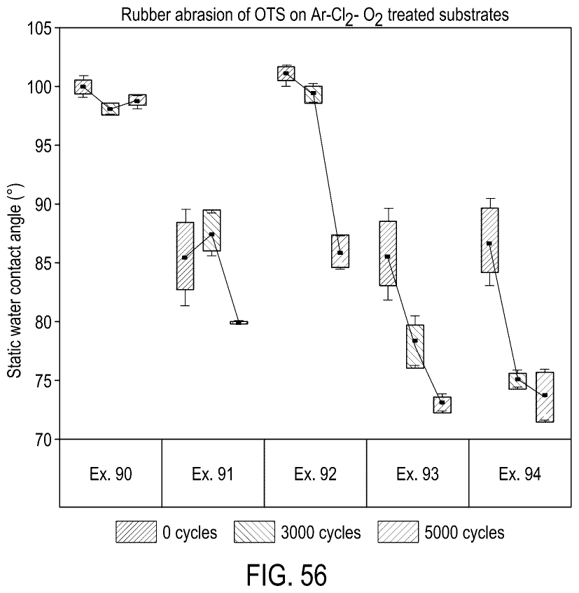

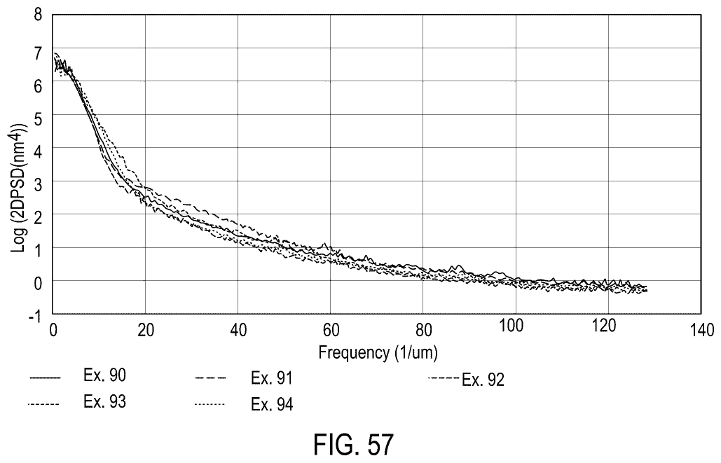

FIG. 56 depicts rubber abrasion tests for Examples 90-94. FIG. 57 depicts logarithms of two-dimensional (2D) power spectral density (PSD) distributions on the vertical axis (y-axis) as a function of spatial frequency in μm⁻¹ on the horizontal axis (x-axis) for Examples 90-94. As shown in FIG. 56, all samples except Ex. 90 showed extensive degradation by 5000 cycles despite the smooth surface morphology as shown in FIG. 57. These results are consistent with poor OTS functionalization of the Ar—Cl₂—O₂ plasma treated surfaces. Low WCA and high COF suggest low coverage with OTS functionalization. Further, it is believed that failure in the rubber abrasion test is consistent with poor coverage of the OTS functionalization and/or or poor silane condensation. Thus, these results demonstrate that roughness reduction without surface hydroxylation may be insufficient for acceptable ETC performance and/or abrasion resistance.

In Examples 95-103, the mechanism by which the simultaneous 2:1 H₂:O₂ plasma reduces roughness and hydroxylates the SiO₂ surface of the substrate was further investigated by treating silica surfaces with a water vapor plasma. A temperature regulated ampoule containing degassed DI water and heated line were added to the Plasmatherm 790 RIE with water vapor flow controlled by a vapor phase MFC. Flow was calibrated by rate of rise into the known chamber volume. 860 nm thick SiO₂ on GG3 samples were water vapor plasma treated with 30 sccm water vapor, 500 W RF at the pressures and times according to Table 26.

TABLE 26
Water vapor plasma treatment pressure and time, change in thickness
as measured by spectroscopic ellipsometry, and AFM roughness
parameters of untreated substrate and Examples 95-103

| Example | RF | Pr | Time | ΔTh (nm) | Ave (nm) | Rq (nm) | Ra (nm) |
|---|---|---|---|---|---|---|---|
| Control | | | | | 9.899 | 2.424 | 1.926 |
| Ex. 95 | 500 | 50 | 60 | 0.51 | 9.414 | 2.386 | 1.911 |
| Ex. 96 | 500 | 100 | 600 | 0.1 | 5.069 | 1.180 | 0.941 |
| Ex. 97 | 500 | 50 | 600 | 0.39 | 4.242 | 1.126 | 0.897 |
| Ex. 98 | 500 | 10 | 60 | 0.97 | 9.847 | 2.356 | 1.882 |
| Ex. 99 | 500 | 10 | 180 | 1.02 | 7.428 | 1.946 | 1.548 |
| Ex. 100 | 500 | 100 | 180 | −0.6 | 7.102 | 1.837 | 1.461 |
| Ex. 101 | 500 | 100 | 60 | 1.38 | 9.667 | 2.370 | 1.891 |
| Ex. 102 | 500 | 10 | 600 | 7.38 | 5.235 | 1.229 | 0.981 |
| Ex. 103 | 500 | 50 | 180 | −0.16 | 8.149 | 1.928 | 1.527 |

| | Skew | kurtosis | PV (nm) | Volume | L2PSD(40/10) |
|---|---|---|---|---|---|
| Control | 0.079 | 0.093 | 20.561 | 39.594 | 0.45 |
| Ex. 95 | 0.087 | −0.065 | 19.089 | 37.657 | 0.38 |
| Ex. 96 | −0.096 | −0.005 | 10.074 | 20.274 | 0.15 |
| Ex. 97 | 0.061 | 0.028 | 9.574 | 16.967 | 0.16 |
| Ex. 98 | 0.137 | 0.002 | 20.174 | 39.387 | 0.40 |
| Ex. 99 | 0.153 | 0.099 | 16.140 | 29.714 | 0.22 |
| Ex. 100 | 0.211 | 0.106 | 15.081 | 28.406 | 0.18 |
| Ex. 101 | 0.078 | 0.101 | 20.390 | 38.667 | 0.35 |
| Ex. 102 | 0.032 | 0.068 | 10.457 | 20.940 | 0.19 |
| Ex. 103 | 0.193 | 0.197 | 16.759 | 32.595 | 0.20 |

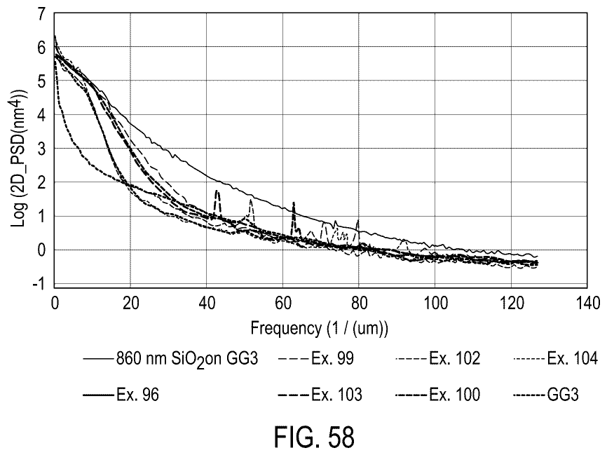

Change in thickness was determined by spectroscopic ellipsometry. In particular, uniform 73 nm thick PETEOS silica films were deposited on 150 mm Si wafers in an Applied Materials P5000, mapping wafer thickness and index by spectroscopic ellipsometry on a Woollam M-2000, exposing the samples to the plasma conditions in Table 26, and remapping in the same locations on the Woollam to produce the Examples 95-103. Table 22 provides the spectroscopic ellipsometry data for the examples prior to the plasma treatment (Control) and subsequent the treatment (Ex. 95-103). The average over the 13 point wafer maps are presented in Table 26. As shown in Table 26, the water vapor sputter etch rate was comparable, ˜0.7 nm/min at 10 mT, and negligible at 50 or 100 mT. FIG. 58 depicts logarithms of two-dimensional (2D) power spectral density (PSD) distributions on the vertical axis (y-axis) as a function of spatial frequency in μm⁻¹ on the horizontal axis (x-axis) for Examples 95-103. The AFM results are summarized in Table 26. As shown in Table 26 and FIG. 58, the degree of smoothing using the water vapor plasma treatment is comparable to simultaneous 2:1 H₂: O₂ plasma treatment. The steep observable PSD peaks in FIG. 58 are believed to be artifacts due to construction related building vibrations.

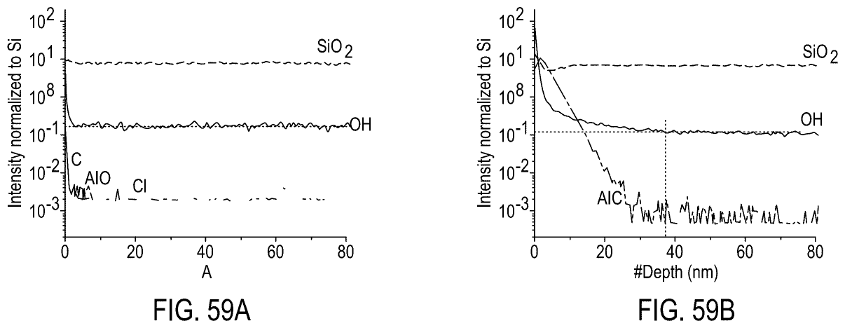

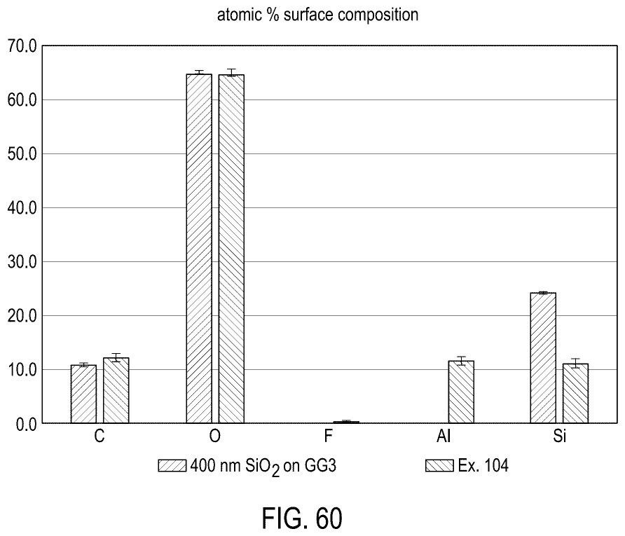

In Example 104, surface composition changes were characterized by SIMS depth profiling and XPS, as shown in FIGS. 59 and 60, respectively. Example 104 was prepared by depositing 400 nm SiO₂ on GG3 and water vapor plasma treating the substrate for 5 minutes with 30 sccm water vapor, 500 W RF, at a pressure of 50 mT. FIGS. 59A and 59B schematically illustrates compositional profiles relative to signal intensity of silicon as measured by dynamic SIMS (D-SIMS) on the vertical axis (y-axis) as a function of a distance from the surface in nanometers on the horizontal axis (x-axis) for the 400 nm SiO₂ on GG3 prior to treatment and Example 104, respectively.

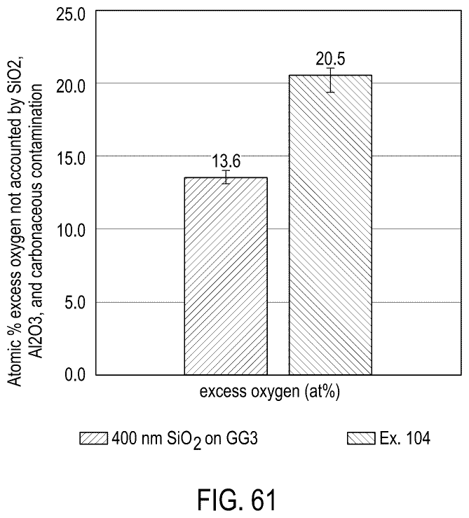

As shown in FIG. 59, the surface OH-enrichment of Example 104 extended about 40 nm, and the magnitude of the OH-enrichment was equivalent or larger to the simultaneous H₂—O₂ treated samples described herein. The atomic % of the surface composition of Example 104 was determined using XPS, as shown in FIG. 60. The excess oxygen of Example 104, as shown in FIG. 61 demonstrates an excess oxygen of 20.5 at. %.

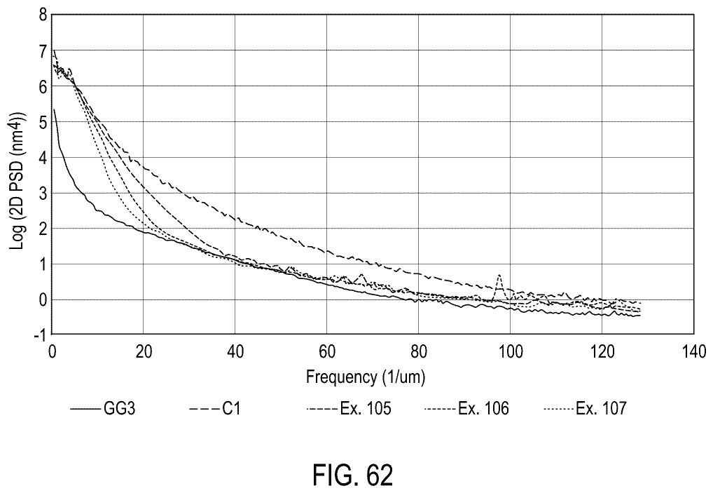

In Examples 105-107, the impact of water vapor plasma treatment on surface functionalization was investigated by comparing WCA maps, COF, and rubber abrasion after OTS functionalization of GG3 and C1 before and after varied water plasma treatment times. AFM characterization of the water vapor plasma treated C1 is shown in Table 27. FIG. 62 depicts logarithms of two-dimensional (2D) power spectral density (PSD) distributions on the vertical axis (y-axis) as a function of spatial frequency in μm⁻¹ on the horizontal axis (x-axis) for Examples 105-107.

TABLE 27
AFM roughness parameters of untreated and water
vapor plasma treated samples of Examples 105-107

| | Treatment | Ave | Rq | Ra | | | PV | |
|---|---|---|---|---|---|---|---|---|
| Example | time (s) | (nm) | (nm) | (nm) | Skew | kurtosis | (nm) | L2PSD(40/10) |
| GG3 | Untreated | 1.26 | 0.29 | 0.23 | 0.08 | 0.02 | 2.62 | 0.44 |
| C1 | Untreated | 14.91 | 3.34 | 2.66 | −0.12 | 0.08 | 29.95 | 0.45 |
| Ex. 105 | 120 | 13.22 | 2.91 | 2.32 | −0.11 | −0.01 | 23.09 | 0.25 |
| Ex. 106 | 300 | 10.43 | 2.67 | 2.11 | −0.10 | 0.07 | 19.69 | 0.23 |
| Ex. 107 | 600 | 8.85 | 2.26 | 1.78 | −0.01 | 0.09 | 17.18 | 0.25 |

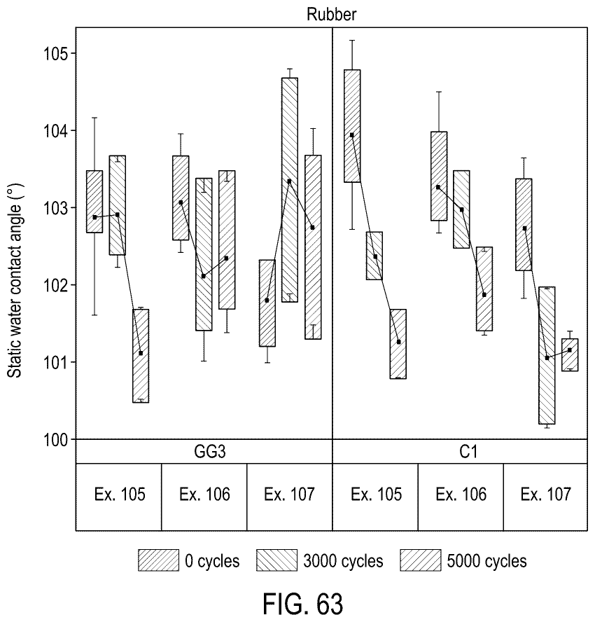

As shown in Table 27 and FIG. 62, a 120 sec treatment (Example 105) reduces high spatial frequency (>40 μm⁻¹) roughness to near that of the bare glass substrate, while longer treatments improve roughness reduction at lower spatial frequencies. COF, WCA, and rubber abrasion results of Examples 105-107 after OTS functionalization are shown in Table 28 and FIG. 63.

TABLE 28
COF and WCA after water vapor plasma treatment
and OTS functionalization of Examples 105-107

| | WVP | COF | COF | | | | | |
|---|---|---|---|---|---|---|---|---|
| Substrate | (sec) | (ave) | (std) | WCA | std | Min | Max | Uniformity |
| C1 | 120 | 0.16 | 0 | 102.9 | 1.3 | 97.4 | 105.1 | 3.70% |
| C1 | 300 | 0.15 | 0 | 103.1 | 0.9 | 99.3 | 104.6 | 2.60% |
| C1 | 600 | 0.14 | 0 | 101.8 | 0.8 | 99.4 | 103.7 | 2.10% |
| GG3 | 120 | 0.12 | 0 | 104 | 1.2 | 100.9 | 106.4 | 2.60% |
| GG3 | 300 | 0.12 | 0 | 103.3 | 1.2 | 99.1 | 105.1 | 2.90% |
| GG3 | 600 | 0.13 | 0 | 102.8 | 0.9 | 100 | 104.4 | 2.10% |

As shown in Table 28 and FIG. 63, the COF is relatively low and the WCA is relatively high for all examples, and varies little with treatment time. All samples pass the rubber abrasion test and results show no significant trends with substrate type or treatment time.

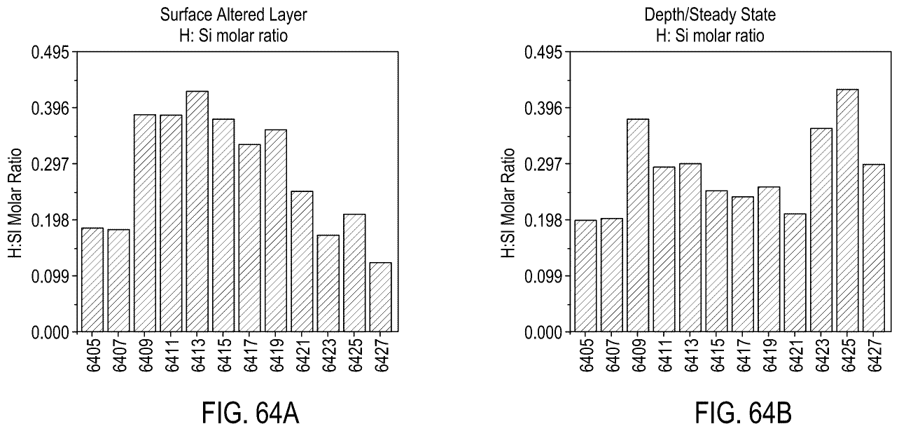

The molar H: Si ratio of the first layer after plasma treatment (i.e. the hydroxyl-modified layer) and the molar H: Si ratio of the bulk material after plasma treatment of SiO₂-coated GG3 under various methods described herein, and are summarized in FIG. 64A, and FIG. 64B, respectively. Traces 6405, 6407, 6409, 6411, 6413, 6415, 6417, 6419, 6421, 6423, 6425, and 6427 correspond to the treatment methods below in Table 29.

TABLE 29
Plasma treatment methods of FIG. 64

| Trace | Method |
|---|---|
| 6405 | H₂ plasma |
| 6407 | H₂ plasma |
| 6409 | Simultaneous 2:1 H₂:O₂ |
| 6411 | Simultaneous 2:1 H₂:O₂ |
| 6413 | Simultaneous 2:1 H₂:O₂ |
| 6415 | Water vapor plasma |
| 6417 | Water vapor plasma |
| 6419 | Water vapor plasma |
| 6421 | Sequential 10x(O₂—H₂) |
| 6423 | Ar—Cl₂—O₂ |
| 6425 | SiO₂/GG3 control |
| 6427 | SiO₂/GG3 control |

As shown in FIG. 64, the coated articles formed herein may comprise a first layer having a molar H:Si ratio of greater than 0.2.

The above observations can be combined to provide coated articles, first layers (e.g. planarization layers and/or hydroxyl-modified layers), and methods of making the same. The first layer can provide a decreased surface roughness Ra relative to what would be obtained in an article (e.g., coated article) without the first layer, which enables the coated article of the present disclosure including the first layer to have increased abrasion resistance of the surface-modifying layer. In aspects, the first layer can provide a reduced surface roughness relative to a surface roughness of an underlying layer, as a ratio of the surface roughness Ra of the first layer to the surface roughness Ra of the underlying layer, can be 0.9 or less (e.g., from 0.1 to 0.90, from 0.2 to 0.80, or from 0.3 to 0.70). Alternatively or additionally, for example when the planarization layer is disposed directly on a substrate, the planarization layer can provide a low surface roughness (e.g., about 0.6 nm or less, from 0.1 nm to 0.6 nm, or from 0.15 nm to about 0.40 nm) that can increase an abrasion resistance of a surface-modifying layer disposed thereon. Alternatively or additionally, for example when the hydroxyl-modified layer is formed directly on a substrate, the hydroxyl-modified layer can provide a low surface roughness (e.g., about 0.6 nm or less, from 0.1 nm to 0.6 nm, or from 0.15 nm to about 0.40 nm) that can increase an abrasion resistance of a surface-modifying layer disposed thereon.

As discussed below with reference to Example 11, the planarization layers in accordance with aspects of the present disclosure can provide unexpected low surface roughness Ra. Indeed, as demonstrated by the results of the Steel Wool Abrasion Test, the Rubber Abrasion Test, and the Cheesecloth Abrasion Test, the surface-modifying layer disposed on the first layer in a coated article in accordance with aspects of the present disclosure can withstand abrasion and maintain good contact angles.

Without wishing to be bound by theory, it is believed that higher spatial frequencies of a surface (e.g., as measured by a 2D isotropic power spectral density discussed herein) impacts the abrasion resistance of a surface-modifying layer disposed thereon. For example, it is believed that decreasing the amplitude of these higher spatial frequencies can enable increased abrasion resistance. Overall surface roughness values such as surface roughness Ra may not fully capture the role of the decreased amplitude at higher spatial frequencies in the first layer. In contrast, aspects of the power spectral density (PSD) (e.g., 2D isotropic PSD) discussed herein may more directly describe these aspects of the first layer.

The first layer can reduce an amplitude of high spatial frequencies (see the power spectral density in FIG. 27), which the inventors have discovered unexpectedly controls the abrasion resistance of the coated article. As shown in FIGS. 23-25, the planarization layer appears to coarsen the resolution of surface features (corresponding to reducing an amplitude of high spatial frequencies in the power spectral density) that in turn, reduces the surface roughness (and/or high frequency texture) of the resulting surface.

The first layer of the present disclosure can be readily distinguished from other silicon-containing oxides (e.g., a silica capping layer) by the properties discussed herein (e.g., hydroxyl content, hardness, refractive index, power spectral density of the surface, surface roughness Ra). For example, the first layer can comprise a greater hydroxyl content than a hydroxyl content of the capping layer; the first layer can exhibit a lower hardness, lower elastic modulus, and/or higher refractive index than the corresponding property of the capping layer; and/or a surface roughness Ra of the first layer can be less than a surface roughness Ra of the capping layer.

The surface-modifying coating can reduce a visibility and/or color shift associated with disposing a fingerprint thereon. Providing a high water contact angle (e.g., about 100° or more) can enhance the removal of aqueous material (e.g., water droplets, sweat droplets) from the anti-fingerprint coating. Consequently, the anti-fingerprint coating can be hydrophobic and oleophilic. The coated article in accordance with the aspects of the disclosure can exhibit good abrasion resistance (e.g., an abraded water contact angle of about 90° or more after 2,000 cycles, 3,000 cycles, and/or 3,500 cycles in a Steel Wool Abrasion Test, a cheesecloth-abraded water contact angle of about 90° after 200,000 cycles in a Cheesecloth Abrasion Test), for example, maintaining a hydrophobic character. The first layer can exhibit good adhesion to the surface-modifying layer disposed thereon, for example, by providing a lower roughness surface for the surface-modifying layer.

In aspects, forming a planarization layer (e.g., as part of the coated article) can comprise evaporating a functionalized POSS and impinging it with an ion beam. Properties of the planarization can be controlled by the discharge current of the ion beam. For a KRI EH-400 End-Hall ion source in a Angstrom Evovac chamber operating at 100V, providing a discharge current of about 0.25 A or more can facilitate the formation of the coating, for example, producing an ion beam with sufficient energy to cause the functionalized POSS to react with other functionalized POSS and/or the first major surface of the substrate at an appreciable rate (e.g., compared to lower discharge currents). Providing a discharge current of about 1 A or less to the ion beam source facilitates deposition of a condensed POSS material. The ion beam discharge can facilitate condensation of the functionalized POSS converting at least a portion of the cage structure of the functionalized POSS to a silica or a partial Si—O—Si—O network. Functionalized POSS is evaporated and subjected to ion beam to create a silica or a partially condensed silica-like network at or near room temperature. Alternatively, the substrate that the thermally evaporated functionalized POSS condenses on and the ion beam impinges can be heated. Substrate temperature during POSS deposition is 250° C. or less, 200° C. or less, 100° C. or less, or preferably 50° C. or less.

The substrate can comprise a glass-based and/or ceramic-based material, which can provide good dimensional stability, good impact resistance, and/or good puncture resistance. The glass-based and/or ceramic-based substrate can comprise one or more compressive stress regions, which can further provide increased impact resistance and/or increased puncture resistance.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein, the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof, as used herein, are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

While various features, elements, or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

What is claimed is:

1. A coated article comprising:
a substrate comprising a first major surface, the substrate comprising a glass-based material, a glass-ceramic material, or a ceramic-based material;
a planarization layer disposed on the first major surface, the planarization layer comprising a thickness between a first surface area and a second surface area opposite the first surface area from about 10 nanometers to about 600 nanometers, the second surface area facing the first major surface, the planarization layer comprises a silica or a silica-like network comprising Si—O—Si—O bonds, and the planarization layer comprises a molar ratio of hydrogen to silica of about 0.2 or more; and
a surface-modifying layer disposed on the first surface area of the planarization layer.

2. The coated article of claim 1, wherein an ion intensity of carbon to an ion intensity of silicon as measured by secondary-ion mass-spectroscopy is about 0.01 or less.

3. The coated article of claim 1, wherein the planarization layer has a 2D isotropic power spectral density of AFM height data at the first surface area of the planarization layer with a value of about 500 nm⁴ or less at a spatial frequency of 30 μm⁻¹.

4. The coated article of claim 1, wherein the planarization layer has a 2D isotropic power spectral density of AFM height data at the first surface area of the planarization layer with a ratio of a first value at a first spatial frequency of 30 μm⁻¹ divided by a second value at a second spatial frequency of 10 μm⁻¹ that is less than 0.55.

5. The coated article of claim 1, wherein a ratio of a 2D isotropic power spectral density of AFM height data at the first surface area of the planarization layer at a spatial frequency of 30 μm⁻¹ divided by a 2D isotropic power spectral density of AFM height data of a surface in contact with the first surface area at a spatial frequency of 30 μm⁻¹ is about 0.9 or less.

6. The coated article of claim 1, wherein the first surface area of the planarization layer exhibits a surface roughness Ra from 0.1 nanometers to 3.0 nanometers.

7. The coated article of claim 1, wherein the planarization layer exhibits one or more of following:
an elastic modulus from about 35 GigaPascals to about 70 GigaPascals,
a hardness from about 3 GigaPascals to about 8 GigaPascals as measured by a Berkovich Indenter Hardness test,
a refractive index from 1.46 to 1.49 at an optical wavelength of 550 nanometers.

8. The coated article of claim 1, wherein the surface-modifying layer is an anti-fingerprint coating or an easy-to-clean coating.

9. The coated article of claim 1, further comprising an optical stack positioned between the planarization layer and the substrate, wherein the optical stack comprises an anti-reflective coating, a gradient coating, a band-pass filter coating, an edge neutral mirror, a beam splitter coating, a multi-layer high-reflectance coating, or an edge filter coating.

10. The coated article of claim 1, wherein the substrate is a textured substrate, a polymer substrate, or a metal substrate.

11. A method of forming a coated article comprising:
evaporating a functionalized polyhedral oligomeric silsesquioxane onto a first major surface of a substrate, the functionalized polyhedral oligomeric silsesquioxane is functionalized with a C1-C10 alkyl group, a C2-C8 alkene group, a phenyl group, or an alkyl silyl group, or combinations thereof; and
impinging an ion beam at the first major surface of the substrate, the impinging occurs in a chamber comprising a chamber pressure ranging from about 10⁻⁴ Pascal to about 1 Pascal, the ion beam is generated using a discharge current from about 0.25 Amps to about 1 Amp, the impinging forms a planarization layer on the first major surface of the substrate, the planarization layer comprises a thickness between a first surface area and a second surface area opposite the first surface area from about 10 nanometers to about 600 nanometers,
disposing a surface-modifying layer disposed on the first surface area of the planarization layer,
wherein the planarization layer comprises a molar ratio of hydrogen to silica of about 0.2 or more, the planarization layer comprises silica or a silica-like network comprising Si—O—Si—O bonds, and the substrate comprises a glass-based material, a glass-ceramic material, or a ceramic-based material.

12. A coated article comprising:
a substrate comprising a first major surface, the substrate comprising a glass-based material, a glass-ceramic material, or a ceramic-based material, wherein the entirety of the substrate comprises a molar ratio of hydrogen to silica of about 0.2 or less;
a first layer disposed on the first major surface, the first layer comprising a thickness between a first surface area and a second surface area opposite the first surface area from about 5 nanometer to about 600 nanometers, the second surface area facing the first major surface, the first layer comprises a silica or a silica-like network each comprising Si—O—Si—O bonds, Si—OH bonds, or both, and the entirety of the first layer comprises a molar ratio of hydrogen to silica of about 0.2 or more; and
a surface-modifying layer disposed on the first surface area of the first layer.

13. The coated article of claim 12, wherein:
the first layer is a planarization layer comprising the Si—O—Si—O bonds,
the first layer is a hydroxyl-modified layer comprising the Si—OH bonds, or
the first layer comprises a planarization layer comprising the Si—O—Si—O bonds and a hydroxyl-modified layer comprising the Si—OH bonds.

14. The coated article of claim 12, wherein the first layer has a 2D isotropic power spectral density of AFM height data at the first surface area of the first layer with a ratio of a logarithm of a first value at a first spatial frequency of 40 μm⁻¹ divided by a logarithm of a second value at a second spatial frequency of 10 μm⁻¹ that is less than 0.4.

15. The coated article of claim 12, wherein the coated article comprises an amount of excess oxygen of at least about 15%.

16. The coated article of claim 12, wherein the first layer has a 2D isotropic power spectral density of AFM height data at the first surface area of the first layer with a value of about 500 nm⁴ or less at a spatial frequency of 30 μm⁻¹.

17. The coated article of claim 12, wherein the first layer has a 2D isotropic power spectral density of AFM height data at the first surface area of the first layer with a value of about 250 nm⁴ or less at a spatial frequency of 40 μm⁻¹.

18. The coated article of claim 12, wherein the first surface area of the first layer exhibits a surface roughness Ra from 0.1 nanometers to 3.0 nanometers.

19. The coated article of claim 12, wherein a ratio of a 2D isotropic power spectral density of AFM height data at the first surface area of the first layer at a spatial frequency of 40 μm⁻¹ divided by a 2D isotropic power spectral density of AFM height data of a surface in contact with the first surface area at a spatial frequency of 40 μm⁻¹ is about 0.9 or less.

20. The coated article of claim 12, wherein a ratio of a surface roughness Ra of the first surface area of the first layer divided by a surface roughness Ra of a surface in contact with the first surface area is about 0.9 or less.

21. The coated article of claim 12, wherein the surface-modifying layer is an anti-fingerprint coating or an easy-to-clean coating.

22. The coated article of claim 12, further comprising an optical stack positioned between the first layer and the substrate, wherein the optical stack comprises an anti-reflective coating, a gradient coating, a band-pass filter coating, an edge neutral mirror, a beam splitter coating, a multi-layer high-reflectance coating, or an edge filter coating.

23. The coated article of claim 12, wherein the substrate is a textured substrate, a polymer substrate or a metal substrate.

24. A method of forming a coated article comprising:
impinging a plasma at a first major surface of a substrate, wherein:
the impinging occurs in a chamber comprising a chamber pressure ranging from about 1 Pascal to about 100 Pascal;
the chamber comprises molecules or ions of oxygen, hydrogen, hydroxyl, or combinations thereof;
the impinging forms a hydroxyl-modified layer on the first major surface of the substrate; and
the hydroxyl-modified layer comprises a thickness between a first surface area and a second surface area opposite the first surface area from about 5 nanometers to about 100 nanometers;
disposing a surface-modifying layer over the first surface area of the hydroxyl-modified layer, wherein:
the hydroxyl-modified layer comprises a molar ratio of hydrogen to silica of about 0.2 or more; and
the hydroxyl-modified layer comprises silica or a silica-like network comprising Si—OH bonds.
